(19) United States
(12) Patent Application Publication
(10) Pub. No.: US 2021/0242409 A1
(43) Pub. Date: Aug. 5, 2021

(54) Light-Emitting Device, Light-Emitting Apparatus, Electronic Device, and Lighting Device

(71) Applicant: Semiconductor Energy Laboratory Co., Ltd., Kanagawa-ken (JP)

(72) Inventors: Satoshi Seo, Sagamihara (JP); Tsunenori SUZUKI, Yokohama (JP); Naoaki HASHIMOTO, Sagamihara (JP)

(73) Assignee: Semiconductor Energy Laboratory Co., Ltd., Kanagawa-ken (JP)

(21) Appl. No.: 17/160,658

(22) Filed: Jan. 28, 2021

(30) Foreign Application Priority Data
Jan. 31, 2020 (JP) 2020-014453
Apr. 28, 2020 (JP) 2020-078787

(51) Int. Cl. H01L 51/00

(52) U.S. Cl. CPC H01L 51/0072; H01L 51/0054

(57) ABSTRACT

A novel light-emitting device that is highly convenient, useful, or reliable is provided. The light-emitting device includes a first electrode, a second electrode, and a first layer. The first layer contains a light-emitting material, a first material, and a second material. The first material has a first anthracene skeleton and a first substituent. The first substituent is bonded to the first anthracene skeleton and includes a heteroaromatic ring. The second material has a second anthracene skeleton, a second substituent, and a third substituent. The second substituent is bonded to the second anthracene skeleton and includes an aromatic ring whose ring structure is composed of carbon. The third substituent is bonded to the second anthracene skeleton and includes an aromatic ring whose ring structure is composed of carbon. The third substituent has a different structure from the second substituent.

### BACKGROUND OF THE INVENTION

### 1. Field of the Invention

One embodiment of the present invention relates to a light-emitting device, a light-emitting apparatus, an electronic device, or a lighting device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display device, a light-emitting device, a power storage device, a memory device, a method of driving any of them, and a method of manufacturing any of them.

### 2. Description of the Related Art

Light-emitting devices (organic EL elements) including organic compounds and utilizing electroluminescence (EL) have been put to more practical use. In the basic structure of such light-emitting devices, an organic compound layer containing a light-emitting material (an EL layer) is interposed between a pair of electrodes. Carriers are injected by application of voltage to the element, and recombination energy of the carriers is used, whereby light emission can be obtained from the light-emitting material.

Since such light-emitting devices are of self-emission type, the light-emitting elements are preferably used for pixels of a display with higher visibility than a liquid crystal display. Displays including such light-emitting devices are also highly advantageous in that they can be thin and lightweight because a backlight is not needed. Moreover, such light-emitting elements also have a feature of extremely fast response speed.

Since light-emitting layers of such light-emitting devices can be successively formed two-dimensionally, planar light emission can be achieved. This feature is difficult to realize with point light sources typified by incandescent lamps or LEDs or linear light sources typified by fluorescent lamps; thus, such light-emitting elements also have great potential as planar light sources, which can be applied to lighting devices and the like.

Displays or lighting devices including light-emitting devices can be suitably used for a variety of electronic devices as described above, and research and development of light-emitting devices have progressed for higher efficiency or longer lifetimes.

Although the characteristics of light-emitting devices have been improved significantly, advanced requirements for various characteristics including efficiency and durability are not yet satisfied. In particular, to solve a problem such as burn-in that still remains as an issue peculiar to EL, it is preferable to suppress a reduction in efficiency due to degradation as much as possible.

Degradation largely depends on an emission center substance and its surrounding materials; therefore, host materials having good characteristics have been actively developed.

### REFERENCE

### Patent Document

[Patent Document 1] Japanese Published Patent Application No. 2004-059535

### SUMMARY OF THE INVENTION

An object of one embodiment of the present invention is to provide a novel light-emitting device that is highly convenient, useful, or reliable. Another object is to provide a novel light-emitting apparatus that is highly convenient, useful, or reliable. Another object is to provide a novel electronic device that is highly convenient, useful, or reliable. Another object is to provide a novel lighting device that is highly convenient, useful, or reliable.

Note that the descriptions of these objects do not preclude the existence of other objects. In one embodiment of the present invention, there is no need to achieve all these objects. Other objects will be apparent from and can be derived from the descriptions of the specification, the drawings, the claims, and the like.

(1) One embodiment of the present invention is a light-emitting device including a first electrode, a second electrode, and a first layer.

The first layer includes a region sandwiched between the first electrode and the second electrode. The first layer contains a light-emitting material D, a first material H1, and a second material H2.

The first material H1 has a first anthracene skeleton and a first substituent R11. The first substituent R11 is bonded to the first anthracene skeleton and includes a heteroaromatic ring.

The second material H2 has a second anthracene skeleton, a second substituent R21, and a third substituent of R22. The second substituent R21 is bonded to the second anthracene skeleton and includes an aromatic ring whose ring structure is composed of carbon. The third substituent R22 is bonded to the second anthracene skeleton, includes an aromatic ring whose ring structure is composed of carbon, and has a structure different from that of the second substituent R21.

(2) Another embodiment of the present invention is the above light-emitting device where the first substituent R11 includes a carbazole skeleton.

Accordingly, reliability can be improved. Alternatively, hole-transport properties can be improved. Alternatively, an increase in driving voltage can be suppressed. As a result, a novel light-emitting device that is highly convenient, useful, or reliable can be provided.

(3) Another embodiment of the present invention is the above light-emitting device where the first substituent R11 includes a dibenzo[c,g]carbazole skeleton and can be represented by the following general formula (R11).

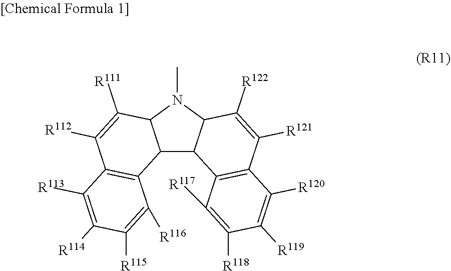

Note that in the above general formula (R11), R¹¹¹ to R¹²² independently represent any one of hydrogen, an alkyl group having 1 to 6 carbon atoms, a cyclic hydrocarbon group having 3 to 6 carbon atoms, an alkoxy group having 1 to 6 carbon atoms, a cyano group, halogen, a haloalkyl group having 1 to 6 carbon atoms, and a substituted or unsubstituted aromatic hydrocarbon group having 6 to 60 carbon atoms.

Thus, a highest occupied molecular orbital (HOMO) level can be made shallow. Alternatively, hole injection can be facilitated. Alternatively, hole-transport properties can be improved. Accordingly, an increase in driving voltage can be suppressed. Alternatively, heat resistance can be improved. As a result, a novel light-emitting device that is highly convenient, useful, or reliable can be provided.

(4) Another embodiment of the present invention is the above light-emitting device where at least one of the second substituents R21 and the third substituent R22 includes a naphthalene ring.

(5) Another embodiment of the present invention is the above light-emitting device where both the second substituent R21 and the third substituent R23 include a naphthalene ring.

(6) Another embodiment of the present invention is the above light-emitting device where the first material H1 can be represented by the following general formula (H11).

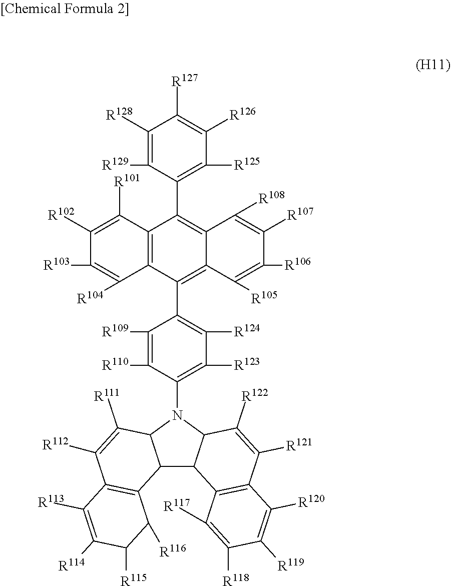

Note that in the above general formula (H11), R¹⁰¹ to R¹²⁹ independently represent any one of hydrogen, an alkyl group having 1 to 6 carbon atoms, a cyclic hydrocarbon group having 3 to 6 carbon atoms, an alkoxy group having 1 to 6 carbon atoms, a cyano group, halogen, a haloalkyl group having 1 to 6 carbon atoms, and a substituted or unsubstituted aromatic hydrocarbon group having 6 to 60 carbon atoms.

(7) Another embodiment of the present invention is the above light-emitting device where the first material H1 is 7-[4-(10-phenyl-9-anthryl)phenyl]-7H-dibenzo[c,g]carbazole represented by the following structural formula (H12).

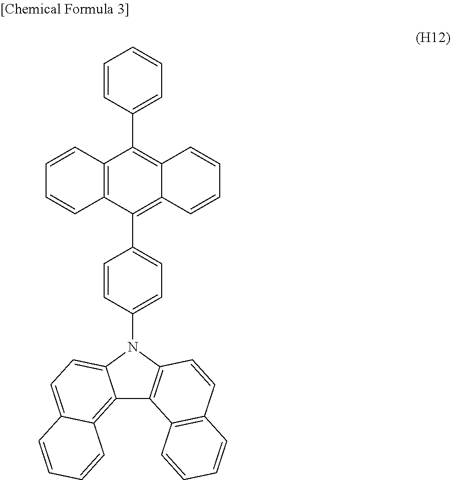 [SMILES: c1ccc(-c2c3ccccc3c(-c3ccc(-n4c5ccc6ccccc6c5c5c6ccccc6ccc54)cc3)c3ccccc23)cc1]

Accordingly, favorable characteristics can be achieved. As a result, a novel light-emitting device that is highly convenient, useful, or reliable can be provided.

(8) Another embodiment of the present invention is the above light-emitting device where the second material H2 has a lower electron-transport property than the first material H1.

Accordingly, reliability can be improved. Alternatively, reliability can be improved while an increase in the driving voltage is suppressed. As a result, a novel light-emitting device that is highly convenient, useful, or reliable can be provided.

(9) Another embodiment of the present invention is the above light-emitting device where the second material H2 can be represented by the following general formula (H21).

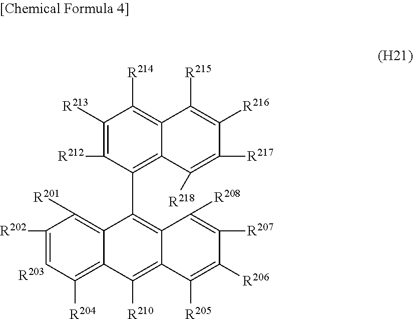

Note that in the above general formula (H21), R²⁰² represents hydrogen or a substituent including an aromatic ring whose ring structure is composed of carbon, R²¹⁰ represents a substituent including an aromatic ring whose ring structure is composed of carbon, at least one of R²⁰² and R²¹⁰ includes a naphthalene ring, R²⁰¹ to R²¹⁸ except R²⁰² and R²¹⁰ independently represent any one of hydrogen, an alkyl group having 1 to 6 carbon atoms, a cyclic hydrocarbon group having 3 to 6 carbon atoms, an alkoxy group having 1 to 6 carbon atoms, a cyano group, halogen, a haloalkyl group having 1 to 6 carbon atoms, and a substituted or unsubstituted aromatic hydrocarbon group having 6 to 60 carbon atoms.

(10) Another embodiment of the present invention is the above light-emitting device where the second material H2 is one selected from 9-(1-naphthyl)-10-[4-(2-naphthyl)phenyl]anthracene represented by the following structural formula (H22) and 2,9-di(1-naphthyl)-10-phenylanthracene represented by the following structural formula (H23).

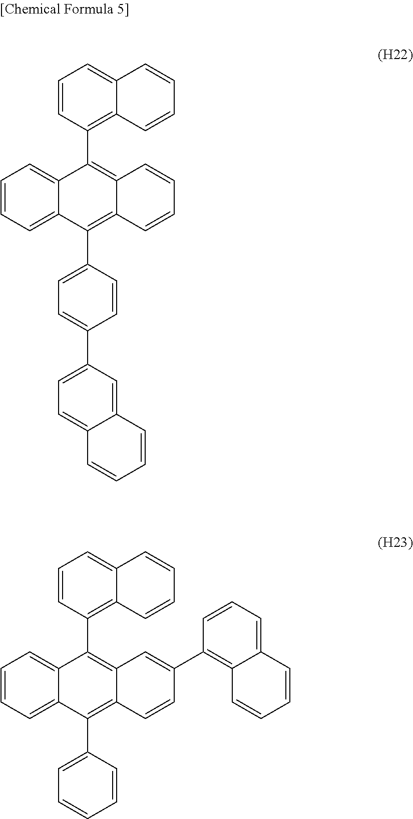

(11) Another embodiment of the present invention is the above light-emitting device where the light-emitting material D emits blue fluorescence.

(12) Another embodiment of the present invention is the above light-emitting device where the light-emitting material D is aromatic diamine or heteroaromatic diamine.

(13) Another embodiment of the present invention is a light-emitting apparatus including the above light-emitting device and a transistor.

Accordingly, reliability can be improved. Alternatively, reliability can be improved while an increase in the driving voltage is suppressed. As a result, a novel light-emitting apparatus that is highly convenient, useful, or reliable can be provided.

(14) Another embodiment of the present invention is an electronic device including the light-emitting apparatus and at least one of a sensor, an operation button, a speaker, and a microphone.

Accordingly, reliability can be improved. Alternatively, reliability can be improved while an increase in the driving voltage is suppressed. As a result, a novel electronic device that is highly convenient, useful, or reliable can be provided.

Although the block diagram in drawings attached to this specification shows components classified by their functions in independent blocks, it is difficult to classify actual components according to their functions completely, and it is possible for one component to have a plurality of functions.

In this specification, the terms “source” and “drain” of a transistor interchange with each other depending on the polarity of the transistor or the levels of potentials applied to the terminals. In general, in an n-channel transistor, a terminal to which a lower potential is applied is called a source, and a terminal to which a higher potential is applied is called a drain. In a p-channel transistor, a terminal to which a lower potential is applied is called a drain, and a terminal to which a higher potential is applied is called a source. In this specification, the connection relation of a transistor is sometimes described assuming for convenience that the source and the drain are fixed; actually, the names of the source and the drain interchange with each other depending on the relation of the potentials.

In this specification, a “source” of a transistor means a source region that is part of a semiconductor film functioning as an active layer or a source electrode connected to the semiconductor film. Similarly, a “drain” of a transistor means a drain region that is part of the semiconductor film or a drain electrode connected to the semiconductor film. A “gate” means a gate electrode.

In this specification, a state in which transistors are connected to each other in series means, for example, a state in which only one of a source and a drain of a first transistor is connected to only one of a source and a drain of a second transistor. In addition, a state in which transistors are connected in parallel means a state in which one of a source and a drain of a first transistor is connected to one of a source and a drain of a second transistor and the other of the source and the drain of the first transistor is connected to the other of the source and the drain of the second transistor.

In this specification, the term “connection” means electrical connection and corresponds to a state where current, voltage, or a potential can be supplied or transmitted. Accordingly, connection means not only direct connection but also indirect connection through a circuit element such as a wiring, a resistor, a diode, or a transistor that allows current, voltage, or a potential to be supplied or transmitted.

In this specification, even when different components are connected to each other in a circuit diagram, there is actually a case where one conductive film has functions of a plurality of components, such as a case where part of a wiring serves as an electrode. The term “connection” in this specification also means such a case where one conductive film has functions of a plurality of components.

In this specification, one of a first electrode and a second electrode of a transistor refers to a source electrode and the other refers to a drain electrode.

According to one embodiment of the present invention, a novel light-emitting device that is highly convenient, useful, or reliable can be provided. A novel light-emitting apparatus that is highly convenient, useful, or reliable can be provided. A novel electronic device that is highly convenient, useful, or reliable can be provided. A novel lighting device that is highly convenient, useful, or reliable can be provided.

Note that the descriptions of these effects do not preclude the existence of other effects. One embodiment of the present invention does not necessarily have all these effects. Other effects will be apparent from and can be derived from the descriptions of the specification, the drawings, the claims, and the like.

### BRIEF DESCRIPTION OF THE DRAWINGS

FIG. 1 illustrates a structure of a light-emitting device according to an embodiment.

FIGS. 2A and 2B each illustrate a structure of a light-emitting device according to an embodiment.

FIG. 3 illustrates a structure of a light-emitting panel according to an embodiment.

FIGS. 4A and 4B are conceptual diagrams of an active matrix light-emitting apparatus.

FIGS. 5A and 5B are conceptual diagrams of an active matrix light-emitting apparatus.

FIG. 6 is a conceptual diagram of an active matrix light-emitting apparatus.

FIGS. 7A and 7B are conceptual diagrams of a passive matrix light-emitting apparatus.

FIGS. 8A and 8B illustrate a lighting device.

FIGS. 9A to 9D each illustrate an electronic device.

FIGS. 10A to 10 C each illustrate an electronic device.

FIG. 11 illustrates a lighting device.

FIG. 12 illustrates a lighting device.

FIG. 13 illustrates in-vehicle display devices and lighting devices.

FIGS. 14A to 14C illustrate an electronic device.

FIG. 15 illustrates a structure of a light-emitting device according to an example.

FIG. 16 is a graph showing luminance versus current density characteristics of light-emitting devices according to an example.

FIG. 17 is a graph showing current efficiency versus luminance characteristics of light-emitting devices according to an example.

FIG. 18 is a graph showing luminance versus voltage characteristics of light-emitting devices according to an example.

FIG. 19 is a graph showing current versus voltage characteristics of of light-emitting devices according to an example.

FIG. 20 is a graph showing external quantum efficiency versus luminance characteristics of light-emitting devices according to an example.

FIG. 21 is a graph showing emission spectra of light-emitting devices according to an example.

FIG. 22 is a graph showing luminance versus current density characteristics characteristics of light-emitting devices according to an example.

FIG. 23 is a graph showing current efficiency versus luminance characteristics of light-emitting devices according to an example.

FIG. 24 is a graph showing luminance versus voltage characteristics of light-emitting devices according to an example.

FIG. 25 is a graph showing current versus voltage characteristics of light-emitting devices according to an example.

FIG. 26 is a graph showing external quantum efficiency versus luminance characteristics of light-emitting devices according to an example.

FIG. 27 is a graph showing emission spectra of light-emitting devices according to an example.

FIG. 28 is a graph showing time dependence of normalized luminance characteristics of light-emitting devices according to an example.

FIG. 29 is a graph showing time dependence of normalized luminance characteristics of light-emitting devices according to an example.

FIG. 30 is a graph showing luminance versus current density characteristics of light-emitting devices according to an example.

FIG. 31 is a graph showing current efficiency versus luminance characteristics of light-emitting devices according to an example.

FIG. 32 is a graph showing luminance versus voltage characteristics of light-emitting devices according to an example.

FIG. 33 is a graph showing current versus voltage characteristics of light-emitting devices according to an example.

FIG. 34 is a graph showing external quantum efficiency versus luminance characteristics of light-emitting devices according to an example.

FIG. 35 is a graph showing emission spectra of light-emitting devices according to an example.

FIG. 36 is a graph showing time dependence of normalized luminance characteristics of light-emitting devices according to an example.

FIG. 37 is a graph showing light distribution of light-emitting devices according to an example.

FIG. 38 is a graph showing light distribution of light-emitting devices according to an example.

FIG. 39 is a graph showing changes in emission intensity after pulse driving of light-emitting devices according to an example.

FIG. 40 is a graph showing changes in emission intensity after pulse driving of light-emitting devices according to an example.

FIG. 41 is a graph showing corrected external quantum efficiency and carrier balance factor γ of light-emitting devices according to an example.

### DETAILED DESCRIPTION OF THE INVENTION

The light-emitting device of one embodiment of the present invention includes a first electrode, a second electrode, and a first layer. The first layer includes a region sandwiched between the first electrode and the second electrode, and the first layer contains a light-emitting material, a first material, and a second material. The first material has a first anthracene skeleton and a heteroaromatic skeleton, and the second material has a second anthracene skeleton and a substituent.

Accordingly, reliability can be improved. Alternatively, reliability can be improved while an increase in the driving voltage is suppressed. As a result, a novel light-emitting device that is highly convenient, useful, or reliable can be provided.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the present invention described below, the same portions or portions having similar functions are denoted by the same reference numerals in different drawings, and the description thereof is not repeated.

### Embodiment 1

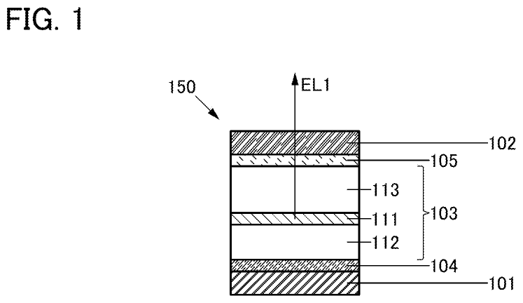

In this embodiment, a structure of a light-emitting device of one embodiment of the present invention will be described with reference to FIG. 1.

FIG. 1 illustrates a structure of a light-emitting device of one embodiment of the present invention.

### <Structure Example of Light-Emitting Device 1>

A light-emitting device 150 described in this embodiment includes an electrode 101, an electrode 102, and a layer 111 (see FIG. 1). Note that the light-emitting device 150 emits light EL1.

The layer 111 includes a region sandwiched between the electrode 101 and the electrode 102. The layer 111 contains a light-emitting material D, a first material H1, and a second material H2.

### <<First Material H1>>

The first material H1 has a first anthracene skeleton and a substituent R11. The substituent R11 is bonded to the first anthracene skeleton, and the substituent R11 includes a heteroaromatic ring.

For example, a compound having the first anthracene skeleton and a carbazole skeleton can be used as the first material H1. Specifically, a compound in which a substituent including a carbazole skeleton is bonded to the 9-position or the 10-position of the first anthracene skeleton can be used as the first material H1.

Accordingly, reliability can be improved. Alternatively, hole-transport properties can be improved. Accordingly, an increase in driving voltage can be suppressed. As a result, a novel light-emitting device that is highly convenient, useful, or reliable can be provided.

For example, the substituent R11 includes a dibenzo[c,g]carbazole skeleton and can be repressed by the following general formula (R11).

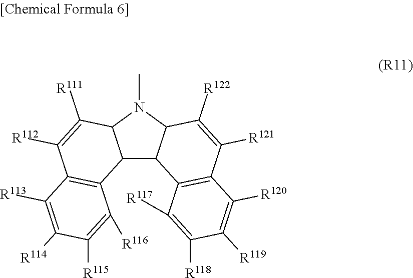

Note that in the above general formula (R11), R¹¹¹ to R¹²² independently represent any one of hydrogen, an alkyl group having 1 to 6 carbon atoms, a cyclic hydrocarbon group having 3 to 6 carbon atoms, an alkoxy group having 1 to 6 carbon atoms, a cyano group, halogen, a haloalkyl group having 1 to 6 carbon atoms, and a substituted or unsubstituted aromatic hydrocarbon group having 6 to 60 carbon atoms.

Thus, the HOMO level can be made shallow. Alternatively, hole injection can be facilitated. Alternatively, hole-transport properties can be improved. Accordingly, an increase in driving voltage can be suppressed. Alternatively, heat resistance can be improved. As a result, a novel light-emitting device that is highly convenient, useful, or reliable can be provided.

For example, the material that can be represented by the following general formula (H11) can be used for the first material H1.

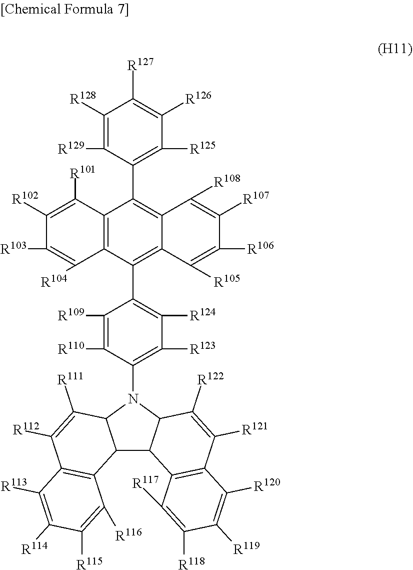

Note that in the above general formula (H11), R^{101 to} R¹²⁹ independently represent any one of hydrogen, an alkyl group having 1 to 6 carbon atoms, a cyclic hydrocarbon group having 3 to 6 carbon atoms, an alkoxy group having 1 to 6 carbon atoms, a cyano group, halogen, a haloalkyl group having 1 to 6 carbon atoms, and a substituted or unsubstituted aromatic hydrocarbon group having 6 to 60 carbon atoms.

For example, as the first material H1, any one of the following compounds whose structural formulae are shown below can be used: 9-[4-(N-carbazolyl)phenyl]-10-phenylanthracene (abbreviation: CzPA): 7-[4-(10-phenyl-9-anthryl)phenyl]-7H-dibenzo[c,g]carbazole (abbreviation: cgDBCzPA); 9-[4-(3-phenyl-9H-carbazol-9-yl)phenyl]-10-phenylanthracene (abbreviation: CzPAP); 7-[4-(10-phenyl-9-anthryl)phenyl]benzo[c]-7H-carbazole (abbreviation: cBCzPA); 5-[4-(10-phenyl-9-anthryl)phenyl]-5H-naphtho[2,3-c]carbazole (abbreviation: cNCzPA); 9-[3-(10-phenyl-9-anthryl)phenyl]-9H-carbazole (abbreviation: mCzPA); 9-[4-(2,9-diphenyl-10-anthryl)phenyl]-9H-carbazole (abbreviation: 2Ph-CzPA); 7-[4-(2,9-diphenyl-10-anthryl)phenyl]-7H-dibenzo[c,g]carbazole (abbreviation: 2Ph-chDBCzPA); 5-phenyl-12-[4-(10-phenyl-9-anthryl)phenyl]-5,12-dihydro-indro[3,2-a]carbazole (abbreviation: ICzPA); 9-phenyl-9′-[4-(10-phenyl-9-anthryl)phenyl]-3,3′-bi(9H-carbazole) (abbreviation: PCCPA); 9-phenyl-9′-[4-(10-phenyl-9-anthryl)phenyl]-3,2′-bi-9H-carbazole (abbreviation: PCCPA-02); 9-[4-(10-phenyl-9-anthryl)phenyl]-3,9′-bi-9H-carbazole (abbreviation: CzCzPA); 9-[4-(10-phenylanthracene-9-yl)-phenyl]4-phenyl-9H-carbazole (abbreviation: CzPAP-03); 9-[4-(3,10-diphenylanthracene-9-yl)-phenyl]4-phenyl-9H-carbazole (abbreviation: 2ph-CzPAP-03); 9-[4-(6-phenyl-13,13,-dimethyl-13H-indeno[1,2-b]anthracene-11-yl)-phenyl]-9H-carbazole (abbreviation: CzIda); 9-[4-(10-phenyl-9-anthryl)phenyl]-9H-tribenzo[a,c]carbazole (abbreviation: acDBCzPA); 7,10-dihydro-10,10-dimethyl-7-[4-(10-phenyl-9-anthryl)phenyl]benzo[c]indeno[1,2-g]carbazole (abbreviation: BINCzPA); 7-[4-(10-phenyl-9-anthryl)phenyl]-9-(9-phenyl-9H-carbazol-2-yl)-7H-benzo[c]carbazole (abbreviation: PCcCzPA-02); 7-[4-(10-phenyl-9-anthryl)phenyl]-9-(9-phenyl-9H-carbazol-3-yl)-7H-benzo[c]carbazole (abbreviation: PCcBCPA); 7-[4-(10-phenyl-9-anthryl)phenyl]-7H-tribenzo[a,c,g]carbazol (abbreviation: acgTBCzPA); 3-[4-(1-naphthyl)phenyl]-9-[4-(10-phenyl-9-anthryl)phenyl]-9H-carbazole (abbreviation: CzPaaNP); 2-phenyl-9-[4-(10-phenyl-9-anthryl)phenyl]-9H-carbazole (abbreviation: CzPAPII); 9-[4-(2,10-diphenylanthracen-9-yl)phenyl]-9H-carbazole (abbreviation: 3Ph-CzPA); 7-[4-(2,10-diphenylanthracen-9-yl)phenyl]-7H-dibenzo[c,g]carbazole (abbreviation: 3Ph-cbDBCzPA); 11-[4-(10-phenyl-9-anthryl)phenyl]-11H-benzo[a]carbazole (abbreviation: aBCzPA); and the like.

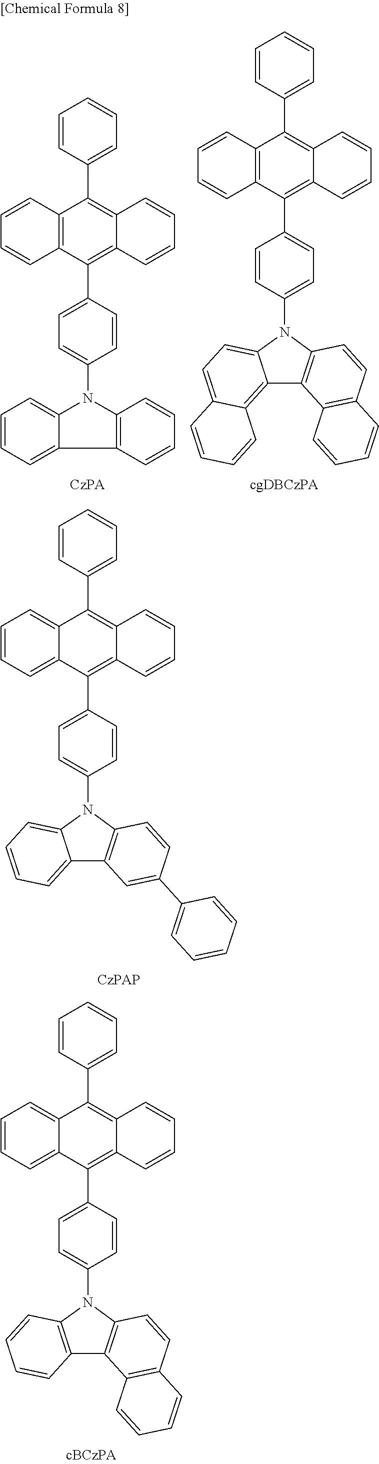

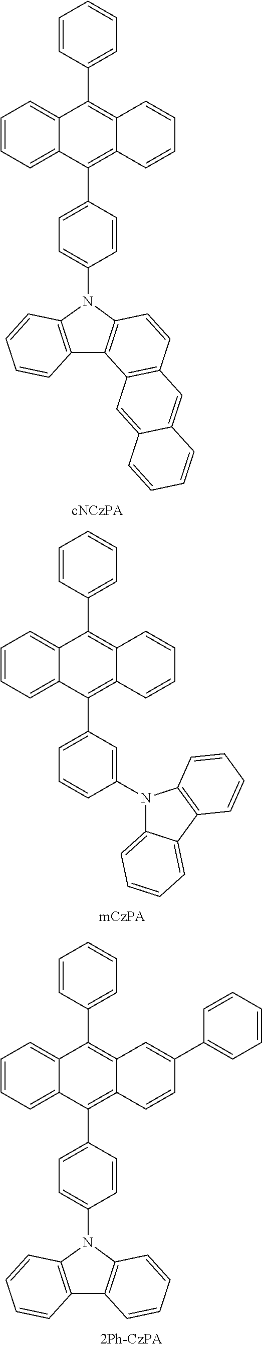 [SMILES: c1ccc(-c2c3ccccc3c(-c3ccc(-n4c5ccccc5c5c6cc7ccccc7cc6ccc54)cc3)c3ccccc23)cc1 ; c1ccc(-c2c3ccccc3c(-c3cccc(-n4c5ccccc5c5ccccc54)c3)c3ccccc23)cc1 ; c1ccc(-c2ccc3c(-c4ccc(-n5c6ccccc6c6ccccc65)cc4)c4ccccc4c(-c4ccccc4)c3c2)cc1]

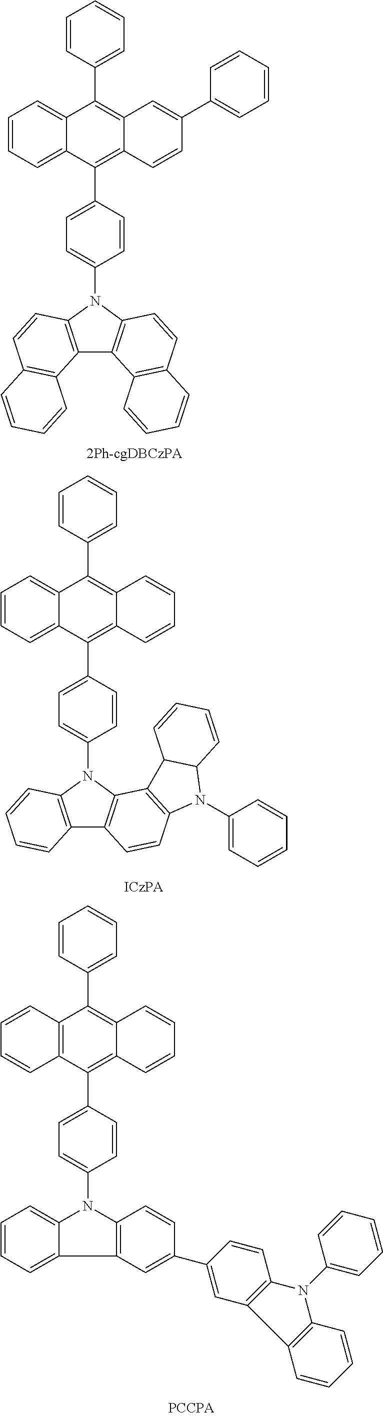 [SMILES: c1ccc(-c2ccc3c(-c4ccc(-n5c6ccc7ccccc7c6c6c7ccccc7ccc65)cc4)c4ccccc4c(-c4ccccc4)c3c2)cc1 ; C1=CC2c3c(ccc4c5ccccc5n(-c5ccc(-c6c7ccccc7c(-c7ccccc7)c7ccccc67)cc5)c34)N(c3ccccc3)C2C=C1 ; c1ccc(-c2c3ccccc3c(-c3ccc(-n4c5ccccc5c5cc(-c6ccc7c(c6)c6ccccc6n7-c6ccccc6)ccc54)cc3)c3ccccc23)cc1]

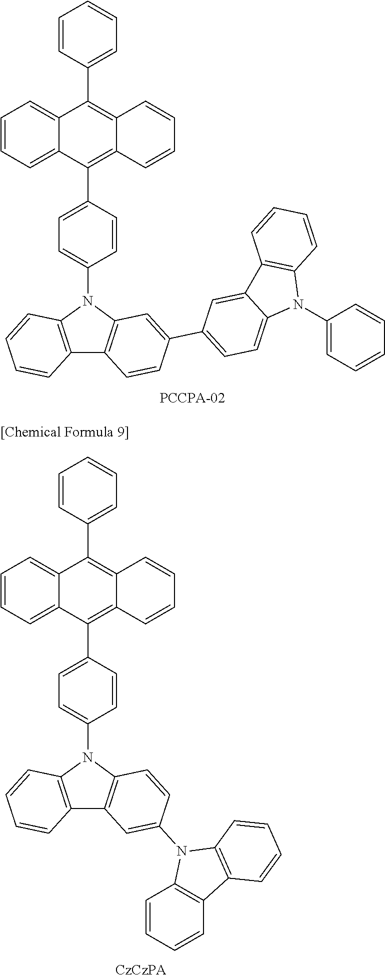 [SMILES: c1ccc(-c2c3ccccc3c(-c3ccc(-n4c5ccccc5c5ccc(-c6ccc7c(c6)c6ccccc6n7-c6ccccc6)cc54)cc3)c3ccccc23)cc1 ; c1ccc(-c2c3ccccc3c(-c3ccc(-n4c5ccccc5c5cc(-n6c7ccccc7c7ccccc76)ccc54)cc3)c3ccccc23)cc1]

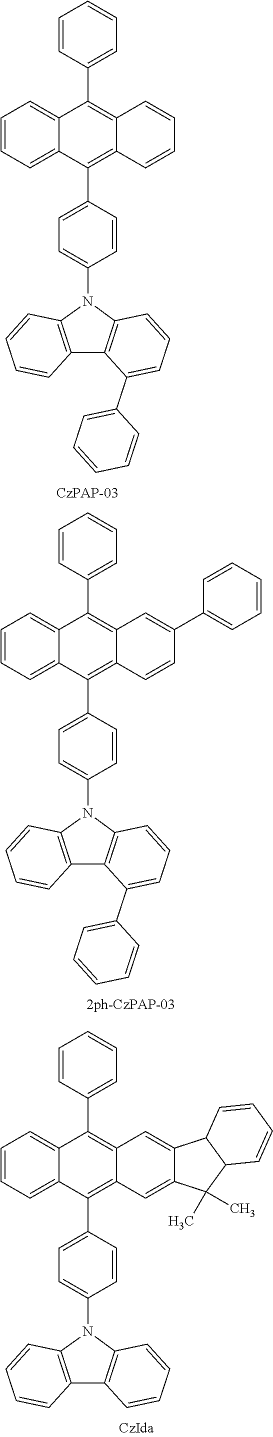

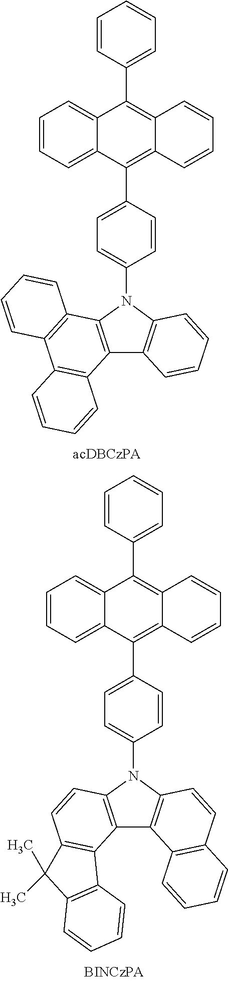 [SMILES: c1ccc(-c2c3ccccc3c(-c3ccc(-n4c5ccccc5c5c6ccccc6c6ccccc6c54)cc3)c3ccccc23)cc1 ; CC1(C)c2ccccc2-c2c1ccc1c2c2c3ccccc3ccc2n1-c1ccc(-c2c3ccccc3c(-c3ccccc3)c3ccccc23)cc1]

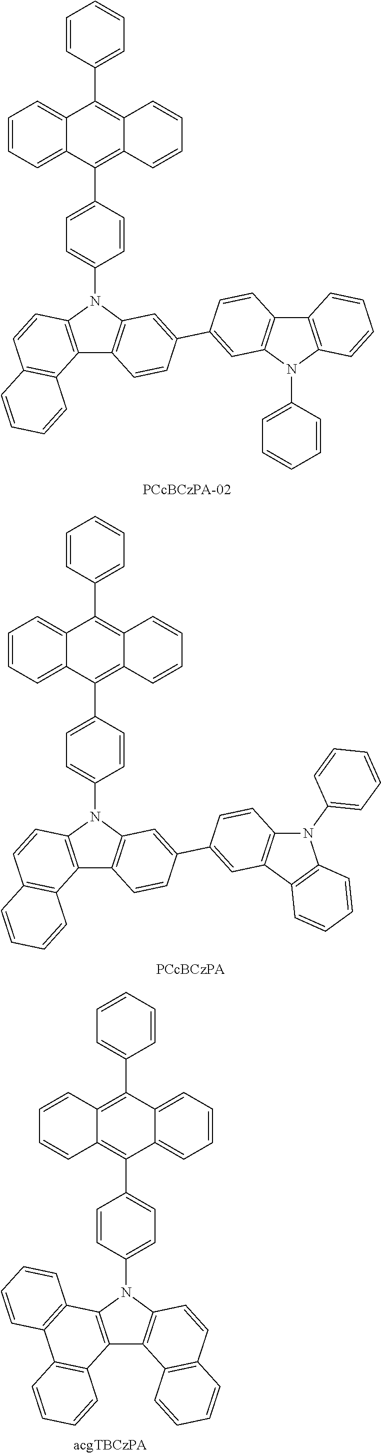 [SMILES: c1ccc(-c2c3ccccc3c(-c3ccc(-n4c5cc(-c6ccc7c8ccccc8n(-c8ccccc8)c7c6)ccc5c5c6ccccc6ccc54)cc3)c3ccccc23)cc1 ; c1ccc(-c2c3ccccc3c(-c3ccc(-n4c5cc(-c6ccc7c(c6)c6ccccc6n7-c6ccccc6)ccc5c5c6ccccc6ccc54)cc3)c3ccccc23)cc1 ; c1ccc(-c2c3ccccc3c(-c3ccc(-n4c5ccc6ccccc6c5c5c6ccccc6c6ccccc6c54)cc3)c3ccccc23)cc1]

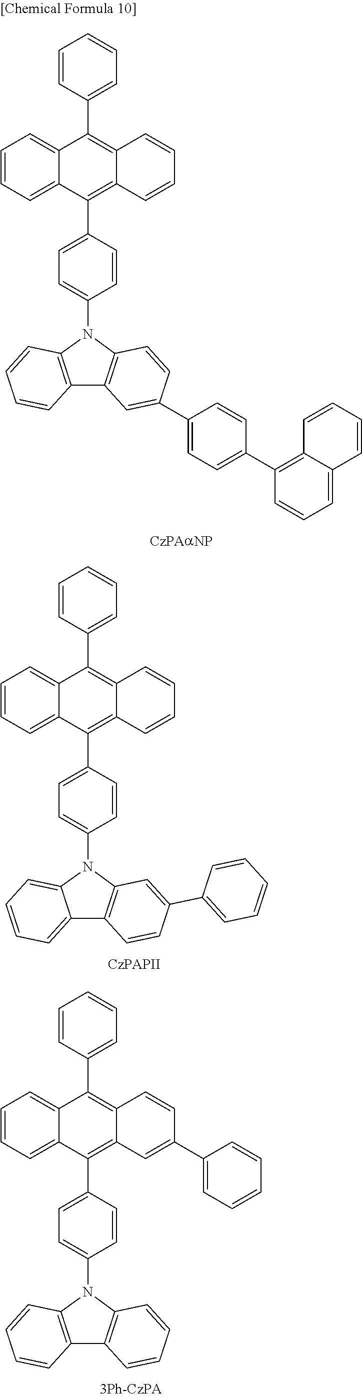 [SMILES: c1ccc(-c2c3ccccc3c(-c3ccc(-n4c5ccccc5c5cc(-c6ccc(-c7cccc8ccccc78)cc6)ccc54)cc3)c3ccccc23)cc1 ; c1ccc(-c2ccc3c4ccccc4n(-c4ccc(-c5c6ccccc6c(-c6ccccc6)c6ccccc56)cc4)c3c2)cc1 ; c1ccc(-c2ccc3c(-c4ccccc4)c4ccccc4c(-c4ccc(-n5c6ccccc6c6ccccc65)cc4)c3c2)cc1]

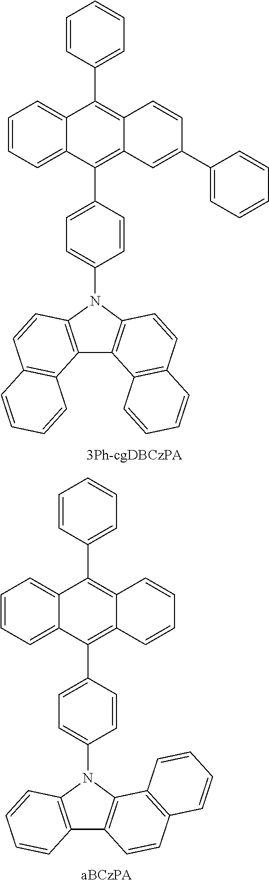 [SMILES: c1ccc(-c2ccc3c(-c4ccccc4)c4ccccc4c(-c4ccc(-n5c6ccc7ccccc7c6c6c7ccccc7ccc65)cc4)c3c2)cc1 ; c1ccc(-c2c3ccccc3c(-c3ccc(-n4c5ccccc5c5ccc6ccccc6c54)cc3)c3ccccc23)cc1]

Alternatively, for example, a compound in which a substituent including a carbazole skeleton is bonded to the 1-position or the 5-position of the first anthracene skeleton can be used as the first material H1.

Specifically, 1,5-bis[4-(9H-carbazol-9-yl)phenyl]-9,10-diphenylanthracene (abbreviation: 1,5CzP2PA) represented by the following structural formula, or the like can be used as the first material H1.

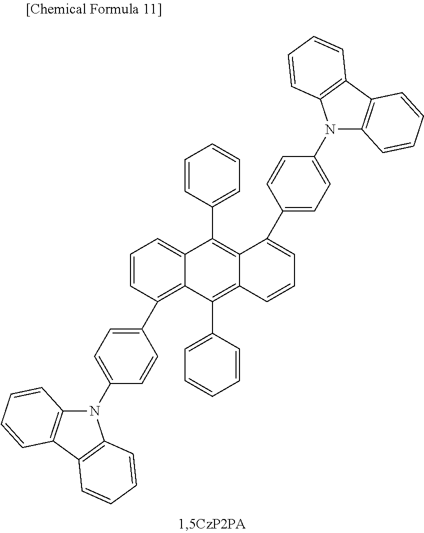 [SMILES: c1ccc(-c2c3cccc(-c4ccc(-n5c6ccccc6c6ccccc65)cc4)c3c(-c3ccccc3)c3cccc(-c4ccc(-n5c6ccccc6c6ccccc65)cc4)c23)cc1]

In particular, 7-[4-(10-phenyl-9-anthryl)phenyl]-7H-dibenzo[c,g]carbazole (abbreviation: cgDBCzPA) can be preferably used as the first material H1.

Furthermore, for example, a compound having the first anthracene skeleton and a furan skeleton can be used as the first material H1. Specifically, a compound in which a substituent including a furan skeleton is bonded to the 9-position or the 10-position of the first anthracene skeleton can be used as the first material H1.

For example, as the first material H1, any one of the following compounds whose structure formulae are shown below can be used: 6-[4-(10-phenyl-9-anthryl)phenyl]-benzo[b]naphtho[1,2-d]furan (abbreviation: BnfPA); 6-[3-(10-diphenyl-9-anthryl)phenyl]-benzo[b]naphtho[1,2-d]furan (abbreviation: mBnfPA); 8-[4-(10-phenyl-9-anthryl)phenyl]-benzo[b]naphtho[1,2-d]furan (abbreviation: BnfPA-02); 10-[3-(10-phenyl-9-anthryl)phenyl]-benzo[b]phenaphtho[9,10-d]furan (abbreviation: mBpfPA); and the like.

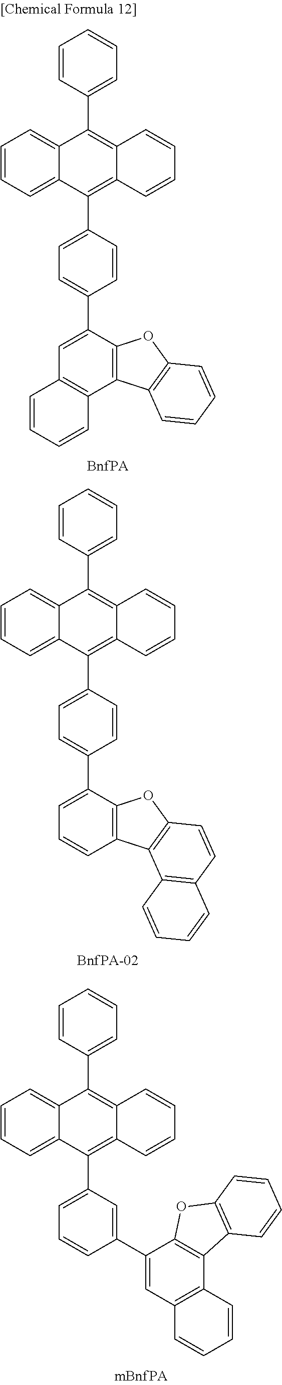 [SMILES: c1ccc(-c2c3ccccc3c(-c3ccc(-c4cc5ccccc5c5c4oc4ccccc45)cc3)c3ccccc23)cc1 ; c1ccc(-c2c3ccccc3c(-c3ccc(-c4cccc5c4oc4ccc6ccccc6c45)cc3)c3ccccc23)cc1 ; c1ccc(-c2c3ccccc3c(-c3cccc(-c4cc5ccccc5c5c4oc4ccccc45)c3)c3ccccc23)cc1]

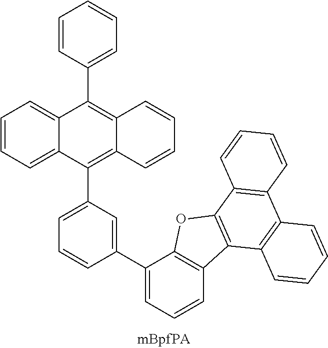 [SMILES: c1ccc(-c2c3ccccc3c(-c3cccc(-c4cccc5c4oc4c6ccccc6c6ccccc6c54)c3)c3ccccc23)cc1]

Furthermore, for example, a compound in which a substituent including a furan skeleton is bonded to the 2-position of the first anthracene skeleton can be used as the first material H1.

Specifically, as the first material H1, any one of the following compounds whose structural formulae shown below can be used: 4-{3-[9,10-di(1-naphthyl)-2-anthryl)phenyl}dibenzofuran (abbreviation: 2mDBfP αDNA); 2-{3-[9,10-di(1-naphthyl)-2-anthryl)phenyl}dibenzofuran (abbreviation: 2mDBfP αDNA-02); 4-{3-[9,10-d](2-naphthyl)-2-anthryl)phenyl}dibenzofuran (abbreviation: 2mDBfPβDNA); 4-{3-[9,10-bis(3-biphenylyl)-2-anthryl)phenyl}dibenzofuran (abbreviation: 2mDBfP-mBP2A); 10-[3-(9,10-diphenyl-2-anthryl)phenyl]-benzo[b]phenanthro[9,10-d]furan (abbreviation: 2mBpfPPA); 6-[3-(9,10-diphenyl-2-anthryl)phenyl]-benzo[b]naphtho[1,2-d]furan (abbreviation: 2mBnfPPA); 2-[3-(9,10-diphenyl-2-anthryl)phenyl]dibenzofuran (abbreviation: 2mDBFPPA); 4-[3-(9,10-diphenyl-2-anthryl)phenyl]-2,8-diphenyldibenzofuran (abbreviation: 2mDBFPPA-III); 4-[4-(9,10-diphenyl-2-anthryl)phenyl]dibenzofuran (abbreviation: 2DBFPPA-II); 4-[3-(9,10-diphenyl-2-anthryl)phenyl]dibenzofuran (abbreviation: 2mDBFPPA-II); 6-(9,10-diphenyl-2-anthryl)benzo[b]naphtho[1,2-d]furan (abbreviation: 2BnfPPA); and the like.

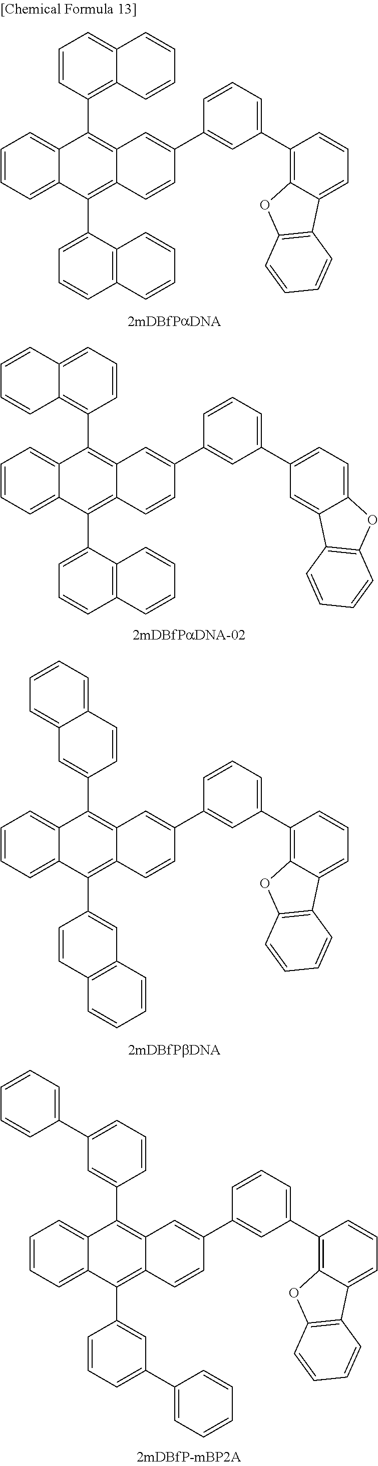 [SMILES: c1cc(-c2ccc3c(-c4cccc5ccccc45)c4ccccc4c(-c4cccc5ccccc45)c3c2)cc(-c2cccc3c2oc2ccccc23)c1 ; c1cc(-c2ccc3c(-c4cccc5ccccc45)c4ccccc4c(-c4cccc5ccccc45)c3c2)cc(-c2ccc3oc4ccccc4c3c2)c1 ; c1cc(-c2ccc3c(-c4ccc5ccccc5c4)c4ccccc4c(-c4ccc5ccccc5c4)c3c2)cc(-c2cccc3c2oc2ccccc23)c1 ; c1ccc(-c2cccc(-c3c4ccccc4c(-c4cccc(-c5ccccc5)c4)c4cc(-c5cccc(-c6cccc7c6oc6ccccc67)c5)ccc34)c2)cc1]

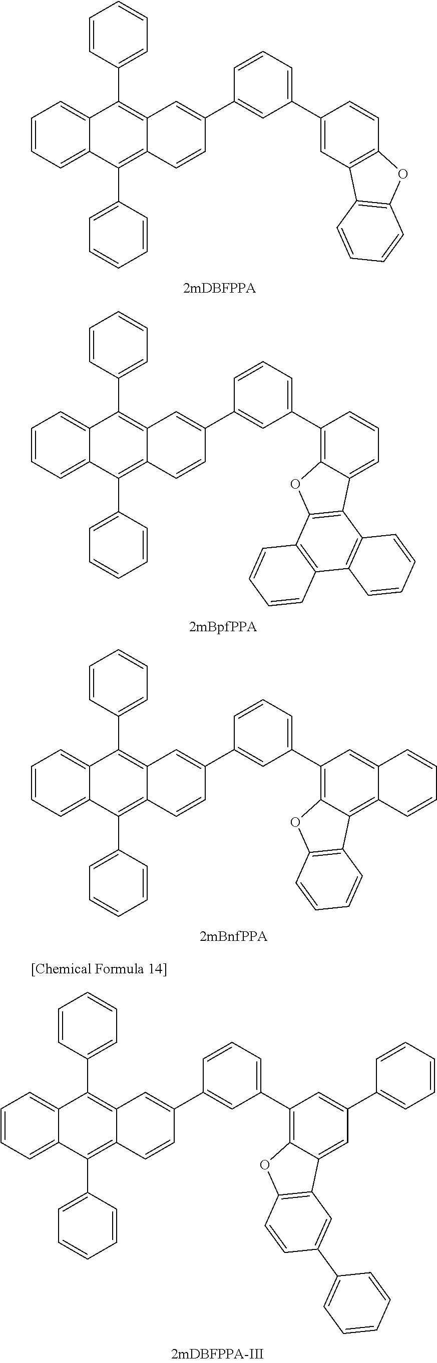

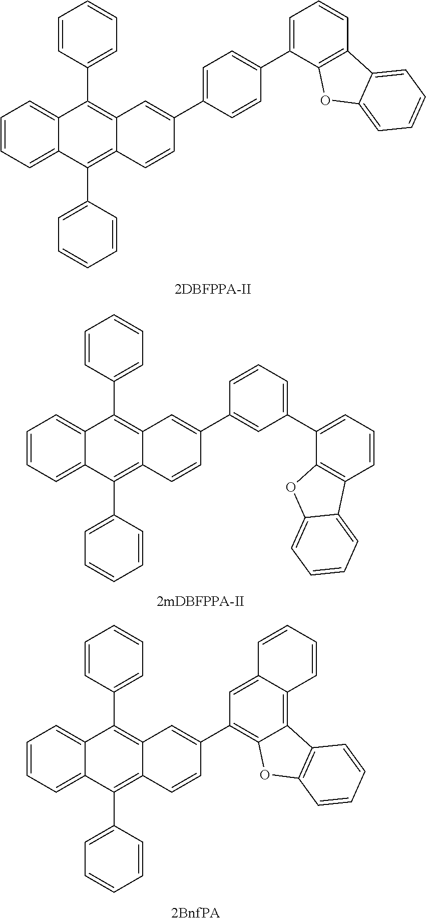

Furthermore, for example, a compound including the first anthracene skeleton and a thiophene skeleton can be used as the first material H1. Specifically, a compound in which a substituent including a thiophene skeleton is bonded to the 9-position or the 10-position of the first anthracene skeleton can be used as the first material H1.

For example, as the first material H1, 4-[3-(10-phenyl-9-anthryl)phenyl]dibenzothiophene (abbreviation: mDBTPA-II) whose structural formula is shown below, or the like can be used.

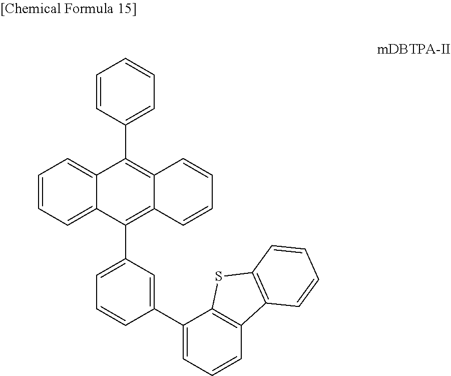 [SMILES: c1ccc(-c2c3ccccc3c(-c3cccc(-c4cccc5c4sc4ccccc45)c3)c3ccccc23)cc1]

Furthermore, for example, a compound in which a substituent including a thiophene skeleton is bonded to the 2-position of the first anthracene skeleton can be used as the first material H1.

Specifically, as the first material H1, any one of the following compounds whose structural formulae are shown blow can be used: 4-[3-(9,10-diphenyl-2-anthryl)phenyl]dibenzothiophene (abbreviation: 2mDBTPA-II); 4-[4-(9,10-diphenyl-2-anthryl)phenyl]dibenzothiophene (abbreviation: 2DBTPPA-II); and the like.

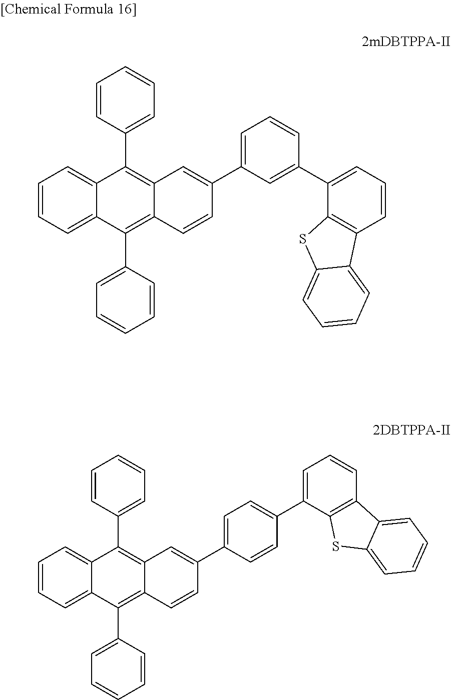 [SMILES: c1ccc(-c2c3ccccc3c(-c3ccccc3)c3cc(-c4cccc(-c5cccc6c5sc5ccccc56)c4)ccc23)cc1 ; c1ccc(-c2c3ccccc3c(-c3ccccc3)c3cc(-c4ccc(-c5cccc6c5sc5ccccc56)cc4)ccc23)cc1]

### <<Second Material H>>

The second material H2 has a second anthracene skeleton, a substituent R21, and a substituent R22. The substituent R21 is bonded to the second anthracene skeleton and contains an aromatic ring whose ring structure is composed of only carbon. The substituent R22 is is bonded to the second anthracene skeleton and contains an aromatic ring whose ring structure is composed of only carbon. The substituent R22 has a structure different from that of the substituent R21.

Note that the second material H2 has an asymmetrical structure with the major axis of the second anthracene skeleton as a rotating shaft. The substituent R21 and the substituent R22 are bonded to the second anthracene skeleton and contain only a carbon atom and a hydrogen atom. In this specification, the structure formula of the second material H2 does not overlap with itself until the structure rotates 360° with the major axis of the second anthracene skeleton as a rotation shaft, and such a structure is referred to as “asymmetric structure with the major axis of the anthracene skeleton as a rotation shaft”.

Furthermore, a material in which at least one of the substituent R21 and the substituent R22 includes a naphthalene ring or a material in which both the substituent R21 and the substituent R22 include a naphthalene ring can be used as the second material H2.

It is preferable that the second material H2 have lower electron-tranport properties than the first material H1.

Accordingly, reliability can be improved. Alternatively, reliability can be improved while an increase in the driving voltage is suppressed. As a result, a novel light-emitting device that is highly convenient, useful, or reliable can be provided.

For example, a compound in which the substituent R21 is bonded to the 9-position of the second anthracene skeleton and the substituent R22 with a different structure from the substituent R21 is bonded to the 10-position of the second anthracene skeleton can be used as the second material H2.

For example, a material that can be represented by the following general formula (H21) can be used for the second material H2.

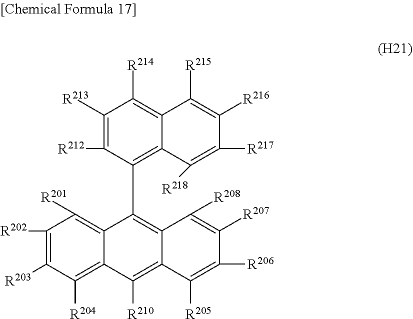

In the above general formula (H21), R²⁰² represents hydrogen or a substituent including an aromatic ring whose ring structure is composed of carbon, R²¹⁰ represents a substituent including an aromatic ring whose ring structure is composed of carbon, at least one of R²⁰² and R²¹⁰ includes a naphthalene ring, R²⁰¹ to R²¹⁸ except R²⁰² and R²¹⁰ independently represent any one of hydrogen, an alkyl group having 1 to 6 carbon atoms, a cyclic hydrocarbon group having 3 to 6 carbon atoms, an alkoxy group having 1 to 6 carbon atoms, a cyano group, halogen, a haloalkyl group having 1 to 6 carbon atoms, and a substituted or unsubstituted aromatic hydrocarbon group having 6 to 60 carbon atoms.

Specifically, as the second material H2, any one of the following compounds whose structural formulae are shown below can be used: 9-(1-naphthyl)-10-[4-(2-naphthyl)phenyl]anthracene (abbreviation: αN-βNPAnth); 9-(1-naphthyl)-10-(2-naphthyl)anthracene (abbreviation: α,β-ADN); 9-(3,5-diphenylphenyl)-10-naphthalen-2-ylanthracene (abbreviation: H2-14); 9-(3,5-diphenylphenyl)-10-naphthalen-1-ylanthracene (abbreviation: H2-15); 9-(3,5-diphenylphenyl)-10-phenylanthracene (abbreviation: H2-16); 9-[3,5-bis(3-methylphenyl)phenyl]-10-phenylanthracene (abbreviation: H2-17), 9-(2-naphthyl)-10-phenylanthracene (abbreviation: H2-18); 9-(1-naphthyl)-10-phenylanthracene (abbreviation: H2-19); 9-(3,5-dinaphthalen-1-ylphenyl)-10-(6-phenylnaphthalen-2-yl)anthracene (abbreviation: H2-20); 9-[3,5-bis(3-methylphenyl)phenyl]-10-(6-phenylnaphthalen-2-yl)anthracene (abbreviation: H2-21); 9-naphthalen-1-yl-10-(6-phenylnaphthalen-2-yl)anthracene (abbreviation: H2-22); 9-(3,5-dinaphthalen-1-ylphenyl)-10-naphthalen-1-yl anthracene (abbreviation: H2-23); 9-(3,5-dinaphthalen-1-ylphenyl)-10-naphthalen-2-ylanthracene (abbreviation: H2-24) and the like.

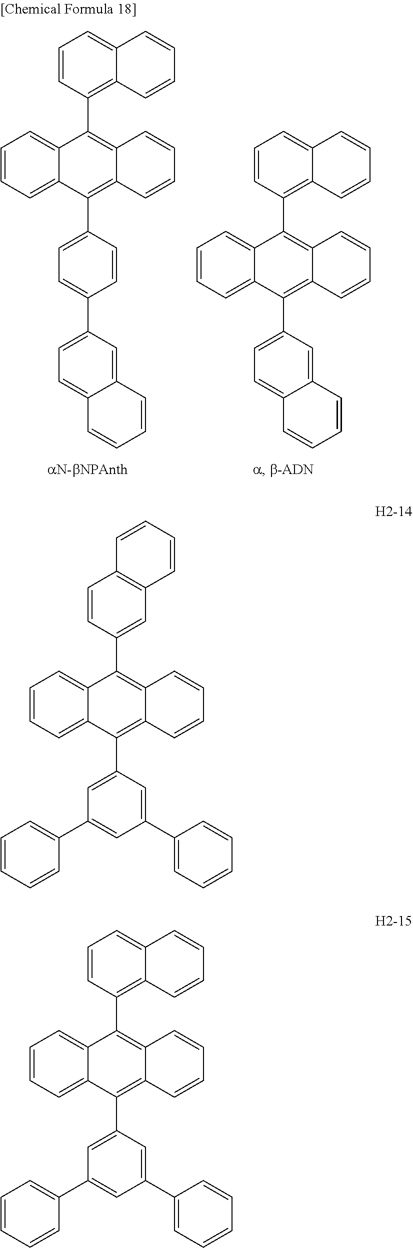

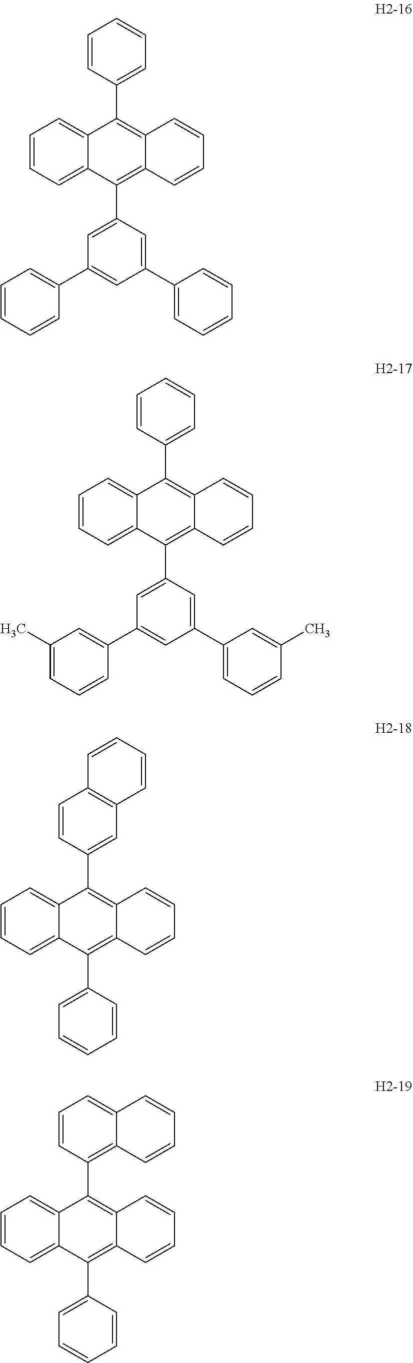

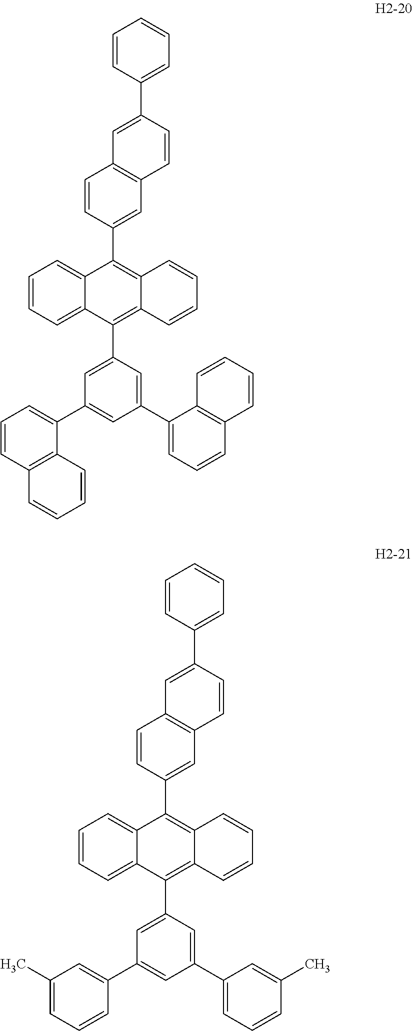

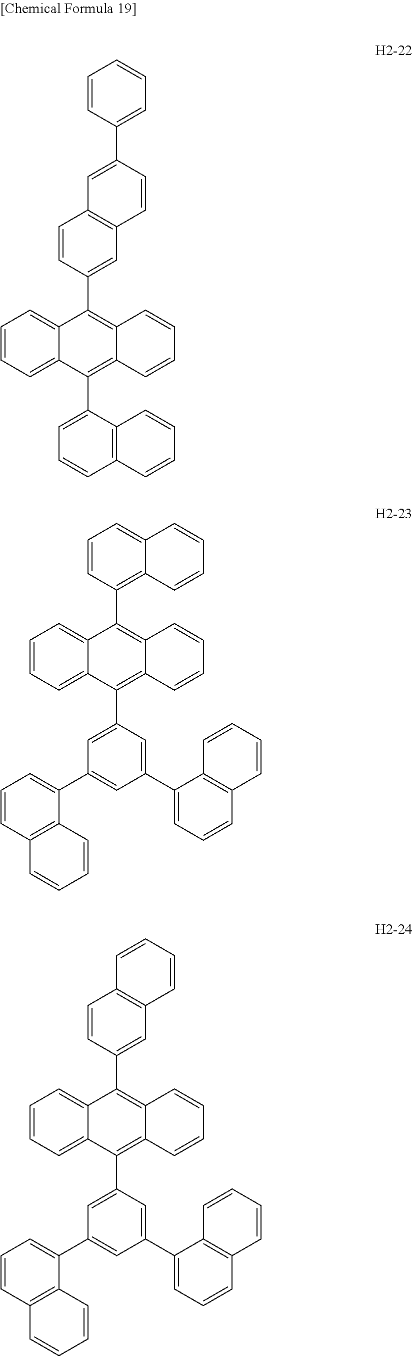

Furthermore, for example, it is possible for the second material H2 to use a compound in which, as well as a first substituent bonded to and a second substituent, a third substituent bonded to the 2-position of the second anthracene skeleton is provided. Here, the first substituent is boded to the 9-position, and the second substituent (with a different structure from the first substituent) is bonded to the 10-position of the second anthracene skeleton.

For example, as the second material H2, any one of the following compounds whose structural formulae are shown below can be used: 9-(1-naphthyl)-2-(2-naphthyl)-10-phenyl anthracene (abbreviation: 2βN-αNPhA); 2,9-di(1-naphthyl)-10-phenylanthracene (abbreviation: 2αN-βNPhA), 2,10-(1-naphthyl)-9-phenylanthracene (abbreviation: 3αN-αNPhA); 9-(1-naphthyl)-10-phenyl-2-(4-methyl-1-naphthyl)anthracene (abbreviation: 2MeαN-αNPhA); 9-(1-naphthyl)-10-phenyl-2-(5-phenyl-1-naphthyl)anthracene (abbreviation: 2PαN-αNPhA); 2,9-(1-naphthyl)-10-(4-biphenylyl)anthracene (abbreviation: 2αN-αNBPhA); 2-(1-naphthyl)-9-(5-phenyl-1-naphthyl)-10-phenylanthracene (abbreviation: 2αN-PαNPhA); 4-[10-(2-naphthyl)-9-phenyl-2-anthryl]benzo[a]anthracene (abbreviation: 3aBA-αNPhA); 4-[9-(2-naphthyl)-10-phenyl-2-anthryl]benzo[a]anthracene (abbreviation: 2aBA-βNPhA); 4-[10-(1-naphthyl)-9-phenyl-2-anthryl]benzo[a]anthracene (abbreviation: 3aBA-αNPhA); 4-[9-(1-naphthyl)-10-phenyl-2-anthryl]benzo[a]anthracene (abbreviation: 2aBA-αNPhA); and the like.

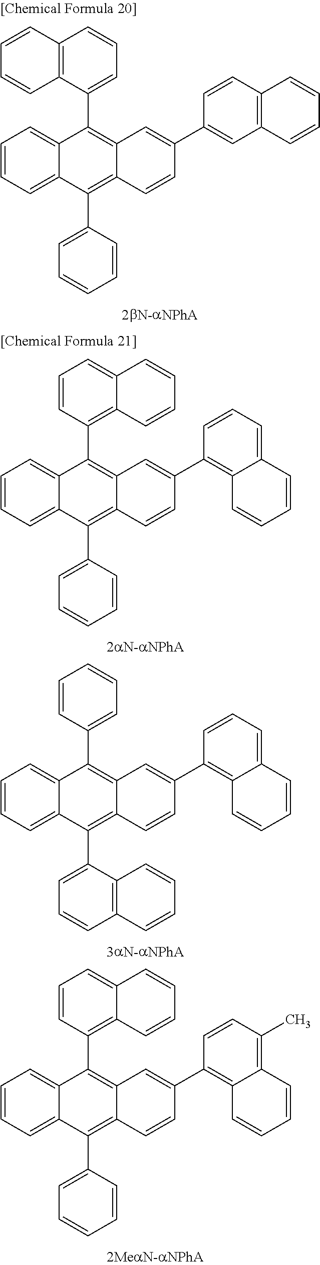

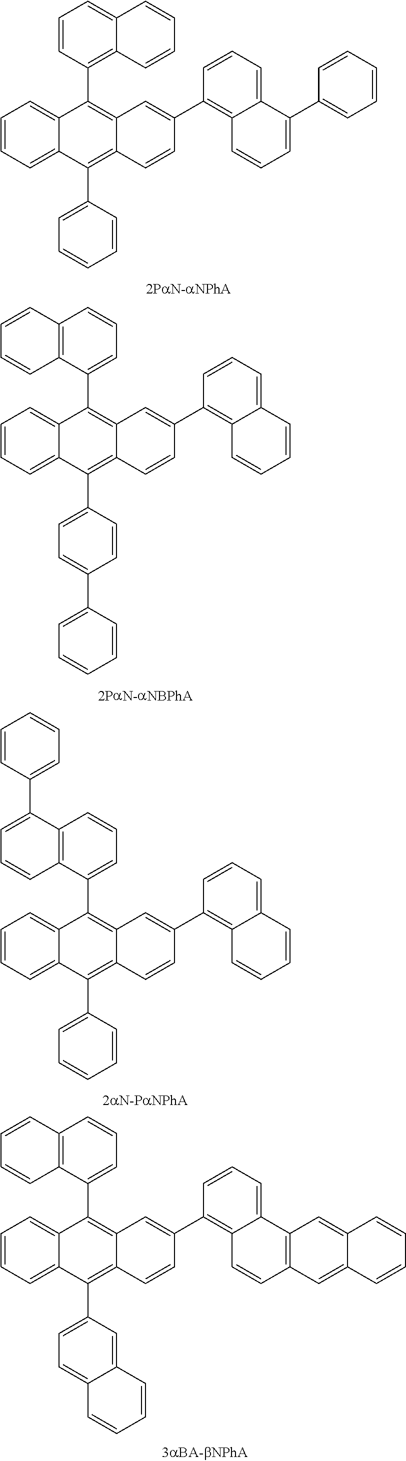

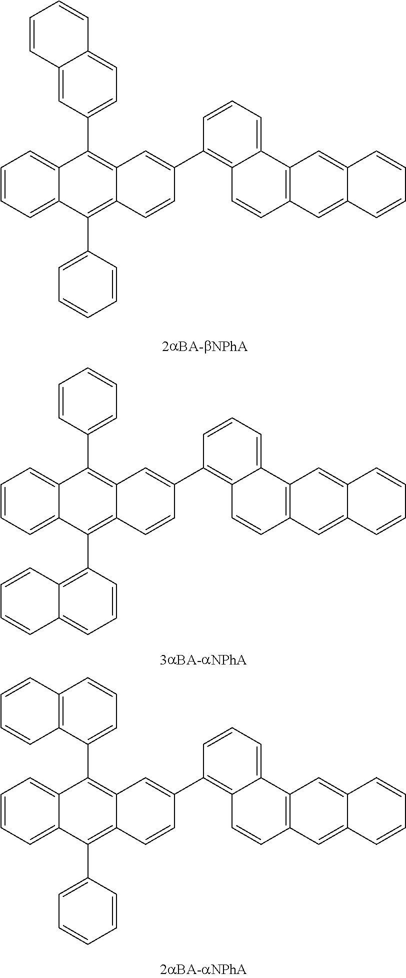

In particular, one selected from 9-(1-naphthyl)-10-[4-(2-naphthyl)phenyl]anthracene (abbreviation: αN-/βNPAnth) and 2,9-di(1-naphthyl)-10-phenylanthracene (abbreviation: 2αN-/βNPhA) can be preferably used as the second material H2.

### <<Light-Emitting Material D>>

The light-emitting material D emits blue fluorescence. For example, as the light-emitting material D, it is possible to use a material that makes a local maximum value of an emission spectrum fall within a wavelength range greater than or equal to 435 nm and less than or equal to 500 nm, preferably greater than or equal to 435 nm and less than or equal to 490 nm, further preferably greater than or equal to 435 nm and less than or equal to 480 nm. Specifically, aromatic diamine or heteroaromatic diamine can be used as the light-emitting material D.

For example, 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) can be used as the light-emitting material D.

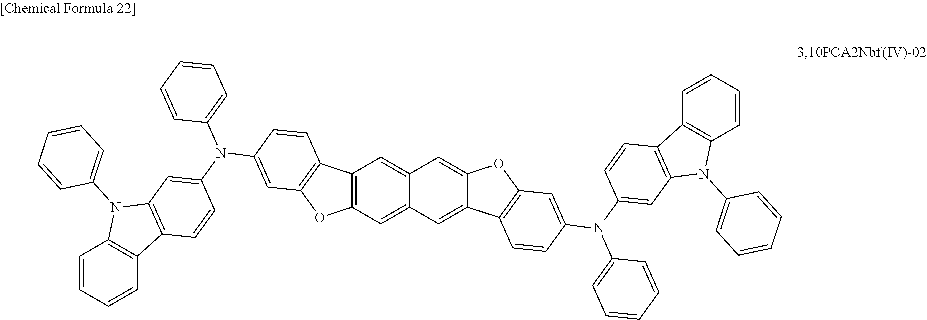 [SMILES: c1ccc(N(c2ccc3c(c2)oc2cc4cc5c(cc4cc23)oc2cc(N(c3ccccc3)c3ccc4c6ccccc6n(-c6ccccc6)c4c3)ccc25)c2ccc3c4ccccc4n(-c4ccccc4)c3c2)cc1]

Note that this embodiment can be combined with any of the other embodiments in this specification as appropriate.

### Embodiment 2

In this embodiment, a structure of the light-emitting device 150 of one embodiment of the present invention will be described with reference to FIG. 1.

### <Structure Example of Light-Emitting Device 150>

The light-emitting device 150 described in this embodiment includes the electrode 101, the electrode 102, and a unit 103.

### <Structure Example of Unit 103>

The unit 103 includes the layer 111, a layer 112, and a layer 113 (see FIG. 1). Note that the layer 111 includes a region sandwiched between the layer 112 and the layer 113. For example, the structure described in Embodiment 1 can be used for the layer 111.

### <<Structure Example of Layer 112>>

The layer 112 includes a region sandwiched between the electrode 101 and the layer 111. It is preferable for the layer 112 to use a substance having a wider bandgap than that in a light-emitting material contained in the layer 111. Thus, transfer of energy from excitons generated in the layer 111 to the layer 112 can be suppressed. For example, a material having a hole-transport property can be used for the layer 112. The layer 112 can be referred to as a hole-transport layer.

### [Hole-Transport Material]

The material having a hole-transport property (hole-transport material) preferably has a hole mobility higher than or equal to 1×10⁻⁶ cm²/Vs. For example, a compound having an aromatic amine skeleton, a compound having a carbazole skeleton, a compound having a thiophene skeleton, a compound having a furan skeleton, or the like can be used.

For example, a hole-transport material capable of being used for the layer 111 can be used for the layer 112. Specifically, a hole-transport material capable of being used for a host material can be used for the layer 112.

The hole-transport material is preferably an aromatic amine compound or an organic compound having a π-electron rich heteroaromatic ring skeleton. For example, a compound having an aromatic amine skeleton, a compound having a carbazole skeleton, a compound having a thiophene skeleton, a compound having a furan skeleton, or the like can be used.

The following are examples that can be used as the compound having an aromatic amine skeleton: 4,4′-bis[N-(1-naphthyl)-N-phenylamino]biphenyl (abbreviation: NPB), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF).

As a compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), or the like can be used.

As a compound having a thiophene skeleton, for example, 4,4′,4″-(benzene-1,3,5-triyl)tri(dibenzofuran) (abbreviation: DBF3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), or the like can be used.

As a compound having a furan skeleton, for example, 4,4′,4″-(benzene-1,3,5-triyl)tri(dibenzofuran) (abbreviation: DBFP-II), 4-{3-[3-(9-phenyl-9H-fluoren-9-yl)phenyl]phenyl}dibenzofuran (abbreviation: mmDBFFLBi-II), or the like can be used.

Among the above materials, the compound having an aromatic amine skeleton or the compound having a carbazole skeleton are preferable because these compounds are highly reliable and have high hole-transport properties to contribute to a reduction in driving voltage.

### <<Structure Example of Layer 113>>

The layer 113 includes a region sandwiched between the layer 111 and the electrode 102. A substance having a wider bandgap than the light-emitting material contained in the layer 111 is preferably used for the layer 113. Thus, transfer of energy from excitons generated in the layer 111 to the layer 113 can be suppressed. For example, a material having an electron-transport property can be used for the layer 113. The layer 113 can be referred to as an electron-transport layer.

### [Electron-Transport Material]

The material having an electron-transport property (electron-transport material) preferably has an electron mobility higher than or equal to 1×10⁻⁷ cm²/Vs and lower than or equal to 5×10⁻⁵ cm²/Vs when the square root of the electric field strength [V/cm] is 600. When the electron-transport property in the electron-transport layer is suppressed, the amount of electrons injected into a light-emitting layer can be controlled. Alternatively, the light-emitting layer can be prevented from having excess electrons.

For example, an electron-transport material capable of being used for the layer 111 can be used for the layer 113. Specifically, an electron-transport material capable of being used as a host material can be used for the layer 113.

An organic compound having an anthracene skeleton can be used as the electron-transport material. In particular, an organic compound having both an anthracene skeleton and a heterocyclic skeleton can be preferably used.

For example, it is possible to use an organic compound having both an anthracene skeleton and a nitrogen-containing five-membered ring skeleton or an organic compound having both an anthracene skeleton and a nitrogen-containing six-membered ring skeleton. Alternatively, it is possible to use an organic compound having both an anthracene skeleton and a nitrogen-containing five-membered ring skeleton where two heteroatoms are included in a ring or an organic compound having a nitrogen-containing six-membered ring skeleton where two heteroatoms are included in a ring. Specifically, it is preferable, as the heterocyclic skeleton, to use a pyrazole ring, an imidazole ring, an oxazole ring, a thiazole ring, a pyrazine ring, a pyrimidine ring, a pyridazine ring, or the like.

A material which includes a substance having an electron-transport property and any of an alkali metal, an alkali metal compound, or an alkali metal complex can be used for the electron-transport material. In particular, when a substance having a relatively deep HOMO level that is greater than or equal to −5.7 eV and lower than or equal to −5.4 eV is used for the composite material of a hole-injection layer, the reliability of the light-emitting device can be increased. In this case, the electron-transport material preferably has a HOMO level of −6.0 eV or higher.

For example, a 8-hydroxyquinolinato structure is preferably included. Specific examples include 8-hydroxyquinolinato-lithium (abbreviation: Liq) and 8-hydroxyquinolinato-sodium (abbreviation: Naq).

In particular, a complex of a monovalent metal ion, especially a complex of lithium is preferable, and Liq is further preferable. Note that in the case where the 8-hydroxyquinolinato structure is included, a methyl-substituted product (e.g., a 2-methyl-substituted product or a 5-methyl-substituted product) thereof or the like can also be used. There is preferably a difference in the concentration (including 0) of the alkali metal, the alkaline earth metal, the compound thereof, or the complex thereof in the electron-transport layer in the thickness direction.

As the electron-transport material, a metal complex or an organic compound having a π-electron deficient heteroaromatic ring skeleton is preferably used. As examples of the organic compound having a π-electron deficient heteroaromatic ring skeleton, the heterocyclic compound having a polyazole skeleton, a heterocyclic compound having a diazine skeleton, and a heterocyclic compound having a pyridine skeleton are preferably used. In particular, the heterocyclic compound having a diazine skeleton and the heterocyclic compound having a pyridine skeleton have favorable reliability and thus are preferable. In addition, the heterocyclic compound having a diazine (pyrimidine or pyrazine) skeleton has a high electron-transport property to contribute to a reduction in driving voltage.

As the metal complexe, bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), bis[2-(2-benzothiazolyl)phenolato]zinc(II) (abbreviation: ZnBTZ), or the like can be used, for example.

As the heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or the like can be used, for example.

As the heterocyclic compound having a diazine skeleton, for example, 2-[3-(dibenzothiophen-4-yl)phenyl]dibenzo[f.h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,8-bis[3-(dibenzothiophen-4-yl)phenyl]benzo[h]quinazolin (abbreviation: 4,8mDBtP2Bqn), or the like can be used.

As the heterocyclic compound having a pyridine skeleton, for example, 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), or the like can be used.

Note that this embodiment can be combined with any of the other embodiments in this specification as appropriate.

### Embodiment 3

In this embodiment, a structure of the light-emitting device 150 of one embodiment of the present invention will be described with reference to FIG. 1.

### <Structure Example of Light-Emitting Device 150>

The light-emitting device 150 described in this embodiment includes the electrode 101, the electrode 102, the unit 103, a layer 104, and a layer 105. For example, the structure described in Embodiment 2 can be used for the unit 103.

### <<Structure Example of Electrode 101>>

For the electrode 101, a metal an alloy, a conductive compound, and a mixture of these, or the like can be used. For example, a material having a work function greater than or equal to 4.0 eV can be favorably used.

For example, indium oxide-tin oxide (ITO: indium tin oxide), indium oxide-tin oxide containing silicon or silicon oxide (ITSO), indium oxide-zinc oxide, indium oxide containing tungsten oxide and zinc oxide (IWZO), or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used. Graphene can also be used.

### <<Structure Example of Electrode 102>>

The electrode 102 includes a region overlapping with the electrode 101. For example, a conductive material can be used for the electrode 102. Specifically, a metal, an alloy, an electrically conductive compound, a mixture of these, or the like can be used for the electrode 102. For example, a material with a lower work function than the electrode 101 can be used for the electrode 102. Specifically, a material having a work function less than or equal to 3.8 eV can be favorably used.

For example, an element belonging to Group 1 of the periodic table, an element belonging to Group 2 of the periodic table, a rare earth metal, or an alloy containing any of these elements can be used for the electrode 102.

Specifically, a Group 1 element such as lithium (Li) or cesium (Cs), a Group 2 element such as magnesium (Mg), calcium (Ca), or strontium (Sr), a rare earth metal such as europium (Eu) or ytterbium (Yb), or an alloy containing any of these elements such as MgAg or AlLi can be used for the electrode 102.

### <<Structure Example of Layer 104>>

The layer 104 includes a region sandwiched between the electrode 101 and the unit 103. Note that the layer 104 can be referred to as a hole-injection layer. For example, a material having a hole-injection property (hole-injection material) can be used for the layer 104.

Specifically, a substance having an acceptor property and a composite material can be used for the layer 104. Note that an organic compound and an inorganic compound can be used as the substance having an acceptor property. The substance having an acceptor property can extract electrons from an adjacent hole-transport layer (or hole-transport material) by the application of an electric field.

### [Example of Hole-Injection Material 1]

The substance having an acceptor property can be used for a hole-injection material. This can facilitate the injection of holes from the electrode 101, for example. In addition, the driving voltage of the light-emitting device can be reduced.

For example, a compound having an electron-withdrawing group (a halogen or cyano group) can be used as the substance having an acceptor property. Note that an organic compound having an acceptor property is easily evaporated, which facilitates film deposition. Thus, the productivity of the light-emitting device can be increased.

Specific examples of a material having a hole-injection material include 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile.

A compound in which electron-withdrawing groups are bonded to a condensed aromatic ring having a plurality of heteroatoms, such as HAT-CN, is particularly preferable because it is thermally stable.

A [3]radialene derivative having an electron-withdrawing group (in particular, a cyano group or a halogen group such as a fluoro group) has a very high electron-accepting property and thus is preferred.

Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile].

For the material having an acceptor property, a molybdenum oxide, a vanadium oxide, a ruthenium oxide, a tungsten oxide, manganese oxide, or the like can be used.

Alternatively, it is possible to use any of the following materials: phthalocyanine-based complex compounds such as phthalocyanine (abbreviation: H₂Pc) and copper phthalocyanine (abbreviation: CuPc); aromatic amine compounds such as 4,4′-bis[N-(4-diphenylaminophenyl)-N-phenylamino]biphenyl (abbreviation: DPAB) and N,N′-bis{4-[bis(3-methylphenyl)amino]phenyl}-N,N′-diphenyl-(1,1′-biphenyl)-4,4′-diamine (abbreviation: DNTPD); and the like.

In addition, high molecular compounds such as poly(3,4-ethylenedioxythiophene)/poly(styrenesulfonic acid) (abbreviation: PEDOT/PSS), and the like can be used.

### [Example of Hole-Injection Material 2]

A composite material can be used for the hole-injection material. For example, a composite material in which a hole-transport material contains a substance having an acceptor property can be used, by which selection of a material used to form an electrode can be carried out in a wide range regardless of work function. Accordingly, besides a material having a high work function, a material having a low work function can also be used for the electrode 101.

A variety of organic compounds can be used for a hole-transport material in the composite material. For the hole-transport material in the composite material, for example, a compound having an aromatic amine skeleton, a carbazole derivative, an aromatic hydrocarbon, a high molecular compound (such as an oligomer, a dendrimer, or a polymer), or the like can be used. A substance having a hole mobility greater than or equal to 1×10⁻⁶ cm²/Vs can be favorably used.

Alternatively, a substance having a relatively deep HOMO level that is greater than or equal to −5.7 eV and less than or equal to −5.4 eV can be favorably used for the hole-transport material in the composite material. Accordingly, hole injection to the hole-transport layer can be facilitated. Furthermore, reliability of the light-emitting device can be improved.

Examples of the compounds having an aromatic amine skeleton include N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N-bis{4-[bis(3-methylphenyl)amino]phenyl}-N,N′-diphenyl-(1,1′-biphenyl)-4,4′-diamine (abbreviation: DNTPD), and 1,3,5-tris[N-(4-diphenylaminophenyl)-N-phenylamino]benzene (abbreviation: DPA3B).

Specific examples of the carbazole derivative include 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(N-carbazolyl)]phenyl-10-phenylanthracene (abbreviation: CzPA), and 1,4-bis[4-(N-carbazolyl)phenyl]-2,3,5,6-tetraphenylbenzene.

Examples of the aromatic hydrocarbon include 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, and 2,5,8,11-tetra(tert-butyl)perylene.

As aromatic hydrocarbon having a vinyl skeleton, the following can be given for example: 4,4′-bis(2,2-diphenylvinyl)biphenyl (abbreviation: DPVBi), 9,10-bis[4-(2,2-diphenylvinyl)phenyl]anthracene (abbreviation: DPVPA), and the like.

Besides, there are pentacene, coronene, and the like, for example.

As the high molecular compound, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), poly[N,N′-bis(4-butylphenyl)-N,N′-bis(phenyl)benzidine] (abbreviation: Poly-TPD), or the like can be used.

Furthermore, a substance having any of a carbazole derivative, a dibenzofuran skeleton, a dibenzothiophene skeleton, or an anthracene skeleton can be favorably used as the hole-transport material in the composite material, for example. Moreover, a substance including any of the following can be used: an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With use of a substance including a N,N-bis(4-biphenyl)amino group, reliability of the light-emitting device can be improved.

Specific examples of the hole-transport material in the composite material include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II) (4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-diphenyl-4′-(2-naphthyl)-4″-{9-(4-biphenyl)carbazol}triphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(4-biphenylyl)-9,9′-spirobi[9H-fluoren]-2-amine (abbreviation: BBASF), N,N-bis([1,1′-biphenyl]-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi(9H-fluoren)-4-amine (abbreviation: oFBiSF), N-(4-biphenyl)-N-(dibenzofuran-4-yl)-9,9-dimethyl-9H-fluoren-2-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-9,9-dimethyl-N-[4-(9-phenyl-9H-carbazol-3-yl)phenyl]-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)9,9′-spirobi-9H-fluoren-2-amine, and N,N-bis(9,9-dimethyl-9H-fluoren-2-yl)-9,9′-spirobi-9H-fluoren-1-amine.

### [Example of Hole-Injection Material 3]

A composite material including a hole-transport material, a substance having an acceptor property, and a fluoride of an alkali metal or an alkaline earth metal can be used for the hole-injection material. In particular, a composite material in which the proportion of fluorine atoms is higher than or equal to 20% can be favorably used. Thus, the refractive index of the layer 111 can be reduced. A layer with a low refractive index can be formed inside the light-emitting device. Furthermore, the external quantum efficiency of the light-emitting device can be improved.

### <<Structure Example of Layer 105>>

The layer 105 includes a region sandwiched between the unit 103 and the electrode 102. For example, a material having an electron-injection property (electron-injection material) can be used for the layer 105. Specifically, a substance having a donor property can be used for the layer 105. Alternatively, a composite material in which a substance having a donor property is contained in the electron-transport material can be used for the layer 105. This can facilitate injection of electrons from the electrode 102, for example. Alternatively, the driving voltage of the light-emitting device can be reduced. Alternatively, a variety of conductive materials can be used for the electrode 102 regardless of the work function. Specifically, Al, Ag, ITO, indium oxide-tin oxide containing silicon or silicon oxide, and the like can be used for the electrode 102.

### [Electron-Injection Material 1]

For example, an alkali metal, an alkaline earth metal, a rare earth metal, or a compound thereof can be used for the substance having a donor property. Alternatively, an organic compound such as tetrathianaphthacene (abbreviation: TTN), nickelocene, or decamethylnickelocene can be used as the substance having a donor property.

Specifically, an alkali metal compound (including an oxide, a halide, and a carbonate), an alkaline earth metal compound (including an oxide, a halide, and a carbonate), a rare earth metal compound (including an oxide, a halide, and a carbonate), or the like can be used as the electron-injection material.

Specifically, lithium oxide, lithium fluoride (LiF), cesium fluoride (CsF), calcium fluoride (CaF₂), lithium carbonate, cesium carbonate, 8-hydroxyquinolinato-lithium (abbreviation: Liq), or the like can be used for the electron-injection material.

### [Electron-Injection Material 2]

For example, a composite material that includes a substance having an electron-transport property and any of an alkali metal, an alkaline earth metal, or a compound thereof can be used as the electron-injection material.

For example, an electron-transport material capable of being used for the unit 103 can be used for an electron-injection material.

Furthermore, for the electron-injection material, a material that includes a fluoride of an alkaline earth metal in a microcrystalline state and a substance having an electron-transport property and a material that includes a fluoride of an alkali metal in a microcrystalline state and a substance having an electron-transport property can be used.

It is particularly preferable to use a material that includes a fluoride of alkali metal or alkaline earth metal at 50 wt % or higher. Alternatively, an organic compound having a bipyridine skeleton can be favorably used. Thus, the refractive index of the layer 104 can be reduced. Alternatively, the external quantum efficiency of the light-emitting device can be improved.

### [Electron-Injection Material 3]

Furthermore, electride can be used for the electron-injection material. For example, a substance obtained by adding electrons to an oxide where calcium and aluminum are mixed can be used, for example, for the electron-injection material.

Note that this embodiment can be combined with any of the other embodiments in this specification as appropriate.

### Embodiment 4

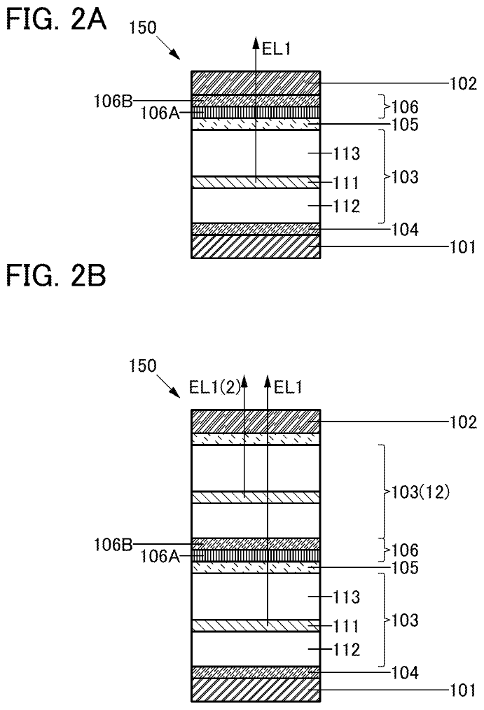

In this embodiment, a structure of a light-emitting device 150 of one embodiment of the present invention will be described with reference to FIG. 2A.

FIG. 2A is a cross-sectional view illustrating a structure of a light-emitting device of one embodiment of the present invention, which is different from the structure illustrated in FIG. 1.

### <Structure Example of Light-Emitting Device 150>

The light-emitting device 150 described in this embodiment includes the electrode 101, the electrode 102, the unit 103, and an intermediate layer 106 (see FIG. 2A). Note that part of the structure described in Embodiments 1 to 3 can be used for the light-emitting device 150, for example.

### <<Structure Example of Intermediate Layer 106>>

The intermediate layer 106 includes a region sandwiched between the unit 103 and the electrode 102. The intermediate layer 106 includes a layer 106A and a layer 106B.

### <<Structure Example of Layer 106A>>

The layer 106A includes a region sandwiched between the unit 103 and the layer 106B. Note that the layer 106A can be referred to, for example, an electron-relay layer.

For example, a substance having an electron-transport property can be used for the electron-relay layer. Accordingly, a layer that is on the anode side and in contact with the electron-relay layer can be distanced from a layer that is on the cathode side and in contact with the electron-relay layer. Alternatively, interaction between the layer that is on the anode side and in contact with the electron-relay layer and the layer that is on the cathode side and in contact with the electron-relay layer can be reduced. Alternatively, electrons can be smoothly supplied to the layer that is on the anode side and in contact with the electron-relay layer.

For example, a substance having an electron-transport property can be favorably used for the electron-relay layer. Specifically, the following can be favorably used for the electron-relay layer: a substance whose lowest unoccupied molecular orbital (LUMO) level is positioned between the LUMO level of the substance having an acceptor property in the composite material given as the hole-injection material and the LUMO level of the substance included in the layer that is on the cathode side and in contact with the electron-relay layer.

For example, a substance having an electron-transport property, which has a LUMO level in a range higher than or equal to −5.0 eV, preferably higher than or equal to −5.0 eV and lower than or equal to −3.0 eV, can be used as the electron-relay layer.

Specifically, a phthalocyanine-based material can be used for the electron-relay layer. In addition, a metal complex having a metal-oxygen bond and an aromatic ligand can be used for the electron-relay layer.

### <<Structure Example of Layer 106B>>

The layer 106B can be referred to, for example, as a charge-generation layer. The charge-generation layer has a function of supplying electrons to the anode side and supplying holes to the cathode side by applying voltages. Specifically, electrons can be supplied to the unit 103 that is positioned on the anode side.

For example, any of the composite material exemplified as the hole-injection material can be used for the charge-generation layer. In addition, for example, a stacked film in which a film including the composite material and a film including a hole-transport material are stacked can be used for the charge-generation layer.

Note that this embodiment can be combined with any of the other embodiments in this specification as appropriate.

### Embodiment 5

In this embodiment, a structure of a light-emitting device 150 of one embodiment of the present invention will be described with reference to FIG. 2B.

FIG. 2B is a cross-sectional view illustrating a structure of a light-emitting device of one embodiment of the present invention, which is different from those in FIG. 1 and FIG. 2A.

### <Structure Example of Light-Emitting Device 150>

The light-emitting device 150 described in this embodiment includes the electrode 101, the electrode 102, the unit 103, the intermediate layer 106, and a unit 103(12) (see FIG. 2(B)). Note that the light-emitting device 150 emits light EL1 and light EL1(2). A structure including the intermediate layer 106 and a plurality of units is referred to as a stacked light-emitting device or tandem light-emitting device in some cases. This structure enables high luminance emission while the current density is kept low. Alternatively, reliability can be improved. Alternatively, the driving voltage can be reduced in comparison with that of the light-emitting device with the same luminance. Alternatively, the power consumption can be reduced.

### <<Structure Example of Unit 103(12)>>

The unit 103(12) includes a region sandwiched between the intermediate layer 106 and the electrode 102.

The structure that can be used for the unit 103 can also be employed for the unit 103(12). In other words, the light-emitting device 150 includes a plurality of units that are stacked. Note that the number of stacked units is not limited to two and may be three or more.

The same structure as the unit 103 can be used for the unit 103(12). Alternatively, a structure different from the unit 103 can be used for the unit 103(12).

For example, a structure which exhibits a different emission color from that of the unit 103 can be employed for the unit 103(12). Specifically, the unit 103 emitting red light and green light and the unit 103(12) emitting blue light can be employed. With this structure, a light-emitting device emitting light of a desired color can be provided. Alternatively, a light-emitting device emitting white light can be provided, for example.

### <<Structure Example of Intermediate Layer 106>>

The intermediate layer 106 has a function of supplying electrons to one of the unit 103 and the unit 103(12) and supplying holes to the other. For example, the intermediate layer 106 described in Embodiment 4 can be used.

### <Fabrication Method of Light-Emitting Device 150>

For example, each of the electrode 101, the electrode 102, the unit 103, the intermediate layer 106, and the unit 103(12) can be formed by a dry process, a wet process, an evaporation method, a droplet discharging method, a coating method, a printing method, or the like. A formation method may differs between components of the device.

Specifically, the light-emitting device 150 can be manufactured with a vacuum evaporation machine, an ink-jet machine, a coating machine such as a spin coater, a gravure printing machine, an offset printing machine, a screen printing machine, or the like.

For example, the electrode can be formed by a wet process or a sol-gel method using a paste of a metal material. Specifically, an indium oxide-zinc oxide film can be formed by a sputtering method using a target obtained by adding indium zinc to indium oxide at a concentration higher than or equal to 1 wt % and lower than or equal to 20 wt %. Furthermore, an indium oxide film containing tungsten oxide and zinc oxide (IWZO) can be formed by a sputtering method using a target containing, with respect to indium oxide, tungsten oxide at a concentration higher than or equal to 0.5 wt % and lower than or equal to 5 wt % and zinc oxide at a concentration higher than or equal to 0.1 wt % and lower than or equal to 1 wt %.

Note that this embodiment can be combined with any of the other embodiments in this specification as appropriate.

### Embodiment 6

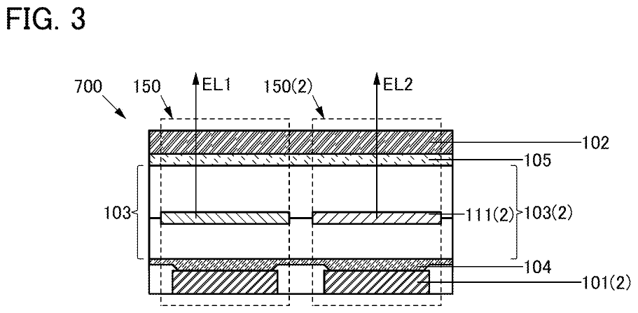

In this embodiment, a structure of a light-emitting panel 700 of one embodiment of the present invention will be described with reference to FIG. 3.

### <Structure Example of Light-Emitting Panel 700>

The light-emitting panel 700 described in this embodiment includes a light-emitting device 150 and a light-emitting device 150(2). The light-emitting device 150 emits light EL1, and the light-emitting device 150(2) emits light EL2.

For example, the light-emitting device described in any one of Embodiments 1 to 5 can be used for the light-emitting device 150.

### <Structure Example of Light-Emitting Device 150(2)>

The light-emitting device 150(2) described in this embodiment includes an electrode 101(2), the electrode 102, and a unit 103(2) (see FIG. 3).

### <<Structure Example of Unit 103(2)>>

The unit 103(2) includes a region sandwiched between the electrode 101(2) and the electrode 102. The unit 103(2) includes a layer 111(2).

The unit 103(2) have a single-layer structure or a stacked-layer structure. For example, the unit 103(2) can include a layer selected from functional layers such as a hole-transport layer, an electron-transport layer, a hole-injection layer, an electron-injection layer, a carrier-blocking layer, an exciton-blocking layer, and a charge-generation layer.

The unit 103(2) includes a region where electrons injected from one of the electrodes are recombined with holes injected from the other electrode. For example, a region where holes injected from the electrode 101(2) are recombined with electrons injected from the electrode 102 is provided.

### <<Structure Example 1 of Layer 111(2)>>

The layer 111(2) contains a light-emitting material and a host material. Note that the layer 111(2) can be referred to as a light-emitting layer. The layer 111(2) is preferably provided in a region where holes and electrons are recombined. Thus, energy generated by recombination of carriers is efficiently converted into light and emitted. Further, the layer 111(2) is preferably provided to be distanced from a metal used for the electrode or the like. Thus, a quenching phenomenon caused by the metal used for the electrode or the like can be inhibited.

For example, a fluorescent substance, a phosphorescent substance, or a substance exhibiting thermally activated delayed fluorescence (TADF) can be used for the light-emitting material. Thus, energy generated by recombination of carriers can be released as light from the light-emitting material.

### [Fluorescent Substance]

A fluorescent substance can be used as the layer 111(2). For example, the following fluorescent substances can be used for the layer 111(2). Note that the fluorescent substance that can be used for the layer 111(2) is not limited to the following, but a variety of known fluorescent substances can be used.

Specific examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N′-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-(pyrene-diyl)bis[(6,N-diphenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nb f(IV)-02), and 3,10-bis[N-(dibenzofuran-3-yl)-N-phenylamino]naphtho[2,3-b; 6,7-b′]bisbenzofuran (abbreviation: 3,10FrA2Nbf(IV)-02).

In particular, a condensed aromatic diamine compound typified by a pyrenediamine compound such as 1,6FLPAPrn, 1,6mMemFLPAPrn, or 1,6BnfAPrn-03 is preferable because of their high hole-trapping properties, high emission efficiency, and high reliability.

### [Phosphorescent Substance 1]

A phosphorescent substance can also be used for the layer 111(2). For example, the following phosphorescent substances can be used for the layer 111(2). Note that the phosphorescent substance that can be used for the layer 111(2) is not limited to the following, but a variety of known phosphorescent substances can be used.

Specifically, an organometallic iridium complex having a 4H-triazole skeleton, or the like can be used for the layer 111(2). Specifically, tris{2-[5-(2-methylphenyl)-4-(2,6-dimethylpyridin-3-yl)-4H-1,2,4-triazol-3-yl-κN2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

Alternatively, an organometallic iridium complex having a 1H-triazole skeleton, or the like can be used. Specifically, tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato]iridium(III) (abbreviation: [Ir(Prptz1-Me)₃]), or the like can be used.

Alternatively, an organometallic iridium complex having an imidazole skeleton or the like can be used. Specifically, fac-tris[1-(2,6-diisopropylphenyl)-2-phenyl-1H-imidazole]iridium(III) (abbreviation: [Ir(iPrpmi)₃]), tris[3-(2,6-dimethylphenyl)-7-methylimidazo[1,2-f]phenanthridinato]iridium(III) (abbreviation: [Ir(dmpimpt-Me)₃]), or the like can be used.

Alternatively, an organometallic iridium complex having a phenylpyridine derivative with an electron-withdrawing group as a ligand, or the like can be used. Specific examples include bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: Ir(CF₃ppy)₂(pic)), and bis[2-(4′,6′-difluorophenyl)pyridinato-N,C^{2′}]iridium(III) acetylacetonate (abbreviation: FIr(acac)).

These substances are compounds exhibiting blue phosphorescence and having an emission wavelength peak at 440 nm to 520 nm.

### [Fluorescent Substance 2]

For example, an organometallic iridium complex having a pyrimidine skeleton or the like can be used for the layer 111(2). Specifically, the followings can be used: tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis(4,6-diphenylpyrimidinato)iridium(III) (abbreviation: [Ir(dppm)₂(acac)]), or the like.

For example, an organometallic iridium complex having a pyrazine skeleton or the like can be used. Specifically, the followings can be used: (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), or the like.

For example, an organometallic iridium complex having a pyridine skeleton or the like can also be used. Specifically, the following can be used: tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d3-methyl-(2-pyridinyl-κN)benzofuro[2,3-b]pyridine-κC]bis[2-(5-d₃-methyl-2-pyridinyl-κN)phenyl-κ]iridium(III) (abbreviation: [Ir(5mppr-d3)₂(mbfpypy-d3)]), [2-d3-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d3)]), or the like.

For example, a rare earth metal complex or the like can also be used. Specifically, tris(acetylacetonato) (monophenanthroline)terbium(III) (abbreviation: Tb(acac)₃(Phen)) or the like can be given.

These are compounds that mainly exhibit green phosphorescence and have an emission wavelength peak at 500 nm to 600 nm. Note that an organometallic iridium complex having a pyrimidine skeleton has distinctively high reliability or emission efficiency and thus is particularly preferable.

### [Fluorescent Substance 3]

For example, an organometallic iridium complex having a pyrimidine skeleton or the like can be used for the layer 111(2). Specifically, (diisobutyrylmethanato)bis[4,6-bis(3-methylphenyl)pyrimidinato]iridium(III) (abbreviation: Ir(5mdppm)₂(dibm)), bis[4,6-bis(3-methylphenyl)pyrimidinato](dipivaloylmethanato)iridium(III) (abbreviation: Ir(5mdppm)₂(dpm)), bis[4,6-di(naphthalen-1-yl)pyrimidinato](dipivaloylmethanato)iridium(III) (abbreviation: Ir(d1pm)₂(dpm)), or the like can be used.

For example, an organometallic iridium complex having a pyrazine skeleton or the like can be used. Specifically, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: Ir(tppr)₂(dpm)), (acetylacetonato)bis[2,3-bis(4-fluorophenyl)quinoxalinato]iridium(III) (abbreviation: [Ir(Fdpq)₂(acac)]), or the like can be used.

For example, an organometallic iridium complex having a pyridine skeleton or the like can also be used. Specifically, tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), or the like can be used.

For example, a platinum complex or the like can also be used. Specifically, 2,3,7,8,12,13,17,18-octaethyl-21H,23H-porphyrin platinum(II) (abbreviation: PtOEP) or the like can be used.

For example, a rare earth metal complex or the like can also be used. Specifically, tris(1,3-diphenyl-1,3-propanedionato) (monophenanthroline)europium(III) (abbreviation: Eu(DBM)₃(Phen)), tris[1-(2-thenoyl)-3,3,3-trifluoroacetonato] (monophenanthroline)europium(III) (abbreviation: Eu(TTA)₃(Phen)), or the like can be used.

These compounds emit red phosphorescence having an emission peak at 600 nm to 700 nm. Furthermore, the organometallic iridium complexes having a pyrazine skeleton can provide red light emission with chromaticity favorably used for display devices.

### [Substance Exhibiting Thermally Activated Delayed Fluorescence (TADF)]

A substance exhibiting thermally activated delayed fluorescence (TADF), which is also referred to as TADF material, can be used for the layer 111(2). For example, any of the TADF materials given below can be used for the layer 111(2). Note that without being limited thereto, a variety of known TADF materials can be used for the layer 111(2).

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used for the TADF material.

Specifically, the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), or the like.

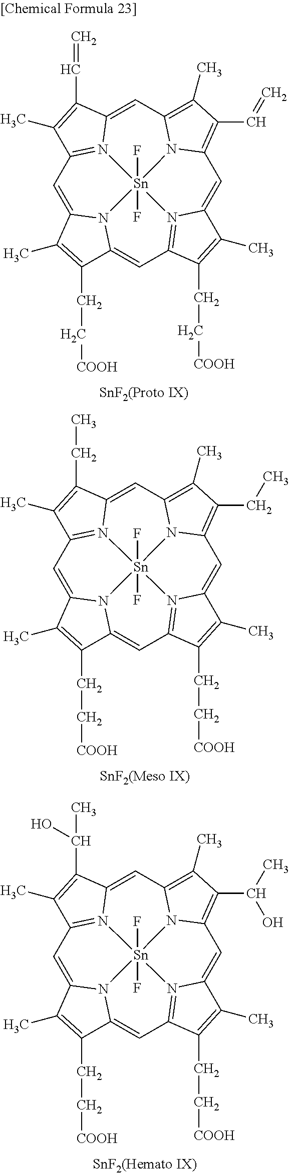

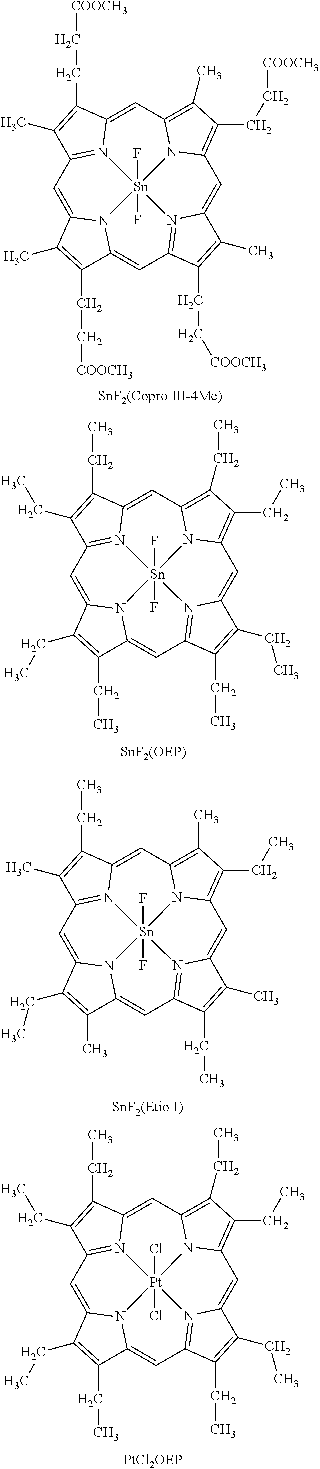

Furthermore, a heterocyclic compound including one or both of a π-electron rich heteroaromatic ring and a π-electron deficient heteroaromatic ring can be used, for example, for the TADF material.

Specifically, the following compounds whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazine-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TP T), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H, 10′H-spiro[acridin-9,9′-anthracen]-10′-one (abbreviation: ACRSA), or the like can be used.

Such a heterocyclic compound is preferable because of having excellent electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferred because of their high stability and reliability. In particular, a benzofuropyrimidine skeleton, a benzothienopyrimidine skeleton, a benzofuropyrazine skeleton, and a benzothienopyrazine skeleton are preferred because of their high accepting properties and high reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane and boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used.

As described above, a π-electron deficient skeleton and a π-electron rich skeleton can be used instead of at least one of the π-electron deficient heteroaromatic ring and the π-electron rich heteroaromatic ring.

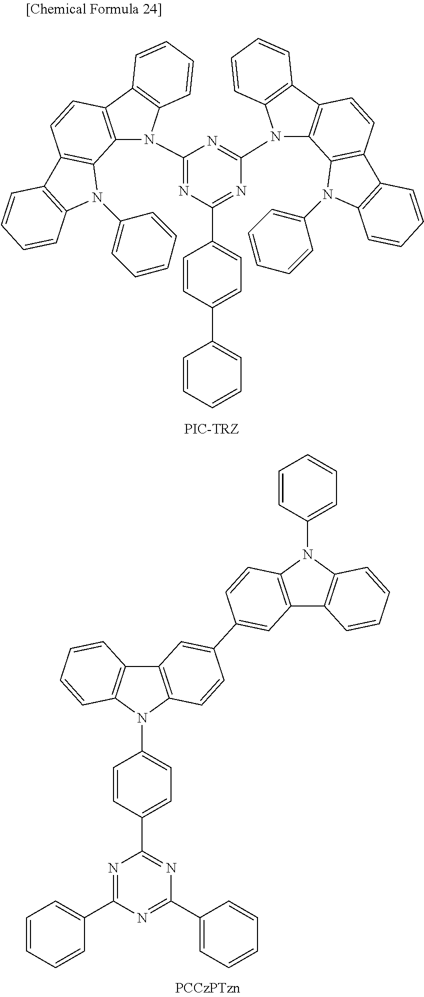 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

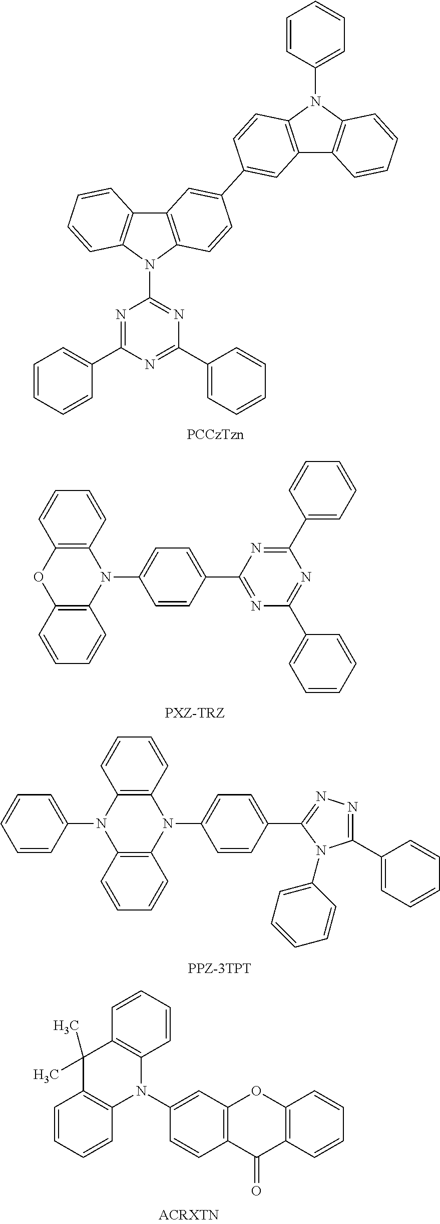 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21]

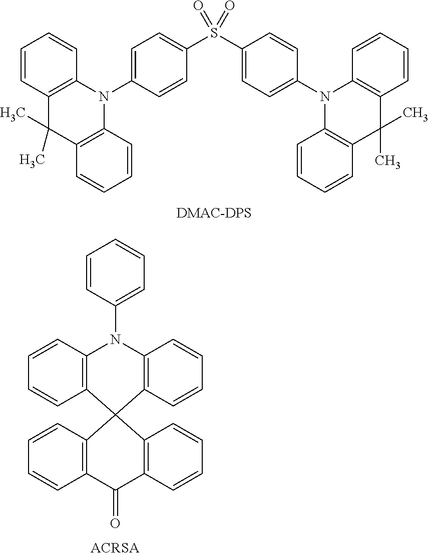 [SMILES: CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Note that a TADF material is a material having a small difference between the S1 level and the T1 level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into luminescence.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

When a TADF material is used as the light-emitting substance, the S1 level of the host material is preferably higher than that of the TADF material. In addition, the T1 level of the host material is preferably higher than that of the TADF material.

### <<Structure Example 2 of Layer 111(2)>>

A material having a carrier transport property can be used for a host material. For example, a material having a hole-transport material (hole-transport material), a material having an electron-transport material (electron-transport material), a TADF material, a material having an anthracene skeleton, a mixed material, or the like can be used for the host material.

### [Hole-Transport Material]

For example, a hole-transport material capable of being used for the layer 112 can be used from the layer 111. Specifically, the hole-transport material described in Embodiment 2 can be used for the host material.

### [Electron-Transport Material]

For example, an electron-transport material capable of being used for the layer 113 can be used for the layer 111. Specifically, the electron-transport material described in Embodiment 2 can be used for the host material.

### [TADF Material]

Any of the TADF materials given the above can be used for the host material. When the TADF material is used for the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S1 level of the TADF material is preferably higher than that of the fluorescent substance in order that high emission efficiency be achieved. Furthermore, the T1 level of the TADF material is preferably higher than the S1 level of the fluorescent substance. Therefore, the T1 level of the TADF material is preferably higher than that of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton which causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transportation or carrier recombination.

Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

### [Material Having Anthracene Skeleton]

In the case where a fluorescent substance is used as the light-emitting substance, a material having an anthracene skeleton is favorably used as the host material. The use of a substance having an anthracene skeleton as the host material for the fluorescent substance makes it possible to obtain a light-emitting layer with high emission efficiency and high durability.

Among the substances having an anthracene skeleton, a substance having a diphenylanthracene skeleton, in particular, a substance having a 9,10-diphenylanthracene skeleton, is chemically stable and thus is preferably used as the host material. The host material preferably has a carbazole skeleton because the hole-injection and hole-transport properties are improved; further preferably, the host material has a benzocarbazole skeleton in which a benzene ring is further condensed to carbazole because the HOMO level thereof is shallower than that of carbazole by approximately 0.1 eV and thus holes enter the host material easily.

In particular, the host material preferably has a dibenzocarbazole skeleton because the HOMO level thereof is shallower than that of carbazole by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzo fluorene skeleton may be used.

Examples of a substance having an anthracene skeleton include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), and 9-(1-naphthyl)-10-[4-(2-naphthyl)phenyl]anthracene (abbreviation: αN-βNPAnth).

In particular, CzPA, cgDBCzPA, 2mBnfPPA, and PCzPA have excellent characteristics.

### [Structure Example 1 of Mixed Material]

A material in which a plurality of kinds of substances are mixed can be used as the host material. For example, a material in which an electron-transport material and a hole-transport material are mixed can be favorably used for the host material. By mixing the electron-transport material with the hole-transport material, the carrier transport property of the layer 111(2) can be easily adjusted and a recombination region can be easily controlled. The weight ratio of the content of hole-transport material contained in the mixed material to of the electron-transport material in the mixed material may be 1:19 or more and 19:1 or less.

### [Structure Example 2 of Mixed Material]

In addition, a material mixed with a phosphorescent substance is can be used as the host material. When a fluorescent substance is used as the light-emitting substance, a phosphorescent substance can be used as an energy donor for supplying excitation energy to the fluorescent substance.

A mixed material containing a material to form an exciplex can be used for the host material. For example, a material in which an emission spectrum of a formed exciplex overlaps with a wavelength of the absorption band on the lowest energy side of the light-emitting substance in can be used for the host material. This enables smooth the energy transfer and improve emission efficiency. Alternatively, the driving voltage can be suppressed.

Note that at least one of the materials forming an exciplex may be a phosphorescent substance. In this case, triplet excitation energy can be efficiently converted into singlet excitation energy by reverse intersystem crossing.

Combination of an electron-transport material and a hole-transport material whose HOMO level is higher than or equal to that of the electron-transport material is preferable for forming an exciplex efficiently. In addition, the LUMO level of the hole-transport material is preferably higher than or equal to the LUMO level of the electron-transport material. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the hole-transport material and the electron-transport material are mixed is shifted to the longer wavelength side than the emission spectra of each of the materials (or has another peak on the longer wavelength side) observed by comparison of the emission spectra of the hole-transport material, the electron-transport material, and the mixed film of these materials, for example. Alternatively, the formation of an exciplex can be confirmed by a difference in transient response, such as a phenomenon in which the transient PL lifetime of the mixed film has more long lifetime components or has a larger proportion of delayed components than that of each of the materials, observed by comparison of transient photoluminescence (PL) of the hole-transport material, the electron-transport material, and the mixed film of the materials. The transient PL can be rephrased as transient electroluminescence (EL). That is, the formation of an exciplex can also be confirmed by a difference in transient response observed by comparison of the transient EL of the hole-transport material, the electron-transport material, and the mixed film of the materials.

Note that this embodiment can be combined with any of the other embodiments in this specification as appropriate.

### Embodiment 7

In this embodiment, a light-emitting apparatus including the light-emitting device described in any one of Embodiments 1 to 6 will be described.

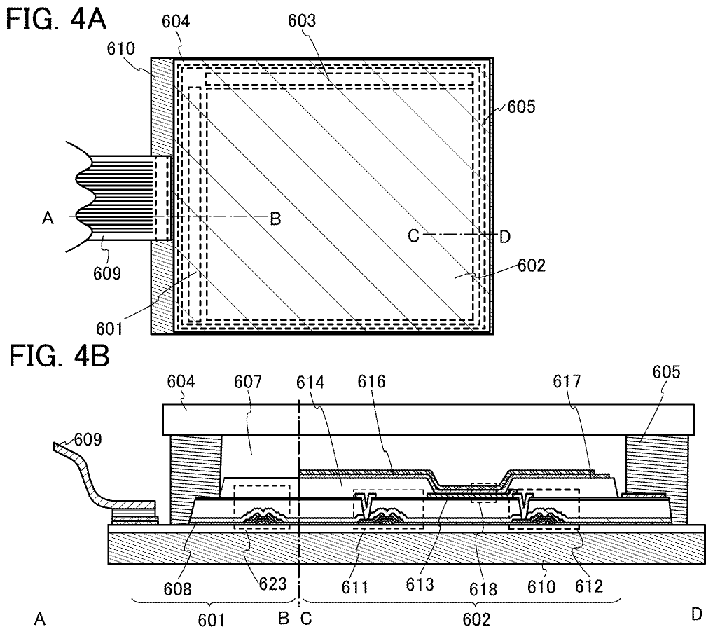

In this embodiment, the light-emitting apparatus fabricated using the light-emitting device described in any one of Embodiments 1 to 6 is described with reference to FIGS. 4A and 4B. Note that FIG. 4A is a top view of the light-emitting apparatus and FIG. 4B is a cross-sectional view taken along the lines A-B and C-D in FIG. 4A. This light-emitting apparatus includes a driver circuit portion (a source line driver circuit 601), a pixel portion 602, and another driver circuit portion (a gate line driver circuit 603), which are to control light emission of a light-emitting device and illustrated with dotted lines. Reference numeral 604 denotes a sealing substrate; 605, a sealing material; and 607, a space surrounded by the sealing material 605.

A lead wiring 608 is a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The light-emitting apparatus in the present specification includes, in its category, not only the light-emitting apparatus itself but also the light-emitting apparatus provided with the FPC or the PWB.

Next, a cross-sectional structure is described with reference to FIG. 4B. The driver circuit portions and the pixel portion are formed over an element substrate 610; here, the source line driver circuit 601, which is a driver circuit portion, and one pixel in the pixel portion 602 are illustrated.

The element substrate 610 may be a substrate containing glass, quartz, an organic resin, a metal, an alloy, or a semiconductor or a plastic substrate formed of fiber reinforced plastics (FRP), poly(vinyl fluoride) (PVF), polyester, an acrylic resin, or the like.

The structure of transistors used in pixels or driver circuits are not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In-Ga-Zn-based metal oxide, may be used.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferable that a semiconductor having crystallinity be used, in which case deterioration of the transistor characteristics can be suppressed.

Here, an oxide semiconductor is preferably used for semiconductor devices such as the transistors provided in the pixels or driver circuits and transistors used for touch sensors described later, and the like. In particular, an oxide semiconductor having a wider band gap than silicon is preferably used. When an oxide semiconductor having a wider band gap than silicon is used, off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed in each display region is maintained. As a result, an electronic device with extremely low power consumption can be obtained.

For stable characteristics of the transistor, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

Note that an FET 623 is illustrated as a transistor formed in the source line driver circuit 601. In addition, the driver circuit may be formed with any of a variety of circuits such as a CMOS circuit, a PMOS circuit, or an NMOS circuit. Although a driver integrated type in which the driver circuit is formed over the substrate is illustrated in this embodiment, the driver circuit is not necessarily formed over the substrate, and the driver circuit can be formed outside, not over the substrate.

The pixel portion 602 includes a plurality of pixels each including a switching FET 611, a current controlling FET 612, and a first electrode 613 electrically connected to a drain of the current controlling FET 612. One embodiment of the present invention is not limited to the structure. The pixel portion 602 may include three or more FETs and a capacitor in combination.

Note that an insulator 614 is formed to cover an end portion of the first electrode 613. Here, the insulator 614 can be formed using a positive photosensitive acrylic resin film.

In order to improve coverage with an EL layer or the like which is formed later, the insulator 614 is formed to have a curved surface with curvature at its upper or lower end portion. For example, in the case where a positive photosensitive acrylic resin is used for a material of the insulator 614, only the upper end portion of the insulator 614 preferably has a surface with a curvature radius (greater than or equal to 0.2 μm and less than or equal to 3 μm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material having a high work function is preferably used. For example, a single-layer film of an ITO film, an indium tin oxide film containing silicon, an indium oxide film containing zinc oxide at 2 wt % to 20 wt %, a titanium nitride film, a chromium film, a tungsten film, a Zn film, a Pt film, or the like, a stack of a titanium nitride film and a film containing aluminum as its main component, a stack of three layers of a titanium nitride film, a film containing aluminum as its main component, and a titanium nitride film, or the like can be used. The stacked-layer structure enables low wiring resistance, favorable ohmic contact, and a function as an anode.

The EL layer 616 is formed by any of a variety of methods such as an evaporation method using an evaporation mask, an inkjet method, and a spin coating method. The EL layer 616 has the structure described in any one of Embodiments 1 to 6. As another material included in the EL layer 616, a low molecular compound or a high molecular compound (including an oligomer or a dendrimer) may be used.

As a material used for the second electrode 617, which is formed over the EL layer 616 and functions as a cathode, a material having a low work function (e.g., Al, Mg, Li, and Ca, or an alloy or a compound thereof, such as MgAg, Mgln, and AlLi) is preferably used. In the case where light generated in the EL layer 616 passes through the second electrode 617, a stack including a thin metal film and a transparent conductive film (e.g., ITO, indium oxide containing zinc oxide at 2 wt % or higher and 20 wt % or lower, indium tin oxide containing silicon, or zinc oxide (ZnO)) is preferably used for the second electrode 617.

Note that the light-emitting device is formed with the first electrode 613, the EL layer 616, and the second electrode 617. The light-emitting device is the light-emitting device described in any one of Embodiments 1 to 6. In the light-emitting apparatus of this embodiment, the pixel portion, which includes a plurality of light-emitting devices, may include both the light-emitting device described in any one of Embodiments 1 to 6 and a light-emitting device having a different structure.

The sealing substrate 604 is attached to the element substrate 610 with the sealing material 605, so that a light-emitting device 618 is provided in a space 607 surrounded by the element substrate 610, the sealing substrate 604, and the sealing material 605. The space 607 may be filled with a filler, or may be filled with an inert gas (such as nitrogen or argon), or the sealing material. It is preferable that the sealing substrate be provided with a recessed portion and a drying agent be provided in the recessed portion, in which case degradation due to influence of moisture can be suppressed.

An epoxy-based resin or glass frit is preferably used for the sealing material 605. It is preferable that such a material not be permeable to moisture or oxygen as much as possible. As the sealing substrate 604, a glass substrate, a quartz substrate, or a plastic substrate formed of fiber reinforced plastics (FRP), poly(vinyl fluoride) (PVF), polyester, an acrylic resin, or the like can be used.

Although not illustrated in FIGS. 4A and 4B, a protective film may be provided over the second electrode. As the protective film, an organic resin film or an inorganic insulating film may be formed. The protective film may be formed so as to cover an exposed portion of the sealing material 605. The protective film may be provided so as to cover surfaces and side surfaces of the pair of substrates and exposed side surfaces of a sealing layer, an insulating layer, and the like.

The protective film can be formed using a material through which an impurity such as water does not permeate easily. Thus, diffusion of an impurity such as water from the outside into the inside can be effectively suppressed.

As a material of the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a deposition method with favorable step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

As described above, the light-emitting apparatus fabricated using the light-emitting device described in any one of Embodiments 1 to 6 can be obtained.

The light-emitting apparatus in this embodiment is fabricated using the light-emitting device described in any one of Embodiments 1 to 6 and thus can have favorable characteristics. Specifically, since the light-emitting device described in any one of Embodiments 1 to 6 has high emission efficiency, the light-emitting apparatus can achieve low power consumption.

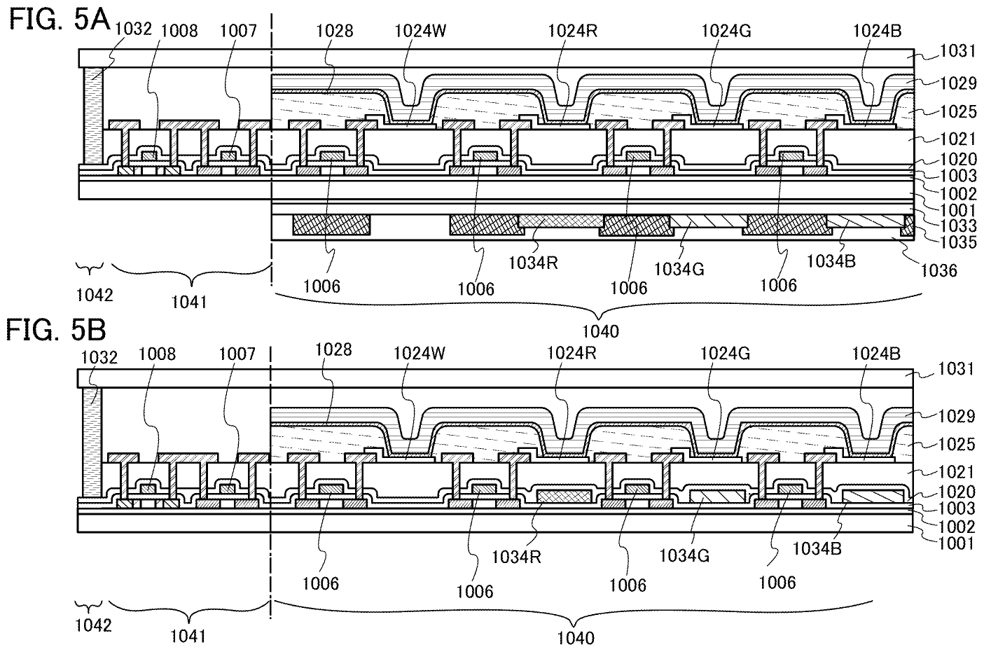

FIGS. 5A and 5B each illustrate an example of a light-emitting apparatus that includes a light-emitting device exhibiting white light emission, coloring layers (color filters) and the like to display a full-color image. In FIG. 5A, a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024W, 1024R, 1024G, and 1024B of light-emitting devices, a partition 1025, an EL layer 1028, a second electrode 1029 of the light-emitting devices, a sealing substrate 1031, a sealing material 1032, and the like are illustrated.

In FIG. 5A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is aligned and fixed to the substrate 1001. Note that the coloring layers and the black matrix 1035 are covered with an overcoat layer 1036. In FIG. 5A, light emitted from part of the light-emitting layer does not pass through the coloring layers, while light emitted from the other part of the light-emitting layer passes through the coloring layers. The light that does not pass through the coloring layers is white and the light that passes through any one of the coloring layers is red, green, or blue; thus, an image can be displayed using pixels of the four colors.

FIG. 5B illustrates an example in which the coloring layers (the red coloring layer 1034R, the green coloring layer 1034G, and the blue coloring layer 1034B) are provided between the gate insulating film 1003 and the first interlayer insulating film 1020. As in the structure, the coloring layers may be provided between the substrate 1001 and the sealing substrate 1031.

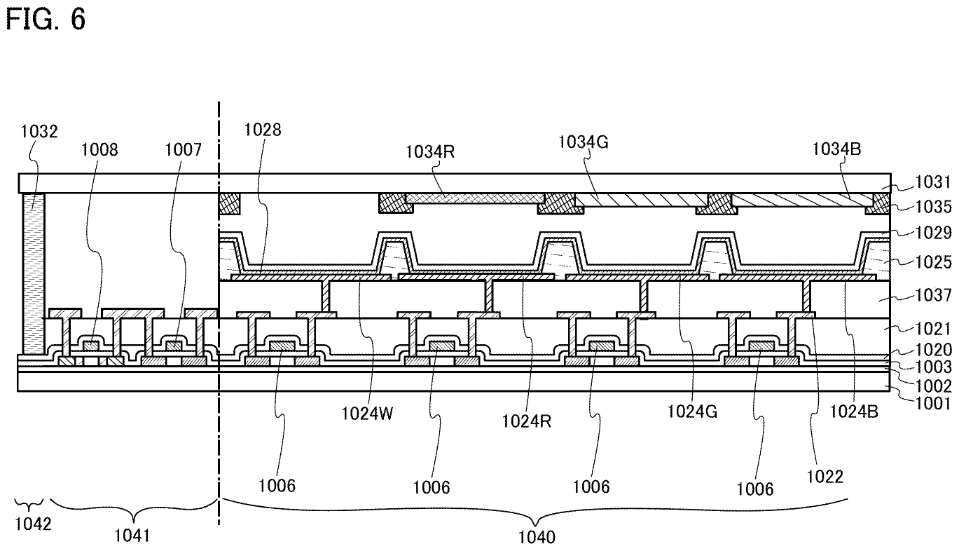

The above-described light-emitting apparatus has a structure in which light is extracted from the substrate 1001 side where FETs are formed (a bottom emission structure), but may have a structure in which light is extracted from the sealing substrate 1031 side (a top emission structure). FIG. 6 is a cross-sectional view of a light-emitting apparatus having a top emission structure. In this case, a substrate which does not transmit light can be used as the substrate 1001. The process up to the step of forming a connection electrode which connects the FET and the anode of the light-emitting device is performed in a manner similar to that of the light-emitting apparatus having a bottom emission structure. Then, a third interlayer insulating film 1037 is formed to cover an electrode 1022. This insulating film may have a planarization function. The third interlayer insulating film 1037 can be formed using a material similar to that of the second interlayer insulating film, and can alternatively be formed using any of other known materials.

The first electrodes 1024W, 1024R, 1024G, and 1024B of the light-emitting devices each serve as an anode here, but may serve as a cathode. Furthermore, in the case of the top-emission light-emitting apparatus illustrated in FIG. 6, the first electrodes are preferably reflective electrodes. The EL layer 1028 is formed to have a structure similar to the structure of the unit 103, which is described in any one of Embodiments 1 to 6, with which white light emission can be obtained.

In the case of a top emission structure as illustrated in FIG. 6, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 which is positioned between pixels. The coloring layers (the red coloring layer 1034R, the green coloring layer 1034G, and the blue coloring layer 1034B) or the black matrix may be covered with the overcoat layer 1036. Note that a light-transmitting substrate is used as the sealing substrate 1031. Although an example in which full color display is performed using four colors of red, green, blue, and white is shown here, there is no particular limitation and full color display using four colors of red, yellow, green, and blue or three colors of red, green, and blue may be performed.

In the light-emitting apparatus having a top emission structure, a microcavity structure can be favorably employed. A light-emitting device with a microcavity structure is formed with use of a reflective electrode as the first electrode and a semi-transmissive and semi-reflective electrode as the second electrode. The light-emitting device with a microcavity structure includes at least an EL layer between the reflective electrode and the semi-transmissive and semi-reflective electrode, which includes at least a light-emitting layer serving as a light-emitting region.

Note that the reflective electrode has a visible light reflectivity higher than or equal to 40% and lower than or equal to 100%, preferably higher than or equal to 70% and lower than or equal to 100%, and a resistivity of 1×10⁻² Ωcm or lower. In addition, the semi-transmissive and semi-reflective electrode has a visible light reflectivity higher than or equal to 20% and lower than or equal to 80%, preferably higher than or equal to 40% and lower than or equal to 70%, and a resistivity of 1×10⁻² Ωcm or lower.

Light emitted from the light-emitting layer included in the EL layer is reflected and resonated by the reflective electrode and the semi-transmissive and semi-reflective electrode.

In the light-emitting device, by changing thicknesses of the transparent conductive film, the composite material, the carrier-transport material, or the like, the optical path length between the reflective electrode and the semi-transmissive and semi-reflective electrode can be changed. Thus, light with a wavelength that is resonated between the reflective electrode and the semi-transmissive and semi-reflective electrode can be intensified while light with a wavelength that is not resonated therebetween can be attenuated.

Note that light that is reflected back by the reflective electrode (first reflected light) considerably interferes with light that directly enters the semi-transmissive and semi-reflective electrode from the light-emitting layer (first incident light). For this reason, the optical path length between the reflective electrode and the light-emitting layer is preferably adjusted to (2n−1)λ/4 (n is a natural number of 1 or larger and λ is a wavelength of color to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer. The tandem light-emitting device described above may be combined with a plurality of EL layers; for example, a light-emitting device may have a structure in which a plurality of EL layers are provided, a charge-generation layer is provided between the EL layers, and each EL layer includes a plurality of light-emitting layers or a single light-emitting layer.

With the microcavity structure, emission intensity with a specific wavelength in the front direction can be increased, whereby power consumption can be reduced. Note that in the case of a light-emitting apparatus which displays images with subpixels of four colors, red, yellow, green, and blue, the light-emitting apparatus can have favorable characteristics because the luminance can be increased owing to yellow light emission and each subpixel can employ a microcavity structure suitable for wavelengths of the corresponding color.

The light-emitting apparatus in this embodiment is fabricated using the light-emitting device described in any one of Embodiments 1 to 6 and thus can have favorable characteristics. Specifically, since the light-emitting device described in any one of Embodiments 1 to 6 has high emission efficiency, the light-emitting apparatus can achieve low power consumption.

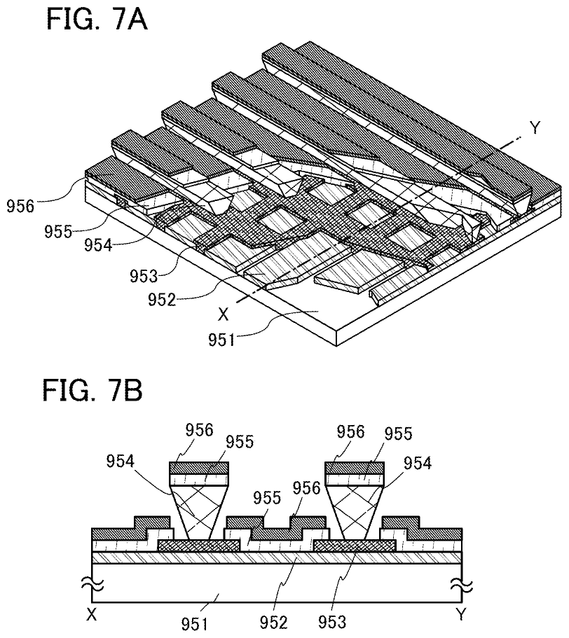

An active matrix light-emitting apparatus is described above, whereas a passive matrix light-emitting apparatus is described below. FIGS. 7A and 7B illustrate a passive matrix light-emitting apparatus manufactured using the present invention. Note that FIG. 7A is a perspective view of the light-emitting apparatus, and FIG. 7B is a cross-sectional view taken along the line X-Y in FIG. 7A. In FIGS. 7A and 7B, over a substrate 951, an EL layer 955 is provided between an electrode 952 and an electrode 956. An end portion of the electrode 952 is covered with an insulating layer 953. A partition layer 954 is provided over the insulating layer 953. The sidewalls of the partition layer 954 are aslope such that the distance between both sidewalls is gradually narrowed toward the surface of the substrate. In other words, a cross section taken along the direction of the short side of the partition layer 954 is trapezoidal, and the lower side (a side of the trapezoid which is parallel to the surface of the insulating layer 953 and is in contact with the insulating layer 953) is shorter than the upper side (a side of the trapezoid which is parallel to the surface of the insulating layer 953 and is not in contact with the insulating layer 953). The partition layer 954 thus provided can prevent defects in the light-emitting device due to static electricity or others. The passive-matrix light-emitting apparatus also includes the light-emitting device described in any one of Embodiments 1 to 6; thus, the light-emitting apparatus can have high reliability or low power consumption.

Since many minute light-emitting devices arranged in a matrix in the light-emitting apparatus described above can each be controlled, the light-emitting apparatus can be suitably used as a display device for displaying images.

This embodiment can be freely combined with any of the other embodiments.

### Embodiment 8

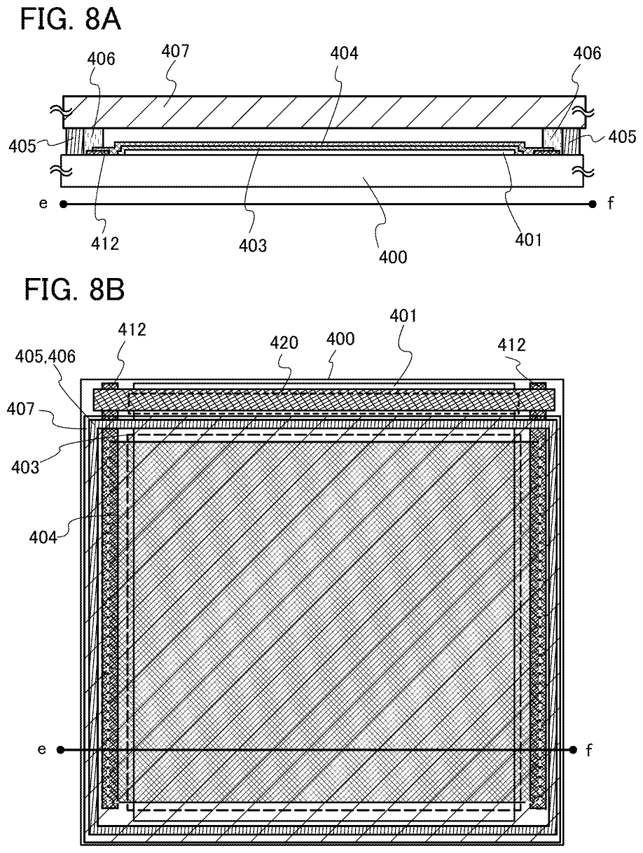

In this embodiment, an example in which the light-emitting device described in any one of Embodiments 1 to 6 is used for a lighting device will be described with reference to FIGS. 8A and 8B. FIG. 8B is a top view of the lighting device, and FIG. 8A is a cross-sectional view taken along the line e-f in FIG. 8B.

In the lighting device in this embodiment, a first electrode 401 is formed over a substrate 400 which is a support and has a light-transmitting property. The first electrode 401 corresponds to the electrode 101 in any one of Embodiments 1 to 6. When light is extracted from the first electrode 401 side, the first electrode 401 is formed using a material having a light-transmitting property.

A pad 412 for applying voltage to a second electrode 404 is provided over the substrate 400.

An EL layer 403 is formed over the first electrode 401. The structure of the EL layer 403 corresponds to, for example, the structure of the unit 103 in any one of Embodiments 1 to 6, or the structure in which the unit 103(2), the layer 104, the layer 105, and the intermediate layer 106 are combined. Refer to the descriptions for the structure.

The second electrode 404 is formed to cover the EL layer 403. The second electrode 404 corresponds to the electrode 102 in any one of Embodiments 1 to 6. The second electrode 404 is formed using a material having high reflectance when light is extracted from the first electrode 401 side. The second electrode 404 is connected to the pad 412, whereby voltage is applied.

As described above, the lighting device described in this embodiment includes a light-emitting device including the first electrode 401, the EL layer 403, and the second electrode 404. Since the light-emitting device is a light-emitting device with high emission efficiency, the lighting device in this embodiment can be a lighting device having low power consumption.

The substrate 400 provided with the light-emitting device having the above structure is fixed to a sealing substrate 407 with sealing materials 405 and 406 and sealing is performed, whereby the lighting device is completed. It is possible to use only either the sealing material 405 or the sealing material 406. The inner sealing material 406 (not illustrated in FIG. 8B) can be mixed with a desiccant that enables moisture to be adsorbed, which results in improved reliability.

When parts of the pad 412 and the first electrode 401 are extended to the outside of the sealing materials 405 and 406, the extended parts can serve as external input terminals. An IC chip 420 mounted with a converter or the like may be provided over the external input terminals.

The lighting device described in this embodiment includes as an EL element the light-emitting device described in any one of Embodiments 1 to 6; thus, the lighting device can consume less power.

### Embodiment 9

In this embodiment, examples of electronic devices each including the light-emitting device described in any one of Embodiments 1 to 6 will be described. The light-emitting device described in any one of Embodiments 1 to 6 has high emission efficiency and low power consumption. As a result, the electronic devices described in this embodiment can each include a light-emitting portion having low power consumption.

Examples of the electronic device including the above light-emitting device include television devices (also referred to as TV or television receivers), monitors for computers and the like, digital cameras, digital video cameras, digital photo frames, cellular phones (also referred to as mobile phones or mobile phone devices), portable game machines, portable information terminals, audio playback devices, and large game machines such as pachinko machines. Specific examples of these electronic devices are shown below.

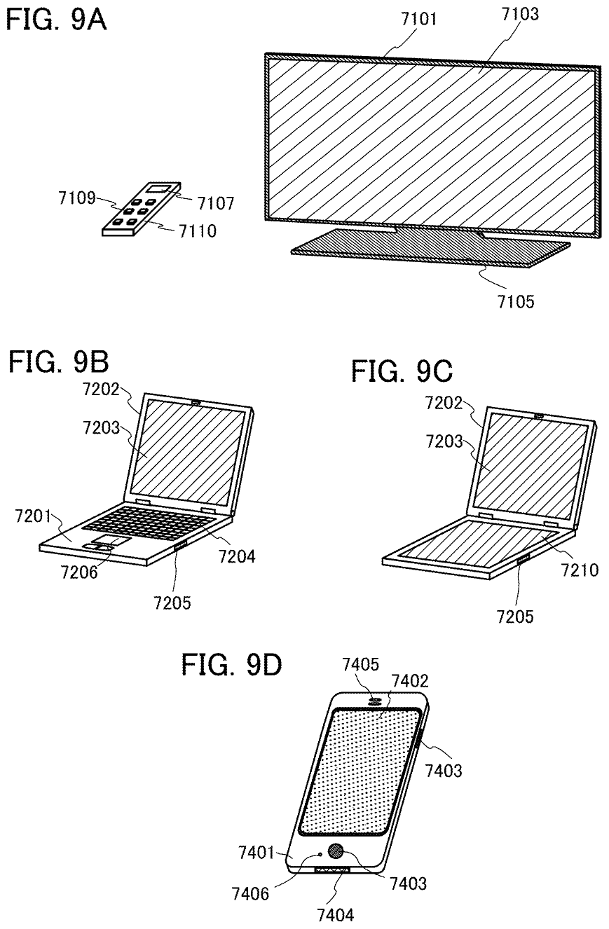

FIG. 9A illustrates an example of a television device. In the television device, a display portion 7103 is incorporated in a housing 7101. Here, the housing 7101 is supported by a stand 7105. Images can be displayed on the display portion 7103, and in the display portion 7103, the light-emitting devices described in any one of Embodiments 1 to 6 are arranged in a matrix.

The television device can be operated with an operation switch of the housing 7101 or a separate remote controller 7110. With operation keys 7109 of the remote controller 7110, channels or volume can be controlled and images displayed on the display portion 7103 can be controlled. Furthermore, the remote controller 7110 may be provided with a display portion 7107 for displaying data output from the remote controller 7110.

Note that the television device is provided with a receiver, a modem, or the like. With use of the receiver, a general television broadcast can be received. Moreover, when the television device is connected to a communication network with or without wires via the modem, one-way (from a sender to a receiver) or two-way (between a sender and a receiver or between receivers) data communication can be performed.

FIG. 9B illustrates a computer, which includes a main body 7201, a housing 7202, a display portion 7203, a keyboard 7204, an external connection port 7205, a pointing device 7206, and the like. Note that this computer is fabricated using the light-emitting devices that are described in any one of Embodiments 1 to 6 and arranged in a matrix in the display portion 7203. The computer illustrated in FIG. 9B may have a structure illustrated in FIG. 9C. A computer illustrated in FIG. 9C is provided with a second display portion 7210 instead of the keyboard 7204 and the pointing device 7206. The second display portion 7210 is a touch panel, and input operation can be performed by touching display for input on the second display portion 7210 with a finger or a dedicated pen. The second display portion 7210 can also display images other than the display for input. The display portion 7203 may also be a touch panel. Connecting the two screens with a hinge can prevent troubles; for example, the screens can be prevented from being cracked or broken while the computer is being stored or carried.

FIG. 9D illustrates an example of a portable terminal. A cellular phone is provided with a display portion 7402 incorporated in a housing 7401, operation buttons 7403, an external connection port 7404, a speaker 7405, a microphone 7406, and the like. Note that the cellular phone has the display portion 7402 including the light-emitting devices described in any one of Embodiments 1 to 6 and arranged in a matrix.

When the display portion 7402 of the portable terminal illustrated in FIG. 9D is touched with a finger or the like, data can be input into the portable terminal. In this case, operations such as making a call and creating an e-mail can be performed by touching the display portion 7402 with a finger or the like.

The display portion 7402 has mainly three screen modes. The first mode is a display mode mainly for displaying images. The second mode is an input mode mainly for inputting information such as text. The third mode is a display-and-input mode in which the two modes, the display mode and the input mode, are combined.

For example, in the case of making a call or creating an e-mail, a text input mode mainly for inputting text is selected for the display portion 7402 so that text displayed on the screen can be input. In this case, it is preferable to display a keyboard or number buttons on almost the entire screen of the display portion 7402.

When a sensing device including a sensor such as a gyroscope sensor or an acceleration sensor for detecting inclination is provided inside the portable terminal, display on the screen of the display portion 7402 can be automatically changed in direction by determining the orientation of the portable terminal (whether the portable terminal is placed horizontally or vertically).

The screen modes are switched by touching the display portion 7402 or operating the operation buttons 7403 of the housing 7401. Alternatively, the screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal sensed by an optical sensor in the display portion 7402 is sensed, the screen mode may be controlled so as to be switched from the input mode to the display mode.

The display portion 7402 may also function as an image sensor. For example, an image of a palm print, a fingerprint, or the like is taken when the display portion 7402 is touched with the palm or the finger, whereby personal authentication can be performed. Furthermore, by providing a backlight or a sensing light source which emits near-infrared light in the display portion, an image of a finger vein, a palm vein, or the like can be taken.

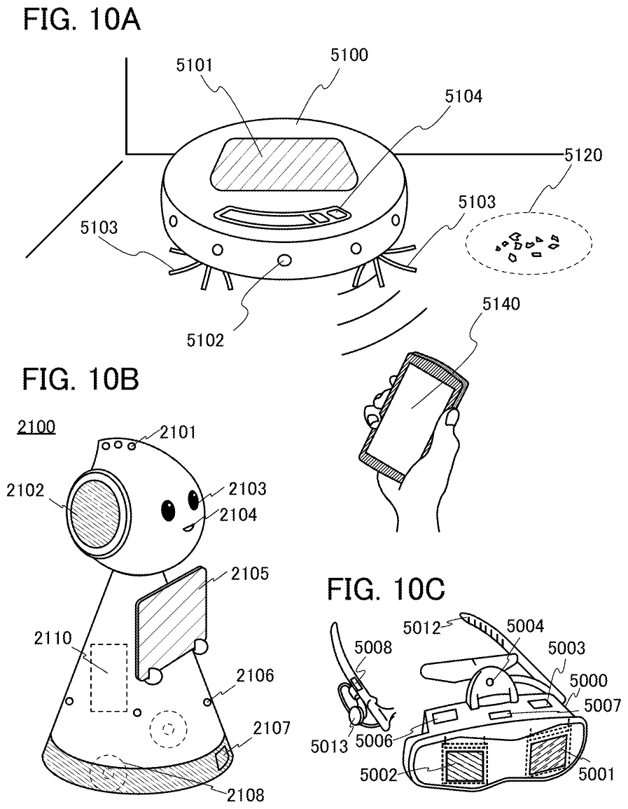

FIG. 10A is a schematic view illustrating an example of a cleaning robot.

A cleaning robot 5100 includes a display 5101 on its top surface, a plurality of cameras 5102 on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. The cleaning robot 5100 has a wireless communication means.

The cleaning robot 5100 is self-propelled, detects dust 5120, and sucks up the dust through the inlet provided on the bottom surface.

The cleaning robot 5100 can determine whether there is an obstacle such as a wall, furniture, or a step by analyzing images taken by the cameras 5102. When the cleaning robot 5100 detects an object that is likely to be caught in the brush 5103 (e.g., a wire) by image analysis, the rotation of the brush 5103 can be stopped.

The display 5101 can display the remaining capacity of a battery, the amount of collected dust, and the like. The display 5101 may display a path on which the cleaning robot 5100 has run. The display 5101 may be a touch panel, and the operation buttons 5104 may be provided on the display 5101.

The cleaning robot 5100 can communicate with a portable electronic device 5140 such as a smartphone. The portable electronic device 5140 can display images taken by the cameras 5102. Accordingly, an owner of the cleaning robot 5100 can monitor his/her room even when the owner is not at home. The owner can also check the display on the display 5101 by the portable electronic device 5140 such as a smartphone.

The light-emitting apparatus of one embodiment of the present invention can be used for the display 5101.

A robot 2100 illustrated in FIG. 10B includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 also has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 10C illustrates an example of a goggle-type display. The goggle-type display includes, for example, a housing 5000, a display portion 5001, a speaker 5003, an LED lamp 5004, a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, a display portion 5002, a support 5012, and an earphone 5013.

The light-emitting apparatus of one embodiment of the present invention can be used for the display portion 5001 and the display portion 5002.

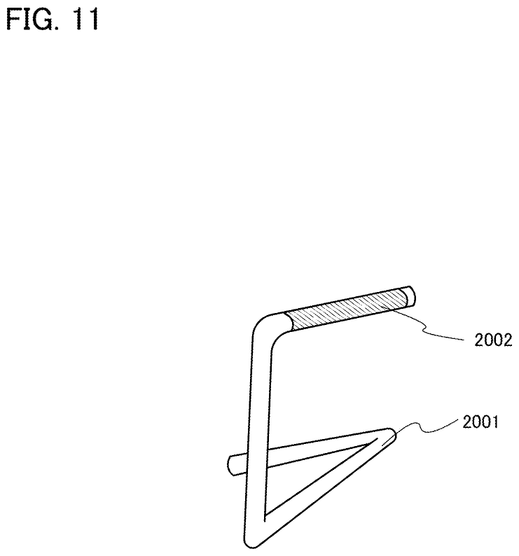

FIG. 11 illustrates an example in which the light-emitting device described in any one of Embodiments 1 to 6 is used for a table lamp which is a lighting device. The table lamp illustrated in FIG. 11 includes a housing 2001 and a light source 2002, and the lighting device described in Embodiment 8 may be used for the light source 2002.

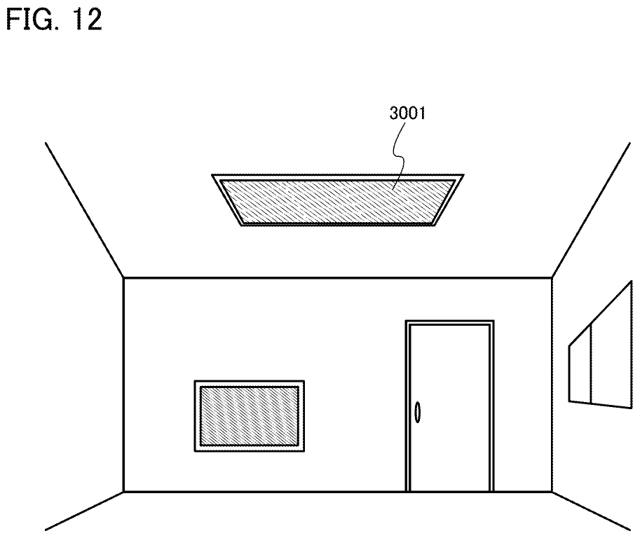

FIG. 12 illustrates an example in which the light-emitting device described in any one of Embodiments 1 to 6 is used for an indoor lighting device 3001. Since the light-emitting device described in any one of Embodiments 1 to 6 has high emission efficiency, the lighting device can have low power consumption. Furthermore, since the light-emitting device described in any one of Embodiments 1 to 6 can have a large area, the light-emitting device can be used for a large-area lighting device. Furthermore, since the light-emitting device described in any one of Embodiments 1 to 6 is thin, the light-emitting device can be used for a lighting device having a reduced thickness.

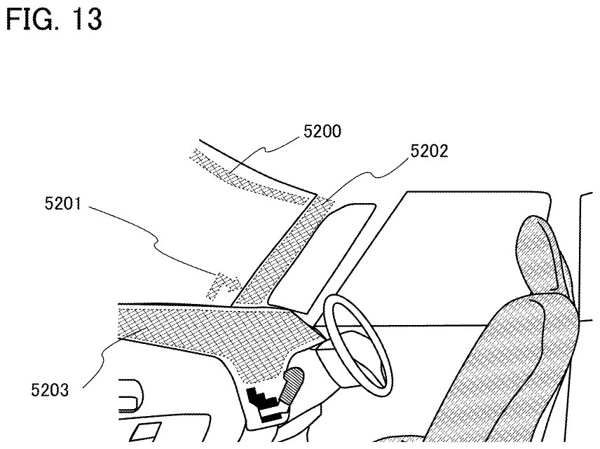

The light-emitting device described in any one of Embodiments 1 to 6 can also be used for an automobile windshield or an automobile dashboard. FIG. 13 illustrates one mode in which the light-emitting device described in any one of Embodiments 1 to 6 is used for an automobile windshield or an automobile dashboard. Display regions 5200 to 5203 each include the light-emitting device described in any one of Embodiments 1 to 6.

The display regions 5200 and 5201 are display devices which are provided in the automobile windshield and in which the light-emitting device described in any one of Embodiments 1 to 6 is incorporated. The light-emitting device described in any one of Embodiments 1 to 6 can be formed into what is called a see-through display device, through which the opposite side can be seen, by including a first electrode and a second electrode formed of electrodes having a light-transmitting property. Such see-through display devices can be provided even in the automobile windshield without hindering the view. In the case where a driving transistor or the like is provided, a transistor having a light-transmitting property, such as an organic transistor including an organic semiconductor material or a transistor including an oxide semiconductor, is preferably used.

A display device incorporating the light-emitting device described in any one of Embodiments 1 to 6 is provided in the display region 5202 in a pillar portion. The display region 5202 can compensate for the view hindered by the pillar by displaying an image taken by an imaging unit provided in the car body. Similarly, the display region 5203 provided in the dashboard portion can compensate for the view hindered by the car body by displaying an image taken by an imaging unit provided on the outside of the automobile. Thus, blind areas can be eliminated to enhance the safety. Images that compensate for the areas which a driver cannot see enable the driver to ensure safety easily and comfortably.

The display region 5203 can provide a variety of kinds of information by displaying navigation data, a speedometer, a tachometer, a mileage, a fuel meter, a gearshift state, air-condition setting, and the like. The content or layout of the display can be changed freely by a user as appropriate. Note that such information can also be displayed on the display regions 5200 to 5202. The display regions 5200 to 5203 can also be used as lighting devices.

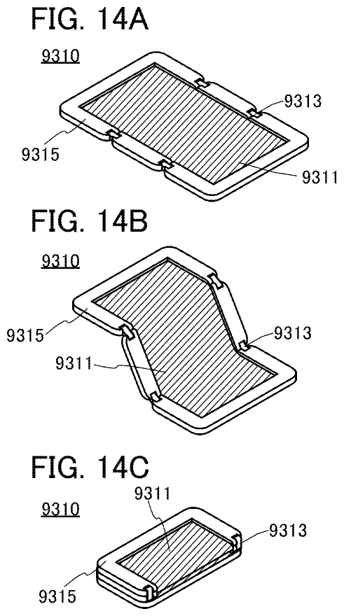

FIGS. 14A to 14C illustrate a foldable portable information terminal 9310. FIG. 14A illustrates the portable information terminal 9310 that is opened. FIG. 14B illustrates the portable information terminal 9310 that is being opened or being folded. FIG. 14C illustrates the portable information terminal 9310 that is folded. The portable information terminal 9310 is highly portable when folded. The portable information terminal 9310 is highly browsable when opened because of a seamless large display region.

A display panel 9311 is supported by three housings 9315 joined together by hinges 9313. Note that the display panel 9311 may be a touch panel (an input/output device) including a touch sensor (an input device). By folding the display panel 9311 at the hinges 9313 between two housings 9315, the portable information terminal 9310 can be reversibly changed in shape from the opened state to the folded state. The light-emitting apparatus of one embodiment of the present invention can be used for the display panel 9311.

Note that the structure described in this embodiment can be combined with any of the structures described in Embodiments 1 to 6 as appropriate.

As described above, the application range of the light-emitting apparatus including the light-emitting device described in any one of Embodiments 1 to 6 is wide, and thus the light-emitting apparatus can be applied to electronic devices in a variety of fields. By using the light-emitting device described in any one of Embodiments 1 to 6, an electronic device with low power consumption can be obtained.

Note that this embodiment can be combined with any of the other embodiments in this specification as appropriate.

### EXAMPLE 1

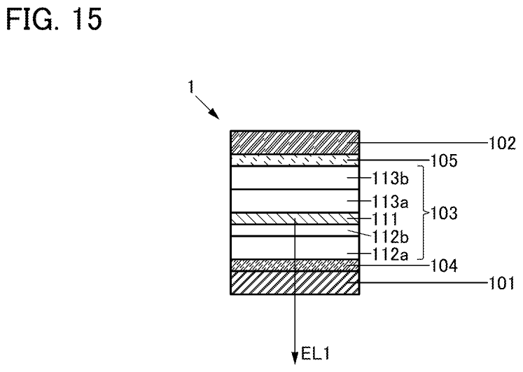

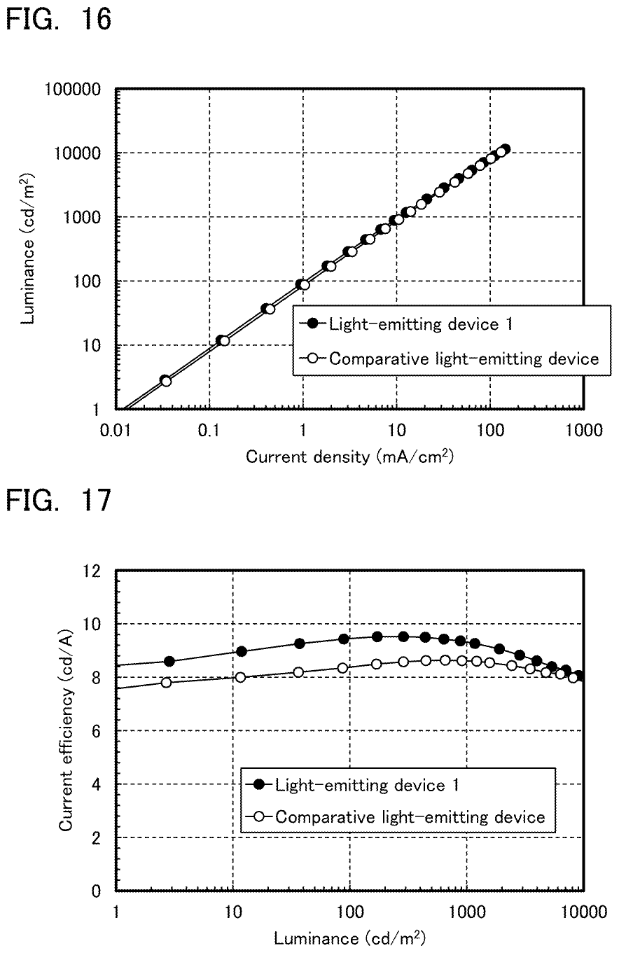

In this example, structures of a light-emitting device 1 and a light-emitting device 2 of one embodiment of the present invention, fabrication methods thereof, and characteristics thereof will be described with reference to FIG. 15 to FIG. 29.

FIG. 15 is a cross-sectional view illustrating a structure of a fabricated light-emitting device.

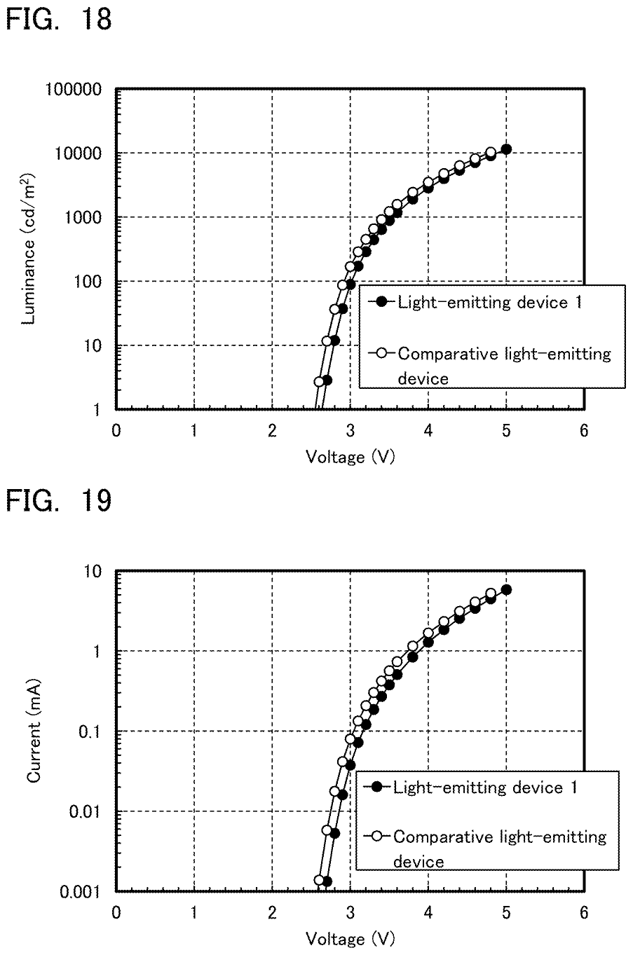

FIG. 16 shows luminance versus current density characteristics of the light-emitting device 1.

FIG. 17 shows current efficiency versus luminance characteristics of the light-emitting device 1.

FIG. 18 shows luminance versus voltage characteristics of the light-emitting device 1.

FIG. 19 shows current versus voltage characteristics of the light-emitting device 1.

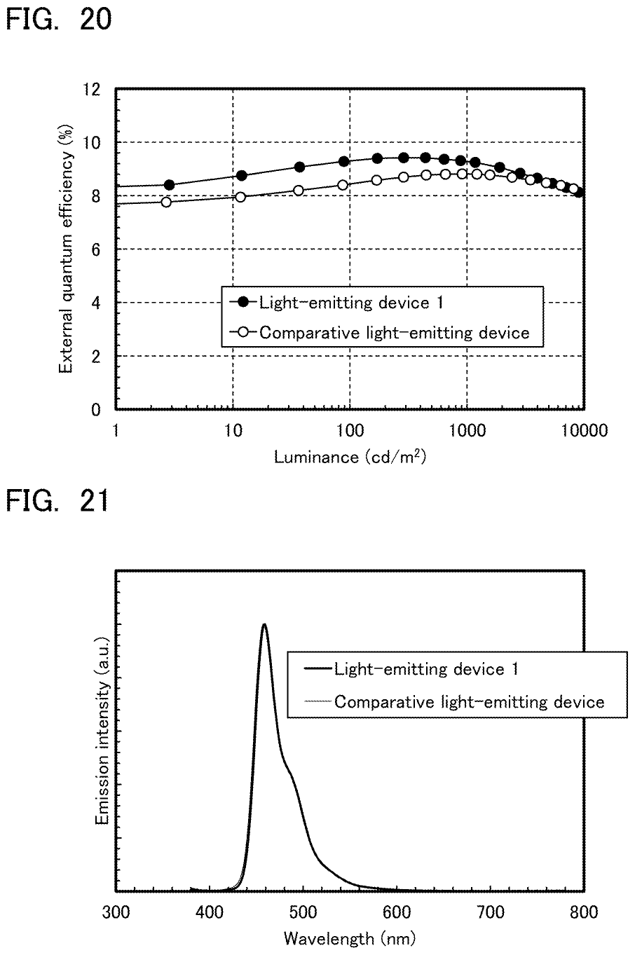

FIG. 20 shows external quantum efficiency versus luminance characteristics of the light-emitting device 1. Note that the external quantum efficiency was calculated from an emission spectrum and luminance in frontal observation assuming that the light distribution characteristics of the light-emitting device are Lambertian type.

FIG. 21 shows an emission spectrum of the light-emitting device 1 emitting light at a luminance of 1000 cd/m².

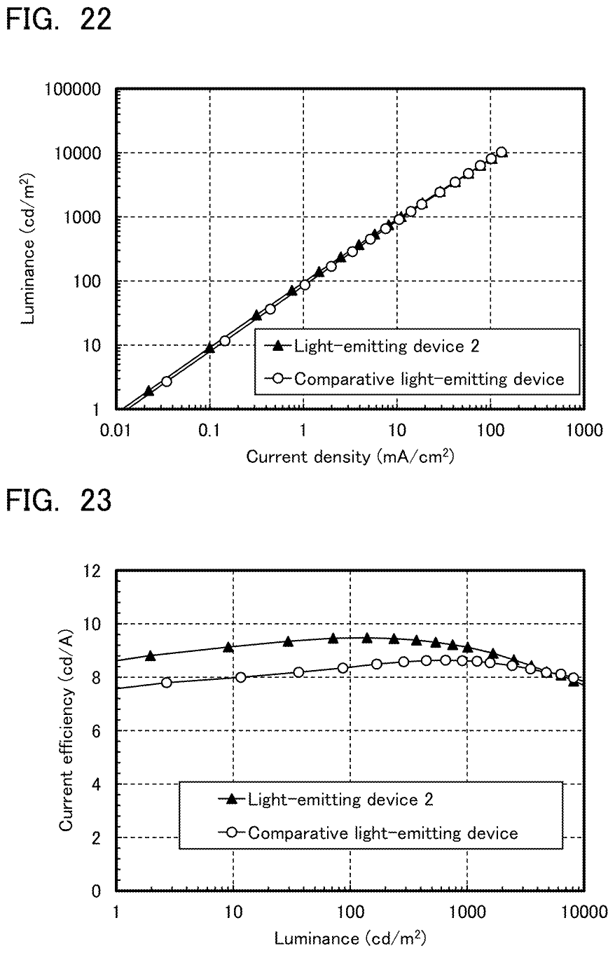

FIG. 22 shows luminance versus current density characteristics of the light-emitting device 2.

FIG. 23 shows current efficiency versus luminance characteristics of the light-emitting device 2.

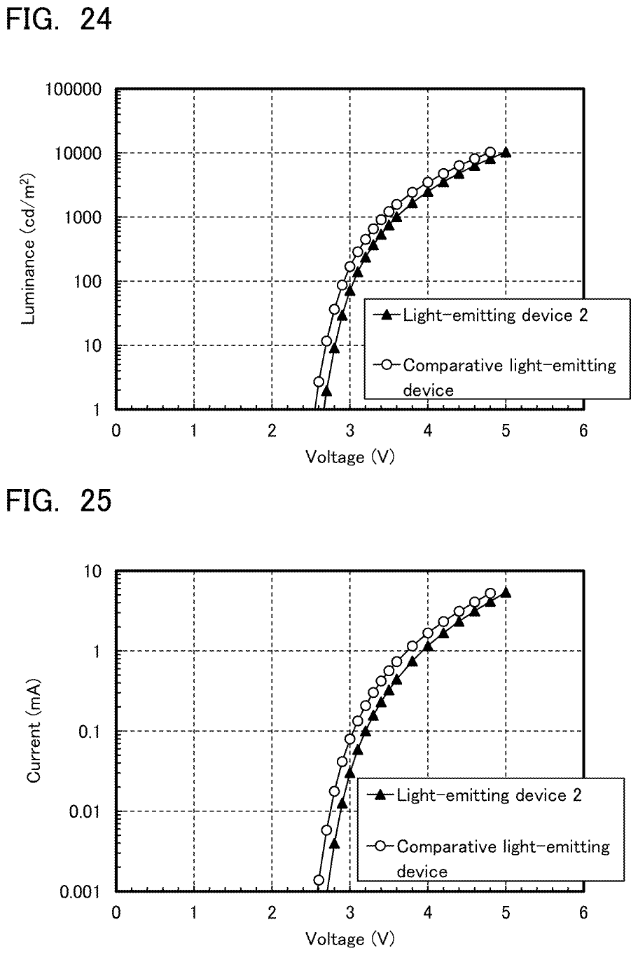

FIG. 24 shows luminance versus voltage characteristics of the light-emitting device 2.

FIG. 25 shows current versus voltage characteristics of the light-emitting device 2.

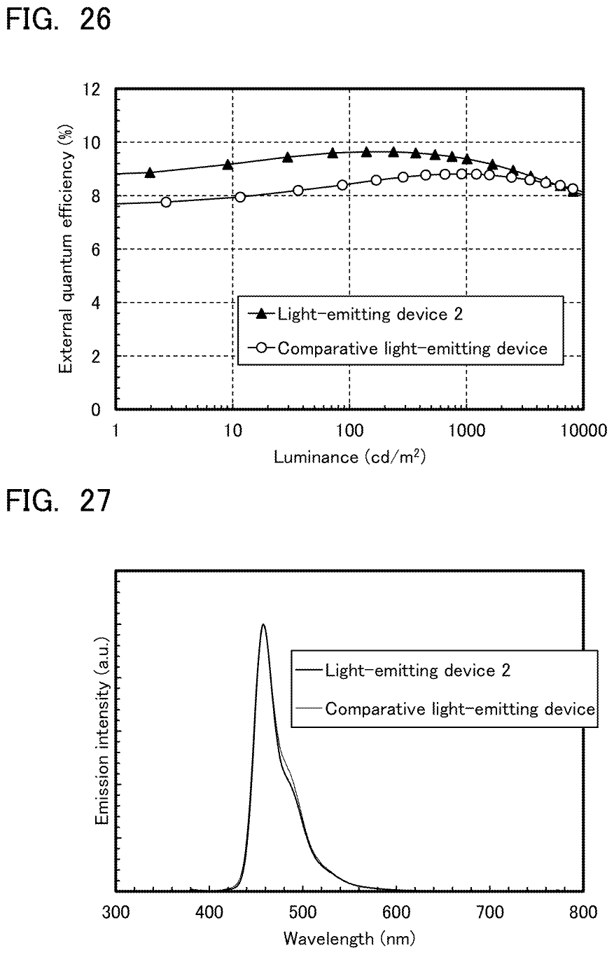

FIG. 26 shows external quantum efficiency versus luminance characteristics of the light-emitting device 2. Note that the external quantum efficiency was calculated from an emission spectrum and luminance in frontal observation assuming that the light distribution characteristics of the light-emitting device are Lambertian type.

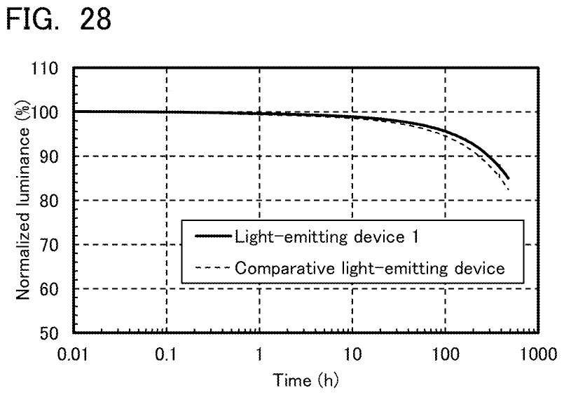

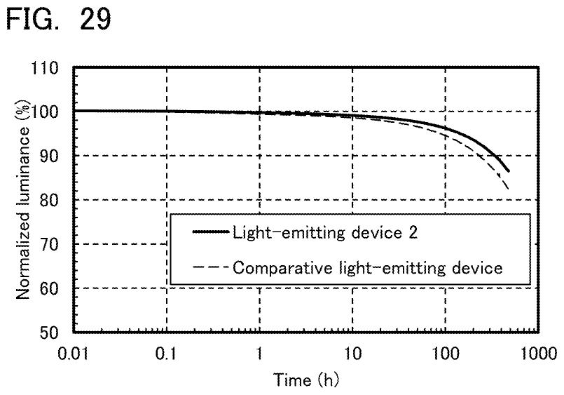

FIG. 27 shows emission spectrum of the light-emitting device 2 emitting light at a luminance of 1000 cd/m².

FIG. 28 is a graph showing time dependence of normalized luminance characteristics of the light-emitting device 1 emitting light at a constant current density of 50 mA/cm². Note that this graph also shows time dependence of normalized luminance characteristics of a comparative light-emitting device emitting light at a constant current density of 50 mA/cm².

FIG. 29 is a graph showing time dependence of normalized luminance characteristics of the light-emitting device 2 emitting light at a constant current density of 50 mA/cm². Note that this graph also shows time dependence of normalized luminance characteristics of the comparative light-emitting device emitting light at a constant current density of 50 mA/cm².

### Light-Emitting Device 1>

The fabricated light-emitting device 1 described in this example includes a first electrode 101, a second electrode 102, and a layer 111. The layer 111 includes a region sandwiched between the first electrode 101 and the second electrode 102 (see FIG. 15). Note that the layer 111 contains a light-emitting material D, a first material H1 and a second material H2. The light-emitting device 1 emits light EL1

The first material H1 has an anthracene skeleton and a substituent R11. The substituent R11 is bonded to the anthracene skeleton and includes a heteroaromatic ring. The second material H2 has an anthracene skeleton, a substituent R21, and a substituent R22. The substituent R21 is bonded to the anthracene skeleton and includes an aromatic ring whose ring structure is composed of only carbon. The substituent R22 is bonded to the anthracene skeleton and includes an aromatic ring whose ring structure is composed of only carbon. The substituent R22 has a structure different from that of the substituent R21. <<Structure of Light-Emitting Device 1>>

Table 1 shows a structure of the light-emitting device 1. Structural formulae of materials used in the light-emitting device described in this example are shown below.

TABLE 1

| | | | | Thick- |
|---|---|---|---|---|
| | Reference | | Composition | ness/ |
| Structure | numeral | Material | ratio | mm |
| Electrode | 102 | Al | | 200 |
| Layer | 105 | Liq | | 1 |
| Layer | 113b | mPn-mDMePyPTzn:Liq | 1:1 | 20 |
| Layer | 113a | 6BP-4Cz2PPm | | 10 |
| Layer | 111 | cgDBCzPA: | 0.5:0.5:0.015 | 20 |
| | | αN-βNPAnth: | | |
| | | 3,10PCA2Nbf(IV)-02 | | |
| Layer | 112b | BBABnf(8) | | 10 |
| Layer | 112a | oFBiSF(2) | | 90 |
| Layer | 104 | oFBiSF(2):OCHD-001 | 1:0.03 | 10 |
| Electrode | 101 | ITSO | | 110 |

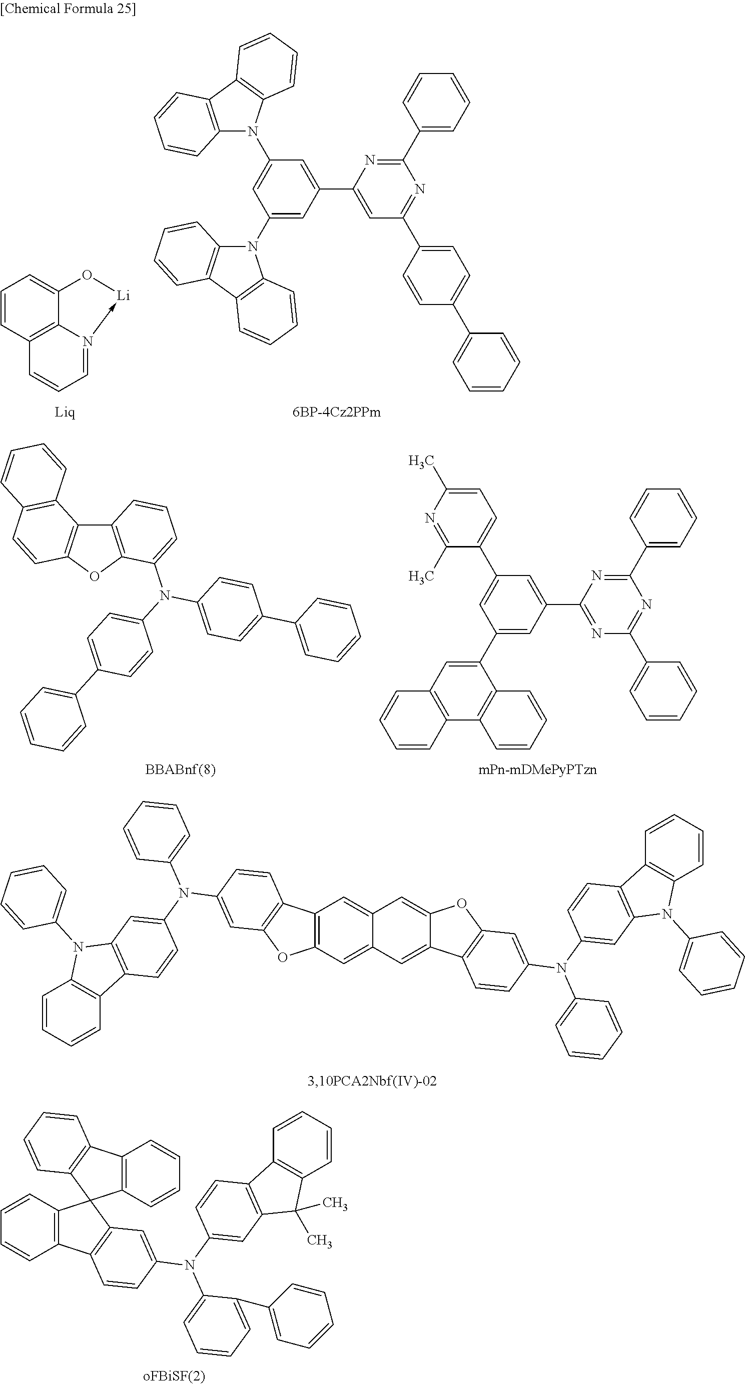

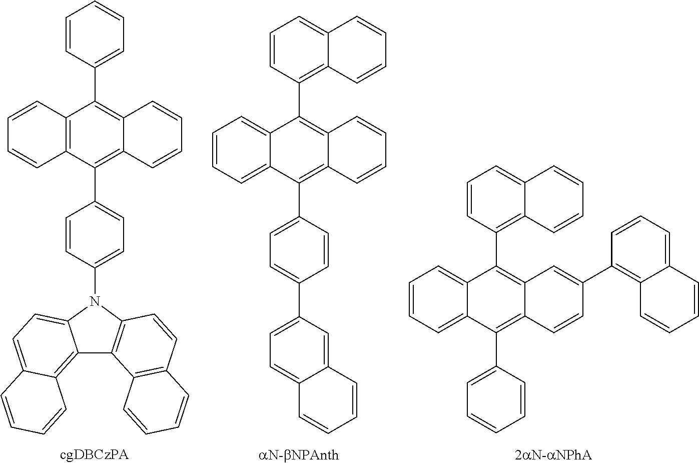

### <<Fabrication Method of Light-Emitting Device 1>>

The light-emitting device 1 described in this example was fabricated using a method including steps described below.

### [First Step]

In a first step, the electrode 101 was formed over a base. Specifically, the electrode 101 was formed by a sputtering method using indium oxide-tin oxide containing silicon or silicon oxide (ITSO) as a target.

The electrode 101 has a thickness of 110 nm and an area of 4 mm² (2 mm×2 mm).

Next, the base over which the electrode 101 was formed was washed with water, baked at 200° C. for an hour, and then subjected to UV ozone treatment for 370 seconds. After that, the base was transferred into a vacuum deposition apparatus whose pressure was reduced to approximately 10⁻⁴ Pa, and vacuum baking at 170° C. for 30 minutes was performed in a heating chamber of the vacuum deposition apparatus. Then, the base was allowed to cool for approximately 30 minutes.

### [Second Step]

In a second step, a layer 104 was formed over the electrode 101. Specifically, after the vacuum deposition apparatus was reduced to 10⁻⁴ Pa, the material of the layer was co-deposited by a resistance-heating method.

The layer 104 contains oFBiSF(2) and an electron acceptor material (abbreviation: OCHD-001) at a weight ratio of 1:0.03 and has a thickness of 10 nm. Note that OCHD-001 has an acceptor property.

### [Third Step]

In a third step, a layer 112a was formed over the layer 104, and a layer 112b was formed over the layer 112a. Specifically, materials of the layers were each deposited by a resistance-heating method.

Note that the layer 112a contains oFBiSF(2) and has a thickness of 90 nm. Furthermore, the layer 112b contains N,N-bis(4-biphenyl)benzo[b]naphtho[1,2-d]furan-8-amine (abbreviation: BBABnf(8)) and a thickness of 10 nm.

### [Fourth Step]

In a fourth step, the layer 111 was formed over the layer 112b. Specifically, a material of the layer was co-deposited by a resistance-heating method.

Note that the layer 111 contains cgDBCzPZ, αN-βNPAnth, and 3,10PCA2Nbf(IV)-02 at a weight ratio of 0.5:0.5:0.015 and has a thickness of 20 nm.

### [Fifth Step]

In a fifth step, a layer 113a was formed over the layer 111, and a layer 113b was formed over the layer 113a. Specifically, materials of the layers were each deposited by a resistance-heating method.

The layer 113a contains 4-[3,5-bis(9H-carbazol-9-yl)phenyl]-2-phenyl-6-(1,1′-biphenyl-4-yl)pyrimidine (abbreviation: 6BP-4Cz2PPm) and has a thickness of 10 nm. The layer 113b contains 2-[3-(2,6-dimethyl-3-pyridinyl)-5-(9-phenanthrenyl)phenyl]-4,6-diphenyl-1,3,5-trizazine (abbreviation: mPn-mDMePyPTzn) and Liq at a weight ratio of 1:1 and has a thickness of 20 nm.

### [Sixth Step]

In a sixth step, a layer 105 was formed over the layer 113b. Specifically, a material of the layer was deposited by a resistance-heating method.

Note that the layer 105 contains Liq and has a thickness of 1 nm.

### [Seventh Step]

In a seventh step, the electrode 102 was formed over the layer 105. Specifically, a material of the layer was deposited by a resistance-heating method.

Note that the electrode 102 contains aluminum (Al) and has a thickness of 200 nm.

### <<Operation Characteristics of Light-Emitting Device 1>>

Operation characteristics of the light-emitting device 1 were measured (see FIG. 16 to FIG. 22). Note that the measurement was performed at room temperature.

Table 2 shows main initial characteristics of the light-emitting device 1 emitting light at a luminance approximately 1000 cd/m².

TABLE 2

| | | | | | | | External |
|---|---|---|---|---|---|---|---|
| | | | Current | | | Current | quantum |
| | Voltage | Current | density | Chromaticity | Chromaticity | efficiency | efficiency |
| | (V) | (mA) | (mA/cm²) | x | y | (cd/A) | (%) |
| Light-emitting device 1 | 3.5 | 0.38 | 9.4 | 0.14 | 0.12 | 9.4 | 9.3 |
| Light-emitting device 2 | 3.6 | 0.44 | 11.1 | 0.14 | 0.11 | 9.1 | 9.4 |
| Comparative light- | 3.4 | 0.42 | 10.5 | 0.14 | 0.11 | 8.6 | 8.8 |
| emitting device | | | | | | | |

The light-emitting device 1 was found to have favorable characteristics. For example, the voltage necessary for light emission at a luminance of 1000 cd/m² was substantially equal to that of the comparative light-emitting device, whereas the external quantum efficiency was improved more than that of the comparative light-emitting device. Furthermore, under a condition where light was emitted at a constant current density of 50 mA/cm², the luminance of the light-emitting device 1 was less lowered than that of the comparative light-emitting device (see FIG. 28).

### <Light-Emitting Device 2>

Table 3 shows a structure of the light-emitting device 2. The fabricated light-emitting device 2 described in this example differs from the light-emitting device 1 in that the layer 111 contains 2αN-αNPhA instead of αN-βNPAnth. Different portions will be described in detail below, and the above description is referred to for the other similar portions.

TABLE 3

| | | | | Thick- |
|---|---|---|---|---|
| | Reference | | Composition | ness/ |
| Structure | numeral | Material | ratio | mm |
| Electrode | 102 | Al | | 200 |
| Layer | 105 | Liq | | 1 |
| Layer | 113b | mPn-mDMePyPTzn:Liq | 1:1 | 20 |
| Layer | 113a | 6BP-4Cz2PPm | | 10 |
| Layer | 111 | cgDBCzPA: | 0.5:0.5:0.015 | 20 |
| | | 2αN-αNPhA: | | |
| | | 3,10PCA2Nbf(IV)-02 | | |
| Layer | 112b | BBABnf(8) | | 10 |
| Layer | 112a | oFBiSF(2) | | 90 |
| Layer | 104 | oFBiSF(2):OCHD-001 | 1:0.03 | 10 |
| Electrode | 101 | ITSO | | 110 |

### <<Fabrication Method of Light-Emitting Device 2>>

The light-emitting element 2 was fabricated using a method including steps described below.

Note that the fabrication method of the light-emitting device 2 differs from that of the light-emitting device 1 in that 2αN-αNPhA is used instead of the αN-βNPAnth in the step of forming the layer 111. Different portions will be described in detail below, and the above description is referred to for the other similar portions.

### [Fourth Step]

In a fourth step, the layer 111 was formed over the layer 112b. Specifically, a material of the layer was co-deposited by a resistance-heating method.

The layer 111 contains cgDBCzPA, 2αN-αNPhA, and 3,10PCA2Nbf(IV)-02 at a weight ratio of 0.5:0.5:0.015 and has a thickness of 20 nm.

### <<Operation Characteristics of Light-Emitting Device 2>>

Operation characteristics of the light-emitting device 2 were measured (see FIG. 22 to FIG. 27). Note that the measurement was performed at room temperature.

Table 2 shows main initial characteristics of the light-emitting device 2.

The light-emitting device 2 was found to have favorable characteristics. For example, the voltage necessary for light emission at a luminance of 1000 cd/m² was substantially equal to that of the comparative light-emitting device, whereas the external quantum efficiency was improved more than that of the comparative light-emitting device. Furthermore, under a condition where light was emitted at a constant current density of 50 mA/cm², the luminance of the light-emitting device 2 was less lowered than that of the comparative light-emitting device (see FIG. 29).

### REFERENCE EXAMPLE 1

Table 4 shows a structure of the comparative light-emitting device.

The fabricated comparative light-emitting device described in this example differs from the light-emitting devices 1 and 2 in that the layer 111 contains cgDBCzPA and 3,10PCA2Nbf(IV)-02 but does not contain the second material H2. Different portions will be described in detail below, and the above description is referred to for the other similar portions.

TABLE 4

| | | | | Thick- |
|---|---|---|---|---|
| | Reference | | Composition | ness/ |
| Structure | numeral | Material | ratio | mm |
| Electrode | 102 | Al | | 200 |
| Layer | 105 | Liq | | 1 |
| Layer | 113b | mPn-mDMePyPTzn:Liq | 1:1 | 20 |
| Layer | 113a | 6BP-4Cz2PPm | | 10 |
| Layer | 111 | cgDBCzPA: | 1:0.015 | 20 |
| | | 3,10PCA2Nbf(IV)-02 | | |
| Layer | 112b | BBABnf(8) | | 10 |
| Layer | 112a | oFBiSF(2) | | 90 |
| Layer | 104 | oFBiSF(2):OCHD-001 | 1:0.03 | 10 |
| Electrode | 101 | ITSO | | 110 |

### <<Fabrication Method of Comparative Light-Emitting Device>>

The comparative light-emitting device was fabricated using a method including steps described below.

Note that the fabrication method of the comparative light-emitting device differs from that of the light-emitting device 1 or the light-emitting device 2 in that only cgDBCzPA and 3,10PCA2Nbf(IV)-02 are used in the step of forming the layer 111. Different portions will be described in detail below, and the above description is referred to for the other similar portions.

### [Fourth Step]

In a fourth step, the layer 111 was formed over the layer 112b. Specifically, a material of the layer was co-deposited by a resistance-heating method.

The layer 111 contains cgDBCzPA and 3,10PCA2Nbf(IV)-02 at a weight ratio of 1:0.015 and has a thickness of 20 nm.

### <<Operation Characteristics of Comparative Light-Emitting Device>>

Operation characteristics of the comparative light-emitting device were measured. Note that the measurement was performed at room temperature.

Table 2 shows main initial characteristics of the comparative light-emitting device.

### EXAMPLE 2

In this example, structures of a light-emitting device 3 and a light-emitting device 4 of one embodiment of the present invention, fabrication methods thereof, and characteristics thereof will be described with reference to FIG. 15 and FIG. 30 to FIG. 41.

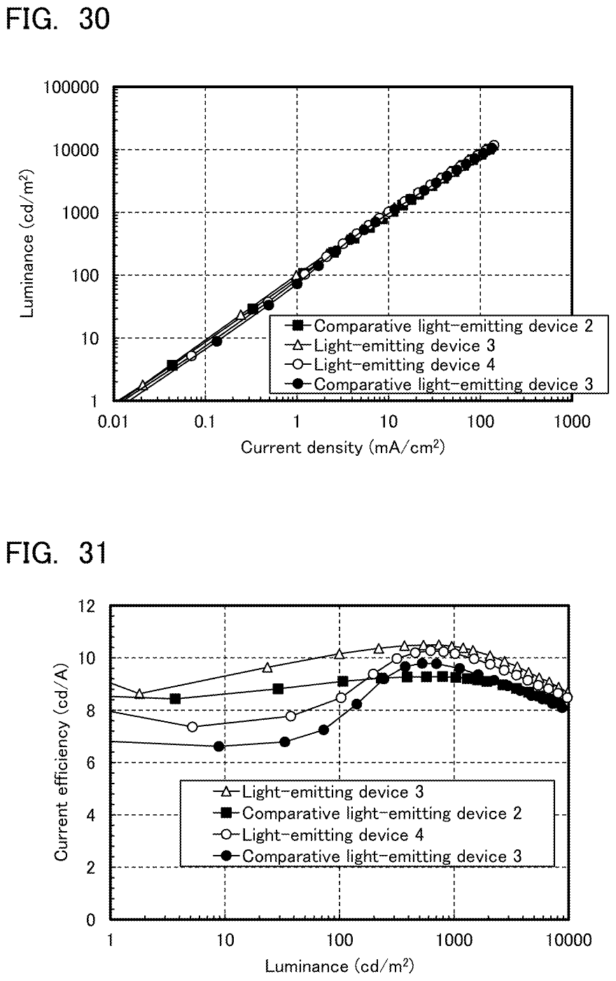

FIG. 30 shows luminance versus current density characteristics of the light-emitting device 3 and the light-emitting device 4.

FIG. 31 shows current efficiency versus luminance characteristics of the light-emitting device 3 and the light-emitting device 4.

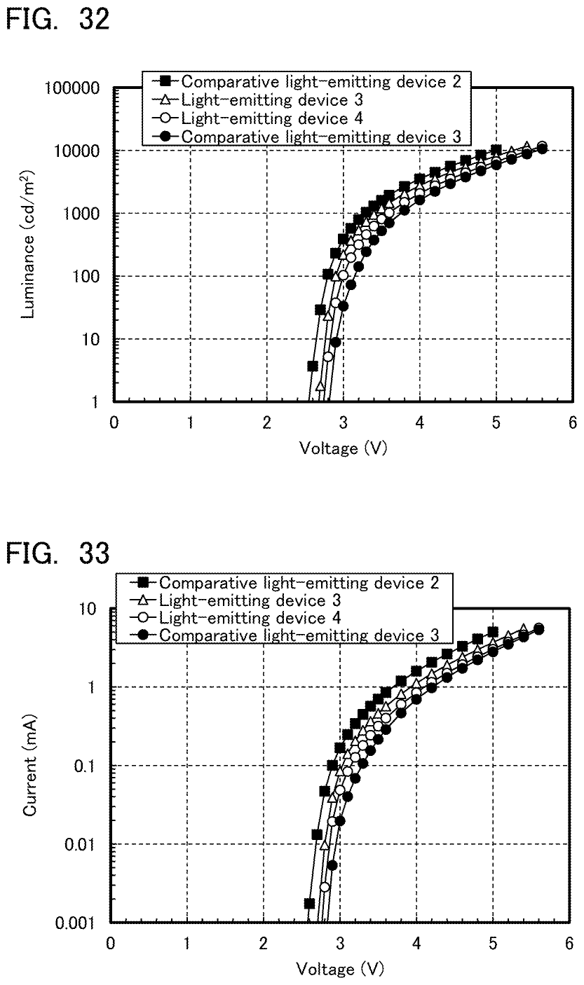

FIG. 32 shows luminance versus voltage characteristics of the light-emitting device 3 and the light-emitting device 4.

FIG. 33 shows current versus voltage characteristics of the light-emitting device 3 and the light-emitting device 4.

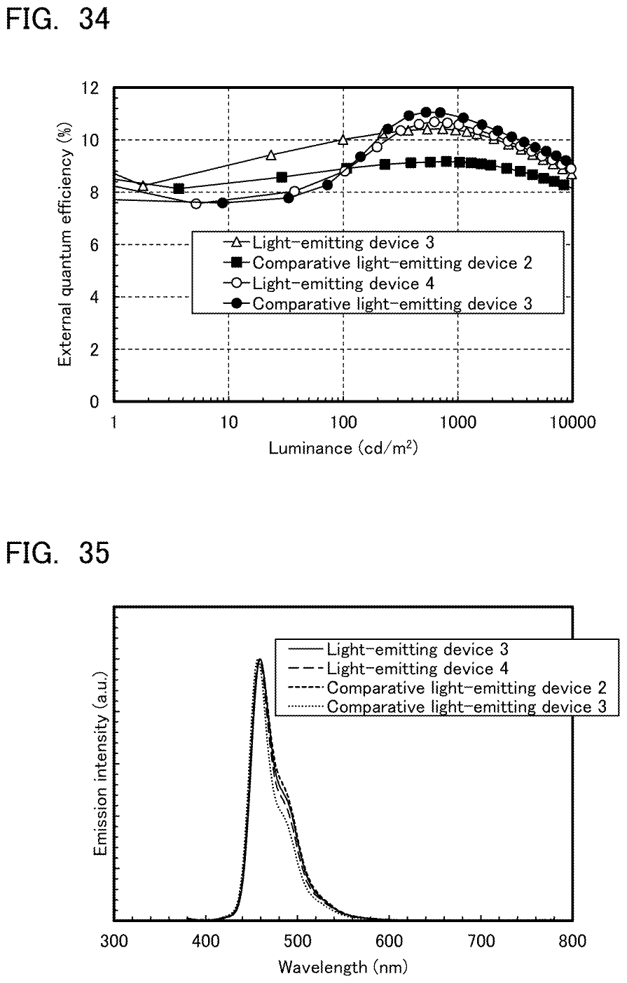

FIG. 34 shows external quantum efficiency versus luminance characteristics of the light-emitting device 3 and the light-emitting device 4. Note that the external quantum efficiency was calculated from an emission spectrum and luminance in frontal observation assuming that assuming that the light distribution characteristics of the light-emitting devices are Lambertian type.

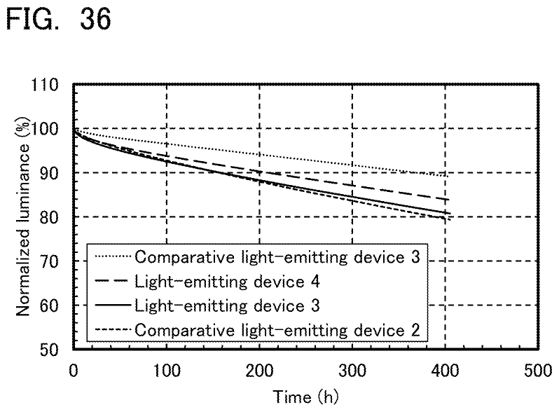

FIG. 35 shows emission spectra of the light-emitting devices 3 and 4 each emitting light at a luminance of 1000 cd/m².

FIG. 36 is a graph showing time dependence of normalized luminance characteristics of the light-emitting devices 3 and 4 each emitting light at a constant current density of 50 mA/cm². Note that the graph also shows time dependence of normalized luminance of comparative light-emitting devices each emitting light at a constant current density of 50 mA/cm².

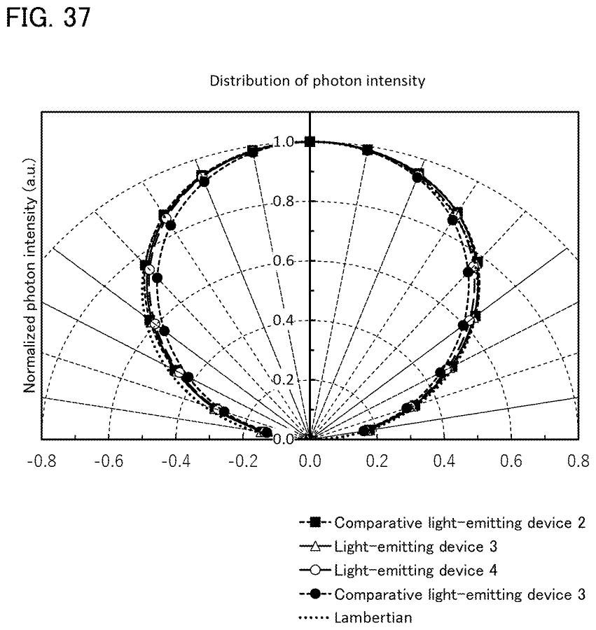

FIG. 37 shows light (photon intensity) distribution characteristics of the light-emitting devices each emitting light so as to exhibit the maximum external quantum efficiency.

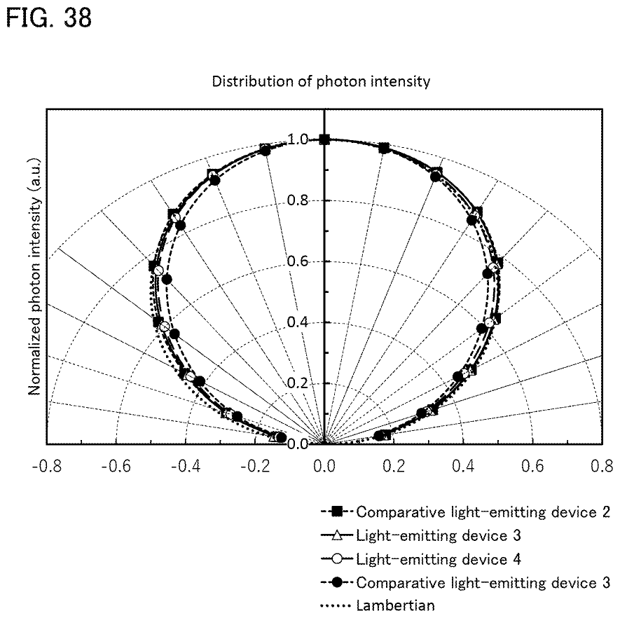

FIG. 38 shows light (photon intensity) distribution characteristics of the light-emitting devices each emitting light at a constant current density of 50 mA/cm².

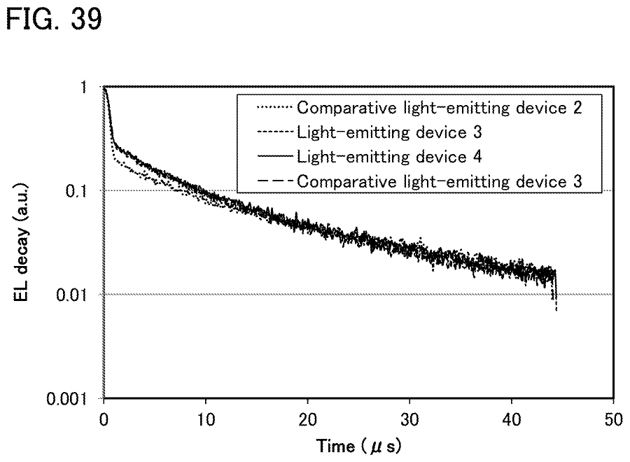

FIG. 39 shows changes in emission intensity of the light-emitting devices each operating in pulse driving at a voltage enabling the maximum external quantum efficiency.

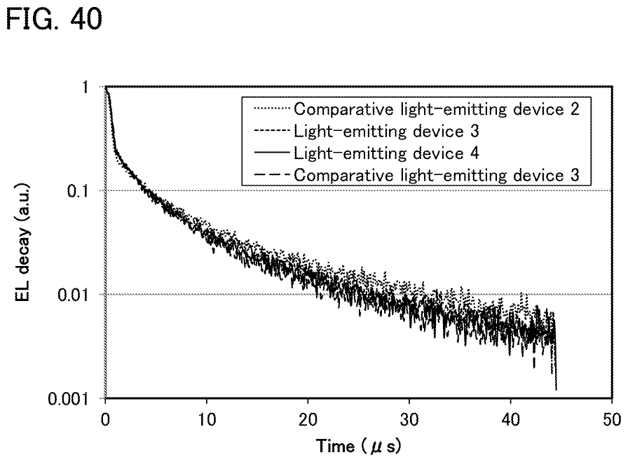

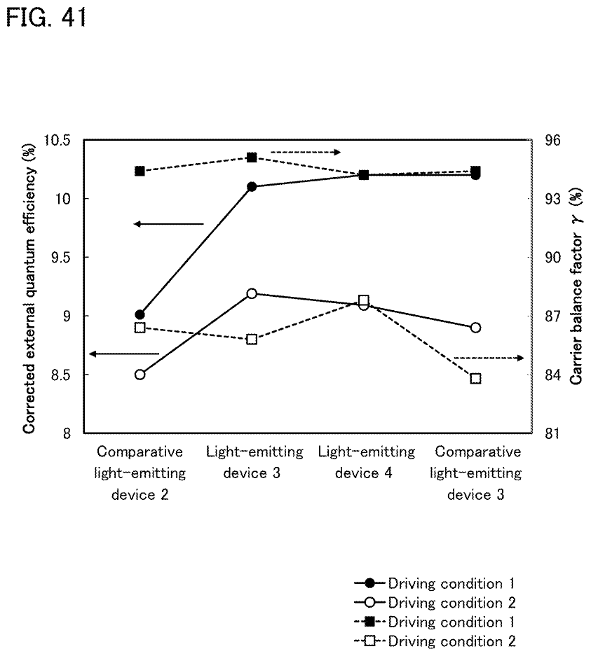

FIG. 40 shows changes in emission intensity of light-emitting devices each operating in pulse driving at a voltage enabling a current density of 50 mA/m².

FIG. 41 shows a relation of corrected external quantum efficiency and carrier balance factor γ with compositions of each host material used in the layer 111.

### <Light-Emitting Devices 3 and 4>

Each of the fabricated light-emitting devices 3 and 4, which are described in this example, includes a first electrode 101, a second electrode 102, and a layer 111. The layer 111 includes a region sandwiched between the first electrode 101 and the second electrode 102 (see FIG. 15). Note that the layer 111 includes a light-emitting material D, a first material H1, and a second material H2. Each of the light-emitting devices 3 and 4 emits light EL1.

The first material H1 has an anthracene skeleton and a substituent R11. The substituent R11 is bonded to the anthracene skeleton and includes a heteroaromatic ring. The second material H2 has an anthracene skeleton and a substituent R21 and a substituent R22. The substituent R21 is bonded to the anthracene skeleton and includes an aromatic ring whose ring structure is composed on only carbon. The substituent R22 is bonded to the anthracene skeleton and includes an aromatic ring whose ring structure is composed on only carbon. The substituent R22 has a structure different from that of the substituent R21.

### <<Structure of Light-Emitting Devices 3 and 4>>

Table 5 shows structures of the light-emitting devices 3 and 4. Structural formulae of materials used for the light-emitting devices described in this example are shown below.

TABLE 5

| | | | | Thick- |
|---|---|---|---|---|
| | Reference | | Composition | ness/ |
| Structure | numeral | Material | ratio | mm |
| Electrode | 102 | Al | | 150 |
| Layer | 105 | Liq | | 1 |
| Layer | 113b | mPn-mDMePyPTzn:Liq | 1:1 | 20 |
| Layer | 113a | 6mBP-4Cz2PPm | | 10 |
| Layer | 111 | cgDBCzPA: | x:y:0.015 | 20 |
| | | αN-βNPAnth: | | |
| | | 3,10PCA2Nbf(IV)-02 | | |
| Layer | 112b | DBfBB1TP | | 10 |
| Layer | 112a | PCBBiF | | 90 |
| Layer | 104 | PCBBiF:OCHD-001 | 1:0.03 | 10 |
| Electrode | 101 | ITSO | | 70 |

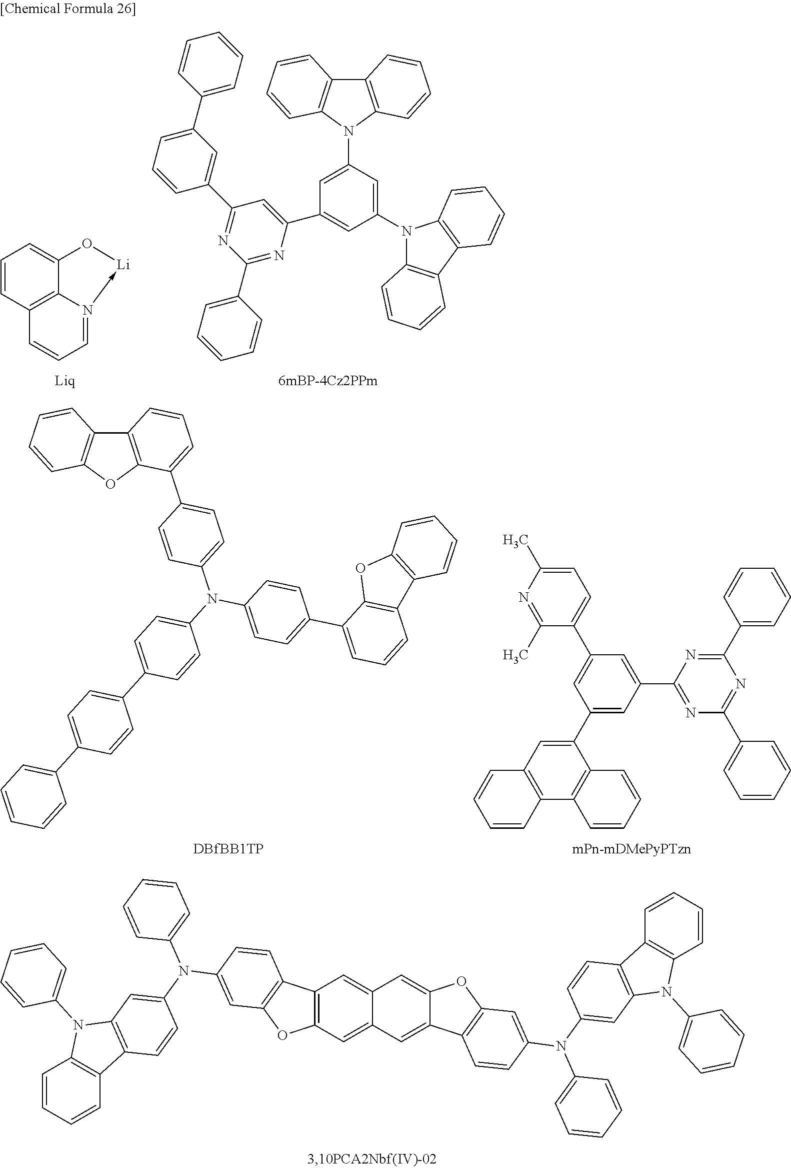

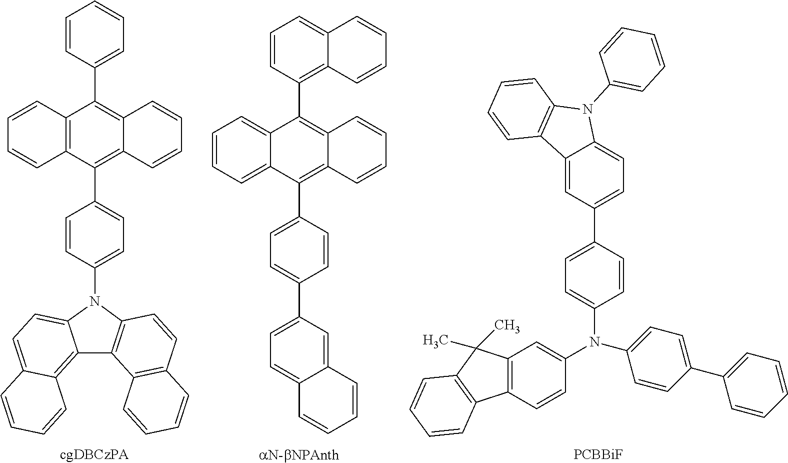

### <<Fabrication Method of Light-Emitting Devices 3 and 4>>

The light-emitting devices 3 and 4 described in this example were fabricated using a method including steps described below.

### [First Step]

In a first step, the electrode 101 was formed. Specifically, the electrode 101 was formed by a sputtering method using indium oxide-tin oxide containing silicon or silicon oxide (ITSO) as a target.

Note that the electrode 101 contains ITSO and has a thickness of 70 nm and an area of 4 mm² (2 mm×2 mm).

Next, a base over which the electrode 101 was formed was washed with water, baked at 200° C. for an hour, and subjected to UV ozone treatment for 370 seconds. Then, the base was transferred into a vacuum deposition apparatus whose pressure was reduced to approximately 10⁻⁴ Pa, and vacuum baking at 170° C. for 30 minutes was performed in a heating chamber of the vacuum deposition apparatus. Then, the base was allowed to cool for approximately 30 minutes.

### [Second Step]

In a second step, a layer 104 was formed over the electrode 101. Specifically, after the vacuum deposition apparatus was reduced to 10⁻⁴ Pa, a material of the layer was co-deposited by a resistance-heating method.

Note that the layer 104 contains PCBBiF and OCHD-001 at a weight ratio of 1:0.03 and has a thickness of 10 nm.

### [Third Step]

In a third step, a layer 112a was formed over the layer 104. Specifically, a material of the layer was deposited by a resistance-heating method.

Note that the layer 112a contains PCBBiF and has a thickness of 90 nm.

### [Fourth Step]

In a fourth step, a layer 112b was formed over the layer 112a. Specifically, a material of the layer was deposited by a resistance-heating method.

Note that the layer 112b contains DBfBB1TP and has a thickness of 10 nm.

### [Fifth Step]

In a fifth step, the layer 111 was formed over the layer 112b. Specifically, a material of the layer was deposited by a resistance-heating method.

Note that the layer 111 contains the first material H1, the second material H2, and the light-emitting material D at a weight ratio of x:y:0.015 and have a thickness of 20 nm.

Specifically, the layer 111 of the light-emitting device 3 contains cgDBCzPA, αN-βNPAnth and 3,10PCA2Nbf(IV)-02 at a weight ratio of 0.5:0.5:0.015.

The layer 111 of the light-emitting device 4 contains cgDBCzPA, αN-βNPAnth, and 3,10PCA2Nbf(IV)-02 at a weight ratio of 0.3:0.7:0.015.

### [Sixth Step]

In a sixth step, a layer 113a formed over the layer 111. Specifically, a material of the layer was deposited by a resistance-heating method.

The layer 113a contains 6-(1,1′-biphenyl-3-yl)-4-[3,5-bis(9H-carbazol-9-yl)phenyl]-2-phenylpyrimidine (abbreviation: 6mBP-4Cz2PPm) and has a thickness of 10 nm.

### [Seventh Step]

In a seventh step, a layer 113b was formed over the layer 113a. Specifically, a material of the layer was co-deposited by a resistance-heating method.

The layer 113b contains mPn-mDMePyPTzn and Liq at a weight ratio of 1:1 and has a thickness of 20 nm.

### [Eighth Step]

In an eighth step, a layer 105 was formed over the layer 113b. Specifically, a material of the layer was deposited by a resistance-heating method.

Note that the layer 105 contains Liq and has a thickness of 1 nm.

### [Ninth Step]

In a ninth step, the electrode 102 was formed over the layer 105. Specifically, a material of the electrode was deposited by a resistance-heating method.

Note that the electrode 102 contains Al and has a thickness of 150 nm.

### <<Operation Characteristics of Light-Emitting Devices 3 and 4>>

Operation characteristics of the light-emitting devices 3 and 4 were measured (see FIG. 30 to FIG. 36). Note that the measurement was performed at room temperature.

Table 6 shows main initial characteristics of the light-emitting devices 3 and 4 emitting light at a luminance approximately 1000 cd/m².

TABLE 6

| | | | | | | | External |
|---|---|---|---|---|---|---|---|
| | | | Current | | | Current | quantum |
| | Voltage | Current | density | Chromaticity | Chromaticity | efficiency | efficiency |
| | (V) | (mA) | (mA/cm²) | x | y | (cd/A) | (%) |
| Light-emitting device 3 | 3.4 | 0.37 | 9.1 | 0.13 | 0.12 | 10.4 | 10.4 |
| Light-emitting device 4 | 3.6 | 0.40 | 10.0 | 0.14 | 0.11 | 10.2 | 10.6 |
| Comparative light- | 3.3 | 0.45 | 11.2 | 0.13 | 0.12 | 9.3 | 9.1 |
| emitting device 2 | | | | | | | |
| Comparative light- | 3.8 | 0.47 | 11.6 | 0.14 | 0.10 | 9.6 | 10.8 |
| emitting device 3 | | | | | | | |

The light-emitting devices 3 and 4 were found to have favorable characteristics. When a variation in external quantum efficiency observed in a region with lower luminance than Driving Condition 1 (low luminance) is particularly focused, it is found that the light-emitting device 3 exhibits not only high external quantum efficiency but also a small variation (see FIG. 34). The first material H1 and the second material H2 were mixed as appropriate and used for the layer 111, whereby dependency of external quantum efficiency on luminance was able to be reduced.

### <<External Quantum Efficiency of Light-Emitting Devices 3 and 4>>

The external quantum efficiency of each of the light-emitting devices 3 and 4 was examined in detail. In a conventional method, on the assumption of ideal Lambertian distribution, external quantum efficiency is calculated from a spectrum and luminance observed in front of a light-emitting device. In this examination, light distribution characteristics of the light-emitting devices were actually measured to calculate a difference from ideal Lambertian distribution (Lambertian ratio), and by taking the Lambertian ratio into consideration, accurate external quantum efficiency was calculated. Note that the Lambertian ratio is a value of a ratio of an area of a region surrounded by a curve of measured light distribution to an area of a region surrounded by a curve of ideal Lambertian distribution.

In detailed examination of the external quantum efficiency, the light-emitting devices were tilted by a predetermined angle with respect to a spectroradiometer, and light distribution characteristics were examined at each angle by a method for measuring light intensity. Specifically, by setting a position where the spectroradiometer and the light-emitting devices face to each other to 0°, luminance was measured from −80° to +80° in steps of 10°, and the measured luminance was normalized with use of emission intensity observed at a facing position, so that light distribution characteristics were examined. FIG. 37 shows light distribution characteristics of the light-emitting devices driven under a condition where each of the light-emitting devices exhibits the maximum external quantum efficiency (Driving Condition 1). FIG. 38 shows light distribution characteristics of the light-emitting devices driven under a condition where the current density is 50 mA/m² (Driving Condition 2). The measurement was performed at room temperature.

Each of the light-emitting device 3, the light-emitting device 4, a comparative light-emitting device 2, and a comparative light-emitting device 3 has light distribution characteristics such that high intensity light is emitted in the front direction as compared to ideal Lambertian distribution, and has a Lambertian ratio that is a smaller value than 1.

The external quantum efficiency varies depending on driving conditions of the light-emitting devices. Here, the external quantum efficiency was compared between two driving conditions, Driving Condition 1 and Driving Condition 2. Table 7 shows results obtained under Driving Condition 1, and Table 8 shows results obtained under Driving Condition 2.

For example, in terms of the corrected external quantum efficiency under Driving Condition 1, the ratio of the light-emitting device 3 to the comparative light-emitting device 2 was 1.12, and that of the light-emitting device 4 was 1.13. Under Driving Condition 2, the ratio of the light-emitting device 3 to the comparative light-emitting device 2 was 1.08, and that of the light-emitting device 4 was 1.07. Accordingly, it was found that the light-emitting device 3 and the light-emitting device 4 exhibit better characteristics than the comparative light-emitting device 2 and the comparative light-emitting device 3.

TABLE 7

| | Pre-correction | | Post-correction | | | | |
|---|---|---|---|---|---|---|---|
| | external | | external | | | | |
| | quantum | Lambertian | quantum | TTA | | | |
| | efficiency | ratio | efficiency | raio | α | φ × χ | γ |
| Driving Condition 1 | (%) | (%) | (%) | (%) | (%) | (%) | (%) |
| Light-emitting device 3 | 10.4 | 97.3 | 10.1 | 29.4 | 35.4 | 30 | 95.1 |
| Light-emitting device 4 | 10.7 | 95.6 | 10.2 | 30.8 | 36.1 | 30 | 94.2 |
| Comparative light- | 9.17 | 98.2 | 9.01 | 21.3 | 31.8 | 30 | 94.4 |
| emitting device 2 | | | | | | | |
| Comparative light- | 11.1 | 92.0 | 10.2 | 30.3 | 36.0 | 30 | 94.4 |
| emitting device 3 | | | | | | | |

TABLE 8

| | Pre-correction | | Post-correction | | | | |
|---|---|---|---|---|---|---|---|
| | external | | external | | | | |
| | quantum | Lambertian | quantum | TTA | | | |
| | efficiency | ratio | efficiency | ratio | α | φ × χ | γ |
| Driving Condition 2 | (%) | (%) | (%) | (%) | (%) | (%) | (%) |
| Light-emitting device 3 | 9.44 | 97.4 | 9.19 | 29.9 | 35.7 | 30 | 85.8 |
| Light-emitting device 4 | 9.56 | 95.1 | 9.09 | 27.5 | 34.5 | 30 | 87.8 |
| Comparative light- | 8.67 | 98.1 | 8.50 | 23.7 | 32.8 | 30 | 86.4 |
| emitting device 2 | | | | | | | |
| Comparative light- | 9.75 | 91.3 | 8.90 | 29.4 | 35.4 | 30 | 83.8 |
| emitting device 3 | | | | | | | |

### <<Carrier Balance Factor γ of Light-Emitting Devices 3 and 4>>

Carrier balance factors γ of the light-emitting devices 3 and 4 were examined.

The external quantum efficiency EQE is a product of a proportion of generated singlet excitons α, a quantum yield φ of a light-emitting material, light extraction efficiency χ, and a carrier balance factor γ.

[Formula 1]

EQE=α×(φ×χ)×γ (1)

According to actual measurement, the quantum yield φ of the light-emitting material is approximately 0.9. In addition, according to actual measurement of molecular orientation of the light-emitting material, the light extraction efficiency χ is 1.23 times higher than the case of random orientation. On the basis of a fact that the light extraction efficiency is generally 25% to 30% approximately, the assumed product ofφ and χ was 0.3.

The proportion of generated singlet excitons α can be found from the following formula. Note that x in the following formula denotes a triplet-triplet annihilation (TTA) yield (TTA ratio).

$$\begin{matrix}[ Formula 2 ] & \\ α = 0.25 \times \frac{1}{1 - x} & ( 2 )\end{matrix}$$

By a recombination of holes and electrons in an EL device, the probability of generation of singlet excitons is generally 25%, and that of triplet excitons is generally 75%. It is known that a part of the triplet excitons interacts with the other triplet excitons to be up-converted to singlet excitons through TTA.

The presence of singlet excitons generated through triplet excitons with a long life can be confirmed by observation of delayed fluorescence. In addition, the following formula is fitted with an attenuation curve of the observed delayed fluorescence, and the fitted curve is extrapolated to Time 0, so that the proportion of the delayed fluorescent components in total light emitted from the light-emitting device can be found. Note that in the following formula, L denotes normalized emission intensity, and t denotes elapsed time after driving is stopped.

$$\begin{matrix}[ Formula 3 ] & \\ L = {\sum }_{n = 1} {A}_{n} exp ( - \frac{t}{{a}_{n}} ) & ( 3 )\end{matrix}$$

The delayed fluorescence was measured with use of a picosecond fluorescence lifetime measurement system (manufactured by Hamamatsu Photonics K.K.). Specifically, a predetermined voltage corresponding to Driving Condition 1 or a predetermined voltage corresponding to Driving Condition 2 was applied to the light-emitting devices. The voltage application was conducted in a rectangular pulse manner. The predetermined voltage was held for 100 μsec, and attenuation of the delayed fluorescence was observed for 50 μsec. Furthermore, a negative bias, −5 V, was applied during a period of observing the attenuation of the delayed fluorescence. The measurement was repeated at a cycle of 10 Hz, and then obtained data was added up. FIG. 39 shows emission intensity of the light-emitting devices operating in pulse driving at the predetermined voltage corresponding to Driving Condition 1. FIG. 40 shows emission intensity of the light-emitting devices operating in pulse driving at the predetermined voltage corresponding to Driving Condition 2.

The carrier balance factor y changes depending on the driving conditions of the light-emitting devices. Here, the carrier balance factors y under two driving conditions were compared between the condition where each light-emitting device exhibits the maximum external quantum efficiency (Driving Condition 1) and the condition where each light-emitting device has a current density of 50 mA/m² (Driving Condition 2) (see FIG. 41).

Under Driving Condition 2, the light-emitting devices 3 and 4 each had a higher proportion of generated singlet excitons a than the comparative light-emitting device 2. In other words, the efficiency of TTA can be increased as compared to the case of using only the first material H1. In addition, the light-emitting devices 3 and 4 each had a better carrier balance factor γ than the comparative light-emitting device 3. It was found that carriers can be recombined efficiently when the layer 111 includes a mixture of the first material H1 and the second material H2. Thus, with use of the layer 111 including a mixture of the first material H1 and the second material H2, not only the proportion of generated singlet excitons a but also the carrier balance factor γ in a region with a high current density were able to be increased.

### REFERENCE EXAMPLE 2

Structures of the comparative light-emitting devices 2 and 3 are described with use of Table 5.

The comparative light-emitting devices 2 and 3 fabricated and described in this example do not use the second material H2, which is different from the light-emitting devices 3 and 4. Here, different portions will be described in detail below, and the above description is referred to for the other similar portions.

### <<Fabrication Method of Comparative Light-Emitting Devices 2 and 3>>

The comparative light-emitting devices 2 and 3 were fabricated using a method including steps described below.

Note that in the fabrication method of the comparative light-emitting device 2, only cgDBCzPA and 3,10PCA2Nbf(IV)-02 are used in the step for forming the layer 111, which is different from the fabrication methods of the light-emitting devices 3 and 4. In the fabrication method of the comparative light-emitting device 3, only αN-βNPAnth and 3,10PCA2Nbf(IV)-02 are used in the step of forming the layer 111, which is different from the fabrication methods of the light-emitting devices 3 and 4. Here, different portions are described in detail, and the above description is referred to for the other similar portions.

### [Fourth Step]

In a fourth step, the layer 111 was formed over the layer 112b. Specifically, a material of the layer was co-deposited by a resistance-heating method.

The layer 111 in the comparative light-emitting device 2 contains cgDBCzPA and 3,10PCA2Nbf(IV)-02 at a weight ratio of 1:0.015 and has a thickness of 20 nm.

The layer 111 in the comparative light-emitting device 3 contains αN-βNPAnth and 3,10PCA2Nbf(IV)-02 at a weight ratio of 1:0.015 and has a thickness of 20 nm.

### <<Operation Characteristics of Comparative Light-Emitting Devices 2 and 3>>

Operation characteristics of the comparative light-emitting devices 2 and 3 were measured. Note that the measurement was performed at room temperature.

Tables 6 to 8 show main initial characteristics of the comparative light-emitting devices 2 and 3.

This application is based on Japanese Patent Application Serial No. 2020-014453 filed with Japan Patent Office on Jan. 31, 2020, and Japanese Patent Application Serial No. 2020-078787 filed with Japan Patent Office on Apr. 28, 2020, the entire contents of which are hereby incorporated by reference.

What is claimed is:

1. A light-emitting device comprising:
a first electrode;
a second electrode; and
a first layer,
wherein the first layer comprises a region sandwiched between the first electrode and the second electrode,
wherein the first layer comprises a light-emitting material, a first material, and a second material,
wherein the first material comprises a first anthracene skeleton and a first substituent,
wherein the first substituent is bonded to the first anthracene skeleton,
wherein the first substituent comprises a heteroaromatic ring,
wherein the second material comprises a second anthracene skeleton, a second substituent, and a third substituent,
wherein the second substituent is bonded to the second anthracene skeleton,
wherein the second substituent comprises an aromatic ring whose ring structure is composed of carbon,
wherein the third substituent is bonded to the second anthracene skeleton,
wherein the third substituent comprises an aromatic ring whose ring structure is composed of carbon, and
wherein the third substituent has a different structure from the second substituent.

2. The light-emitting device according to claim 1, wherein the first substituent comprises a carbazole skeleton.

3. The light-emitting device according to claim 1,
wherein the first substituent comprises a dibenzo[c,g]carbazole skeleton and is represented by a general formula (R11), 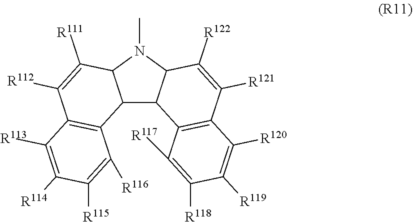
wherein in the general formula (R11), R¹¹¹ to R¹²² independently represent any one of hydrogen, an alkyl group having 1 to 6 carbon atoms, a cyclic hydrocarbon group having 3 to 6 carbon atoms, an alkoxy group having 1 to 6 carbon atoms, a cyano group, halogen, a haloalkyl group having 1 to 6 carbon atoms, and a substituted or unsubstituted aromatic hydrocarbon group having 6 to 60 carbon atoms.

4. The light-emitting device according to claim 1, wherein at least one of the second substituent and the third substituent comprises a naphthalene ring.

5. The light-emitting device according to claim 1, wherein both the second substituent and the third substituent comprise a naphthalene ring.

6. The light-emitting device according to claim 2,
wherein the first material is represented by a general formula (H11), 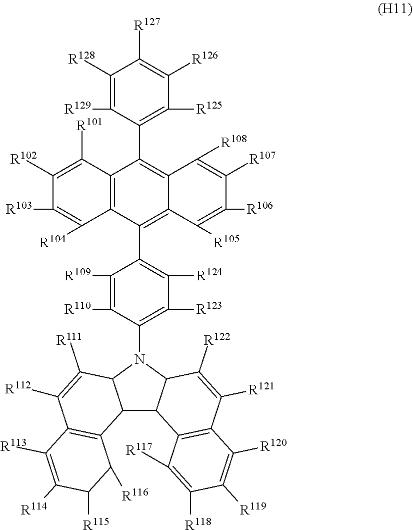
wherein in the general formula (H11), R¹⁰¹ to R¹²⁹ independently represent any one of hydrogen, an alkyl group having 1 to 6 carbon atoms, a cyclic hydrocarbon group having 3 to 6 carbon atoms, an alkoxy group having 1 to 6 carbon atoms, a cyano group, halogen, a haloalkyl group having 1 to 6 carbon atoms, and a substituted or unsubstituted aromatic hydrocarbon group having 6 to 60 carbon atoms.

7. The light-emitting device according to claim 6, wherein the first material is 7-[4-(10-phenyl-9-anthryl)phenyl]-7H-dibenzo[c,g]carbazole represented by a structural formula (H12):

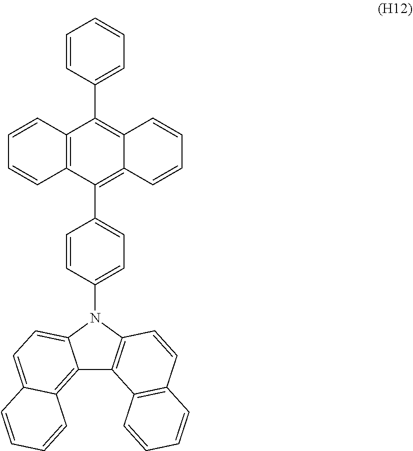 [SMILES: c1ccc(-c2c3ccccc3c(-c3ccc(-n4c5ccc6ccccc6c5c5c6ccccc6ccc54)cc3)c3ccccc23)cc1]

8. The light-emitting device according to claim 1, wherein the second material has a lower electron-transport property than the first material.

9. The light-emitting device according to claim 1,
wherein the second material is represented by a general formula (H21), 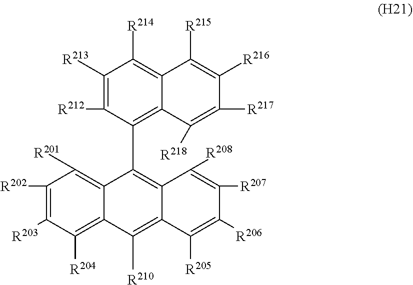
wherein in the general formula (H21), R²⁰² represents hydrogen or a substituent comprising an aromatic ring whose ring structure is composed of carbon, R²¹⁰ represents a substituent comprising an aromatic ring whose ring structure is composed of carbon, at least one of R²⁰² and R²¹⁰ comprises a naphthalene ring, R²⁰¹ to R²¹⁸ except R²⁰² and R²¹⁰ independently represent any one of hydrogen, an alkyl group having 1 to 6 carbon atoms, a cyclic hydrocarbon group having 3 to 6 carbon atoms, an alkoxy group having 1 to 6 carbon atoms, a cyano group, halogen, a haloalkyl group having 1 to 6 carbon atoms, and a substituted or unsubstituted aromatic hydrocarbon group having 6 to 60 carbon atoms.

10. The light-emitting device according to claim 9, wherein the second material is one selected from 9-(1-naphthyl)-10-[4-(2-naphthyl)phenyl]anthracene represented by a structural formula (H22) and 2,9-di(1-naphthyl)-10-phenylanthracene represented by a structural formula (H23):

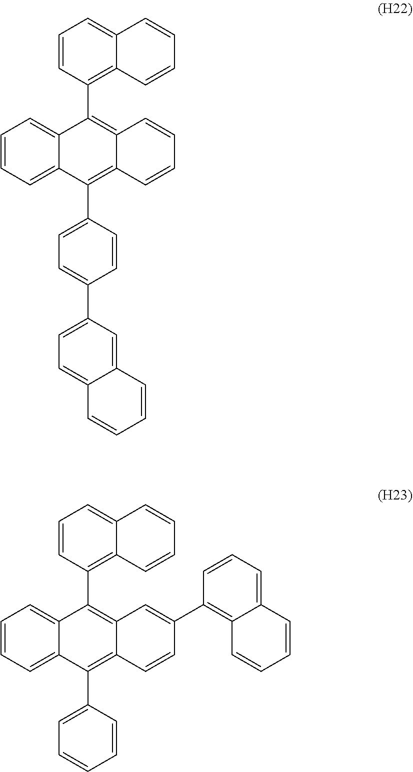

11. The light-emitting device according to claim 1, wherein the light-emitting material emits blue fluorescence.

12. The light-emitting device according to claim 11, wherein the light-emitting material is aromatic diamine or heteroaromatic diamine.

13. A light-emitting apparatus comprising:
the light-emitting device according to claim 1; and
a transistor.

14. An electronic device comprising:
the light-emitting apparatus according to claim 13; and
at least one of a sensor, an operation button, a speaker, and a microphone.
